(19) United States
(12) Patent Application Publication
(10) Pub. No.: US 2004/0252547 A1
(43) Pub. Date: Dec. 16, 2004

(54) Concurrent Processing Memory

(75) Inventor: Chengpu Wang, Setauket, NY (US)

Correspondence Address: Chengpu Wang, 1 Andrea Drive, Setauket, NY, 11733

(73) Assignee: Chengpu Wang, Setauket, NY (US)

(21) Appl. No.: 10/709,920

(22) Filed: Jun. 5, 2004

Related U.S. Application Data
(60) Provisional application No. 60/320,250, filed on Jun. 6, 2003.

(51) Int. Cl. G11C 11/00

(52) U.S. Cl. 365/154

(57) ABSTRACT

A SIMD smart memory comprise addressable registers and functionality of random access memory, as well as processing elements made of addressable and internal registers, neighboring connectivity between the processing elements, and a lattice-like element activation scheme. This memory carries out parallel processing within itself of those simple parallel operations that are universal to all elements, or only involve neighboring memory elements. Many common algorithms using this memory are discussed. For an array of N items, it reduces the total instruction cycle count of universal operations such as insertion and match finding to ˜1, local operations, such as filtering and template matching, to ˜local operation size, and global operations such as sum and sorting to ˜sqrt(N). Particularly, it eliminates most streaming activities for data processing purpose on the system bus. Yet it is easy to use, pin and functional compatible with a random accessible conventional memory, and practical for implementation. In addition, some new designs for components, such as all-line decoder, general decoder, parallel shifter, parallel comparator, parallel adder and parallel divider, are presented.

### CROSS REFERENCE TO RELATED APPLICATIONS

The present application claims the benefit of Provisional Application No. 60/320250 filed June 6, 2003 by Chengpu Wang.

### COPYRIGHT STATEMENT

A portion of the disclosure of this patent document contains material which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### BACKGROUND OF INVENTION

In the past 40 years, the semiconductor industry has been dictated by Moore's law, which says for every one and half years, the density of semiconductor devices doubles.

Moore's law has also applied to CPU speed in a similar fashion. However, in recent years, the semiconductor industry has slowed down and deviated noticeably from the Moore's law, e.g. the increase of the clock speed of CPU can no longer keep the same pace. Also, the industry faces two major technology challenges for further size reduction: (A) the transition from classical circuit to quantum circuit, and (B) the transition from far-field (wave) manufacture technology to near-field (nano) manufacture technology. At this moment an important question is: Are our computers fast enough?

The majority of our computers, including PC, Unix, Macintosh, and most embedded computers, are bus-sharing computers, in which there is: (A) a memory unit that stores instructions and data, (B) a processing unit that executes the instructions one after another, to process the data, and (C) a bus unit that connects the two. At MHz or even GHz of clock rate, and even with multiple CPUs within the processing unit, our bus-sharing computers seem quite fast for solving most serial problems which contains sequence of instructions, yet they are ill equipped when dealing with parallel problems such as searching and ordering database, processing image, and modeling involving space, mainly due to the following reasons:

(1) The parallel nature of the problem is different from the serial way in which the problem is solved in bus-sharing computers. In a parallel problem, a procedure is applied independently to each item of an array. The collection of such applications can be carried out concurrently. Yet a bus-sharing computer can only carry out them one after another. The drawback is two fold: (A) The amount of data could be huge, e.g., even a common digital camera contains million of pixels. If a same procedure has to be repeated for each array item, it is a very slow solution. For an example, to process a photo taken by a common digital camera, a bus-sharing computer has to repeat a same procedure of a parallel problem at least millions times. (B) Each application of the procedure contains many same operations on the same data, and a bus-sharing computer has to repeat every one of them for each different datum. Thus, it is also a very inefficient solution. For an example, every pair of neighboring data has to be summed multiple times in any neighborhood averaging scheme.

(2) The large amount of required data transfer for carrying out the serial solution for a parallel problem will boggle down the bus unit in a bus-sharing computer. Actually, the bus unit is already normally much slower than the processing unit, e.g., in PC, it has been always about 5 times slower for the past ten years. The speed of a bus-sharing computer is usually determined by the speed at which the bus unit can supply instructions and data from the memory unit to the processing unit. This is called a bus bottleneck problem. Trying to cope with this bus bottleneck is already the major task of a modern CPU, e.g. costing about 70% of die area of a Pentium III CPU. Flushing the bus unit of a bus-sharing computer with a lot of repeated instructions and repeated data when solving a parallel problem serially can only make the matter much worse. For an example, the simplest neighborhood averaging of a digital camera photo in a bus-sharing computer requires tens of millions times of pixel data transfer, and all of them are repeated. This adds a lot of stress to the bus unit of the bus-sharing computer.

The above drawbacks of the bus-sharing computer originate from the separation of (A) the processing and (B) the storing of instructions and data. With the currently achievable semiconductor size and new developments in silicon integration, it is quite desirable to merge the processing and the storing of instructions and data into one unit. The end of the Moore's law actually provides development possibilities in other dimensions.

Still, it is not the time to dismiss our bus-sharing computers yet. In addition to their well known advantages of maturity and ubiquity, and amazing abilities for serial problems, bus-sharing computers have one hidden advantage: they fit our Human logic well. Our Human logic is based on induction and deduction, both of which are serial in nature. We only deal with parallel problems as one of the steps of our serial problems. The bus-sharing computers have the architecture that guarantees the serial execution of instructions, and provides bases for proper synchronization between multiple threads of serial executions. Even the reconfigurable systems, such as PLD and FPGA, which are frequently associated with parallel data processing, are mostly configured in programs, which comprise serial descriptive instructions and are processed by bus-sharing computers using serial instructions.

Another hidden advantage of our bus-sharing computers is that they can have a powerful processing unit that can do almost everything. On the other hand, any solution for parallel problems based on massive parallel processing can not be universal to make economical sense. It is justified to have one or a few very complicated CPUs for one computer. It is probably not justified to have one very complicated CPU for every datum in a large pool of data.

So a fast and efficient solution to our parallel problems may call for a device that: (A) integrates seamlessly with a bus-sharing architecture; (B) is controlled by the processing unit of the bus-sharing architecture and is part of the memory unit; (C) is limited to the application of parallel problems only; (D) stores the data for the parallel problem; (E) processes the data locally near each datum; (F) solves the parallel problem using massive parallel algorithm, such as SIMD (Single-instruction Multiple-Data) in particular; and (G) has minimal impact on the bus unit of the bus-sharing architecture. Or in another word, what we need is a smart memory for each particular kind of parallel problems.

Information relevant to attempts to build memory with some internal processing power can be found in U.S. Pat. Nos. 6,460,127, 6,404,439, 6,711,665, 6,275,920, 4,215,401, 4,739,474, 6,073,185, 5,809,322, 5,717,943, 5,710,932, 5,546,343, 5,421,019, 5,134,711, 5,095,527, 5,038,282, 6,049,859, 6,173,388, 5,752,068, 5,729,758, 5,590,356, 5,555,428, 5,418,915, 5,175,858, 4,992,933, and 4,775,952. However, each one of these references suffers from one or more of the following disadvantages: (A) Not pin-compatible or function-compatible with a conventional random access memory; (B) Not able to be used in a memory unit of a conventional bus-sharing architecture; (C) Not able to accomplish tasks by itself of required complexity for most common parallel problems such as sorting and sum; (D) requiring a lot reconfiguration effort when switching tasks; and (E) requiring re-designing of existing computer architectures.

For the foregoing reasons, there is a need to build smart memories that is: (A) pin compatible with a conventional random access memory; (B) function compatible with a conventional random access memory; (C) comprising a SIMD (Single-instruction Multiple-Data) processing architecture inside; (D) requiring no or little external bus activities to solve the parallel problem for which the smart memory is designed for; (E) switching between different tasks instantly, (F) variable in scope of capability; and (G) is practical to be implemented.

### SUMMARY OF INVENTION

The present invention is directed to an apparatus that satisfies this need for a smart memory. This apparatus is called concurrent processing memory, or simply CP memory.

The CP memory is pin compatible with a conventional random access memory. It needs only difference of one extra pin, called a command input pin, from a conventional random access memory. The command input pin can actually be connected as an address pin as if the CP memory is a random access memory of a larger capacity.

When the command input pin is negatively asserted, the CP memory behaves exactly like a conventional random access memory, containing an array of addressable registers for storing and retrieving data through an external bus comprising address bus, data bus and control bus.

The CP memory is also a SIMD (Single-instruction Multiple-Data) machine for solving parallel problems, containing identical memory elements: (A) each of which preferably comprises at least one addressable registers, possibly other registers, and some processing power, and (B) all of which can simultaneously execute a same instruction independently from each other. The concurrent processing power means great reduction of the required instruction cycles for parallel problems. The processing power within the CP memory means reduction, in most cases great reduction, of the need to use the external bus to transfer data.

When the command input pin is positively asserted, the CP memory treats the content of the external bus as an instruction. Since the command input pin is connected as a pin for address bus, to a user of the CP memory, sending instruction and getting result is like storing and retrieving data using a special address in a conventional random access memory. In this way, a CP memory can be used anywhere a conventional random access memory can be used, including in any bus-sharing computer.

A memory element of a CP memory only executes an instruction when it is activated. The CP memory instantly activates all memory elements whose element addresses are: (A) no less than a start address, (B) no more than an end address, and (C) an integer increment of the carry number starting from the start address. In another word, the activated elements form a lattice that is instantly changeable. The lattice structure is analogous with the data array structure which is common to all parallel problems. This guarantees quick task switching, no matter how many memory elements need to be activated or inactivated between tasks.

The CP memory is actually a family name that comprises CP memories of various scopes, for solving different kinds of parallel problems. Among them, in the order of increased complexity of the memory element, are: (A) content movable memory, (B) content searchable memory, (C) content comparable memory, (D) database memory, (E) 1D math memory, and (F) 2D math memory. The content searchable memory and the content comparable memory are collectively referred as content matchable memory. The 1D math memory and 2D math memory are collectively referred as math memory.

The CP memory is constructed using standard digital circuitry technology. Still, several device components of the CP memory have been invented also using standard digital circuitry technology, such as carry pattern generator, parallel shifter, all-line decoder, parallel comparator, general decoder, range decoder, multi-channel multiplexer, and multi-channel demultiplexer. BRIEF DESCRIPTION OF DRAWINGS

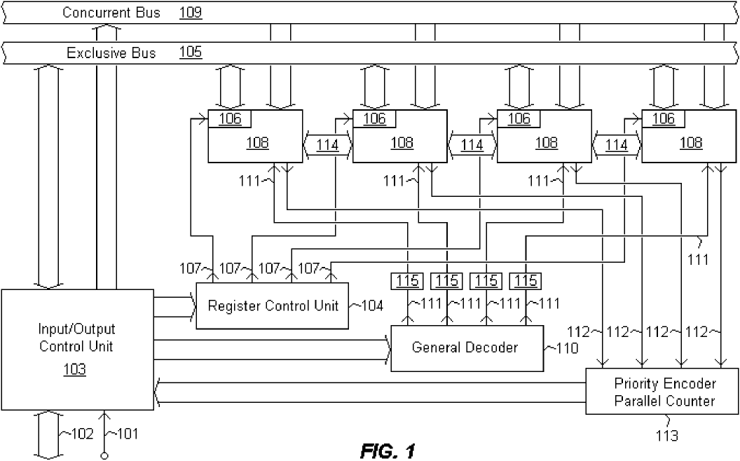

FIG. 1: Complex system structure of a complex CP Memory.

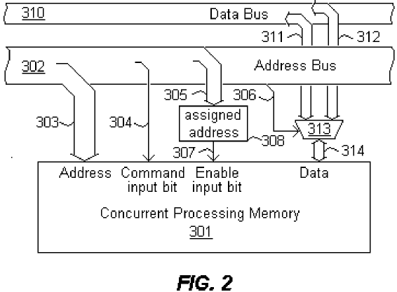

FIG. 2: Connecting a CP memory to an external bus.

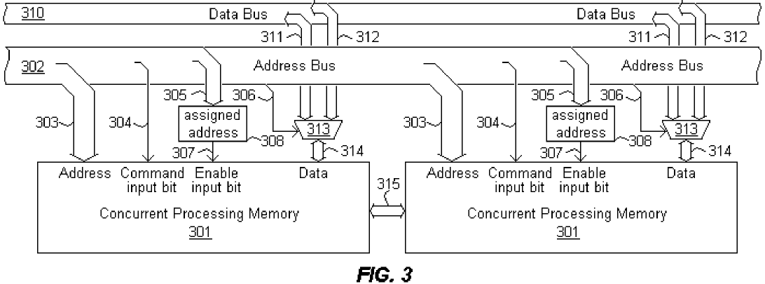

FIG. 3: Connecting two CP memories together and to an external bus.

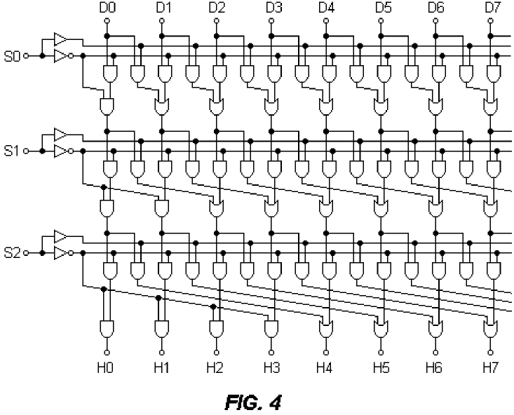

FIG. 4: Circuit diagram of a 3-digit 8-input/output parallel left shifter.

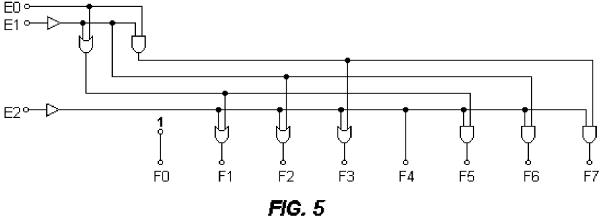

FIG. 5: Circuit diagram of a 3-input 8-output all-line dedoder.

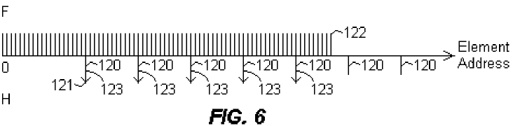

FIG. 6: Logic for activating general decoder bit outputs.

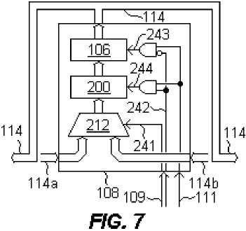

FIG. 7: Structure diagram of a content movable memory element.

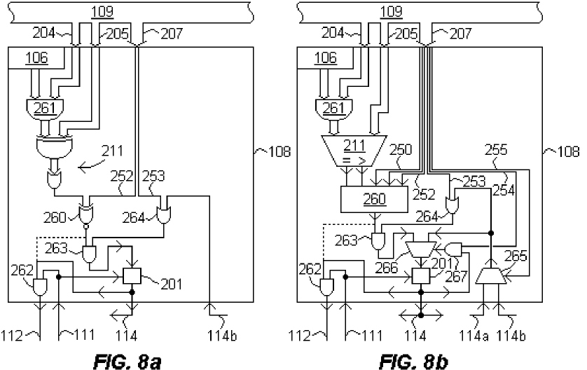

FIG. 8a: Structure diagram of a content searchable memory element.

FIG. 8b: Structure diagram of a content comparable memory element.

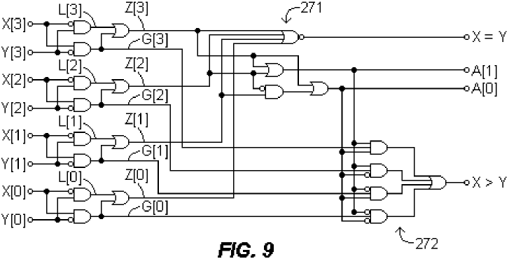

FIG. 9: Circuit diagram of a 4-bit parallel comparator.

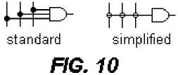

FIG. 10: Symbols for standard and simplified multiple input AND gate.

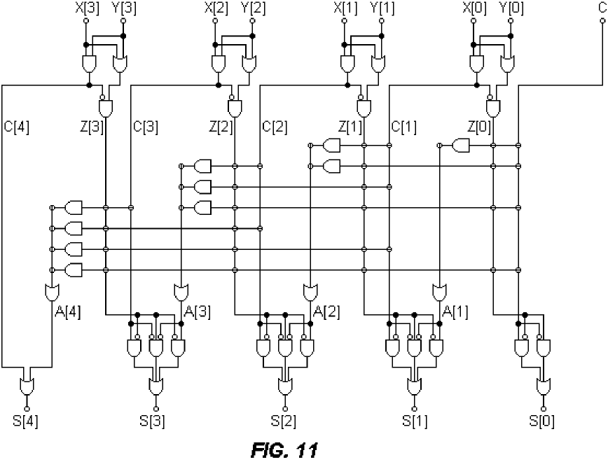

FIG. 11: Circuit diagram of a 4-bit parallel adder.

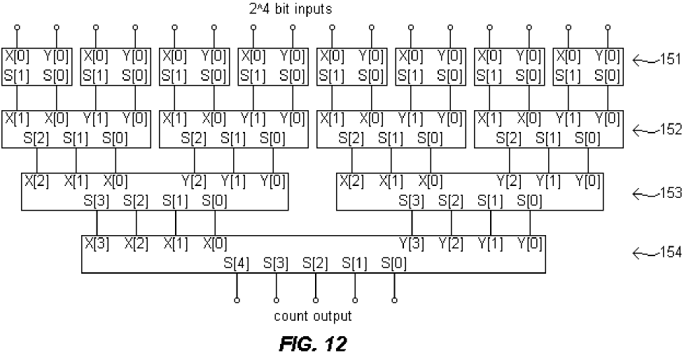

FIG. 12: Structure diagram of a 4-bit parallel counter using adders in binary tree construct.

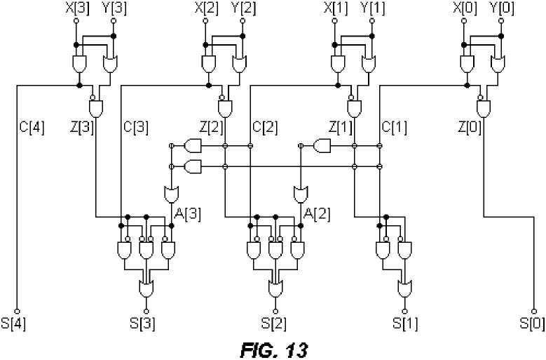

FIG. 13: Circuit diagram of a 4-bit parallel adder for parallel counter.

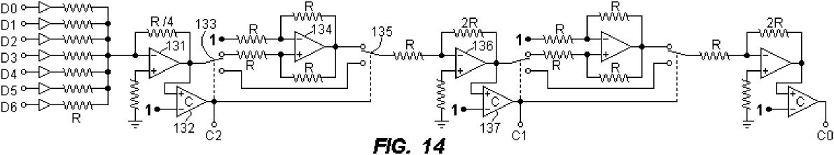

FIG. 14: Circuit diagram of a 3-bit parallel counter using A/D technology.

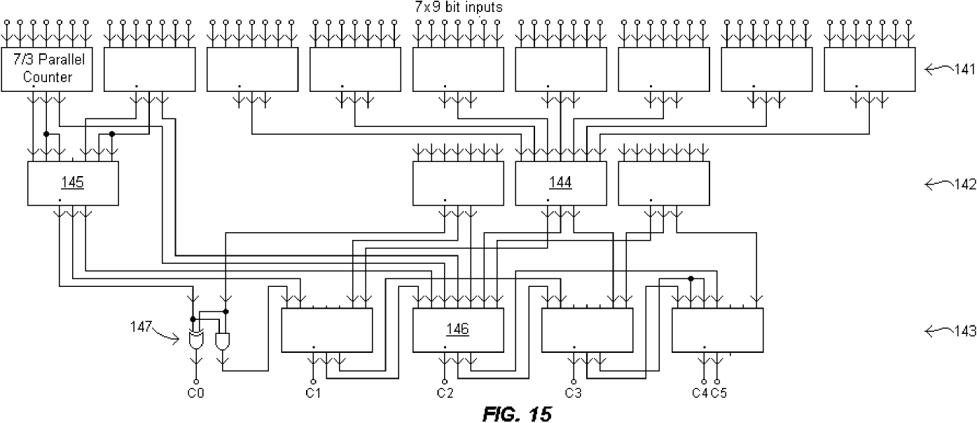

FIG. 15: Structure diagram of a 6-bit parallel counter scaled up from 3-bit parallel counters.

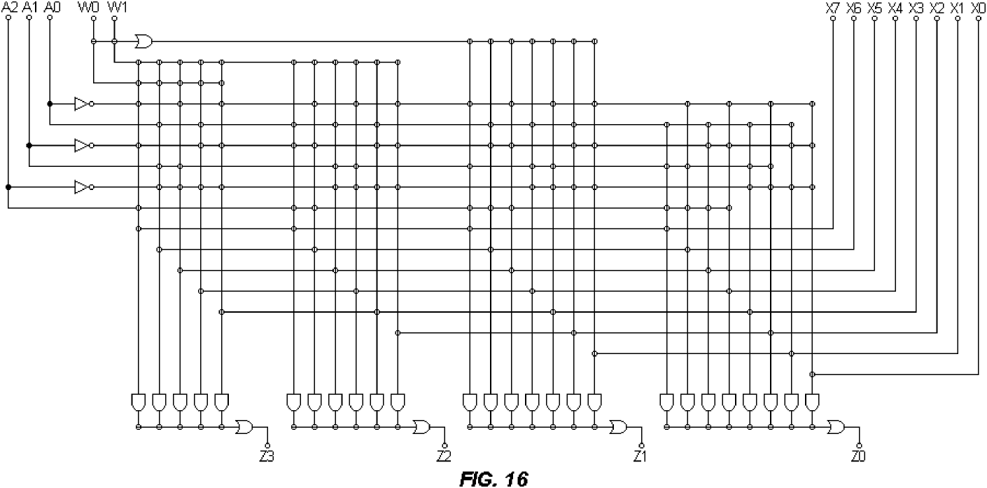

FIG. 16: Circuit diagram of an 8-input 4-channel multiplexer.

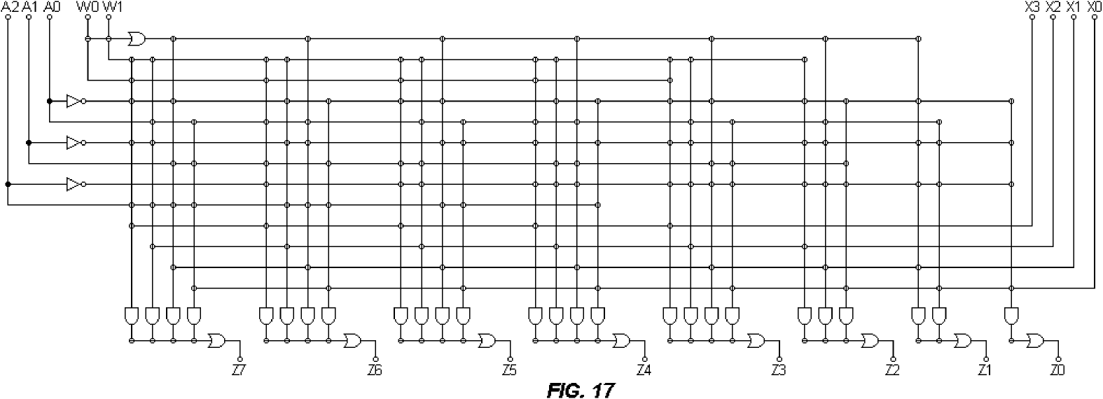

FIG. 17: Circuit diagram of an 8-output 4-channel demultiplexer.

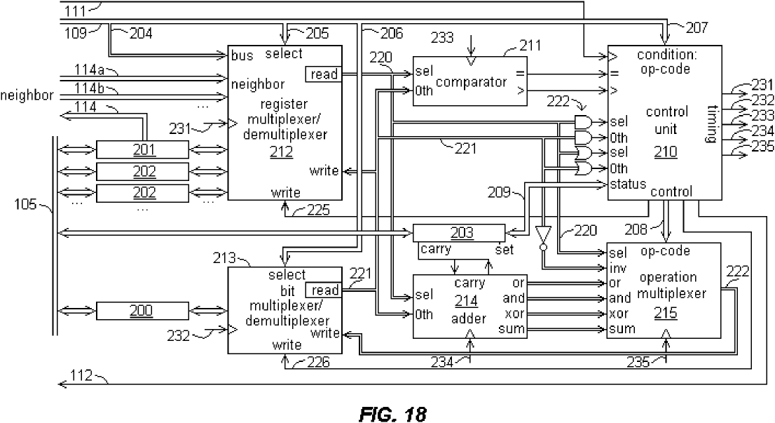

FIG. 18: Structure diagram of a memory element for math memory.

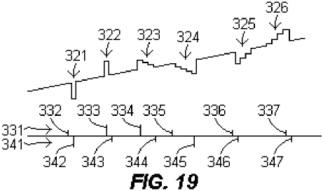

FIG. 19: General cases of disorder for global moving sorting algorithm.

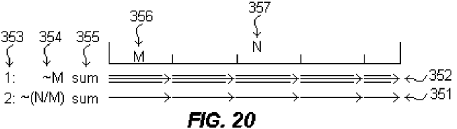

FIG. 20: Algorithm flow diagram for 1-D sum.

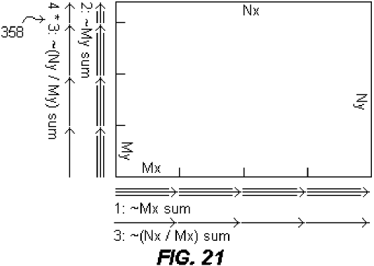

FIG. 21: Algorithm flow diagram for 2-D sum.

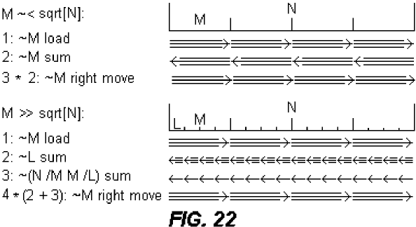

FIG. 22: Algorithm flow diagram for 1-D template matching.

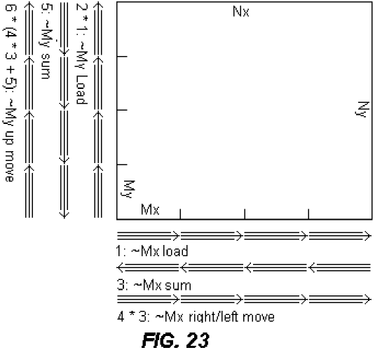

FIG. 23: Algorithm flow diagram for 2-D template matching.

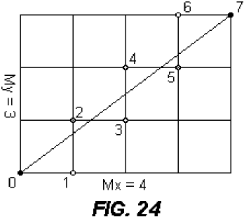

FIG. 24: (4*3) super lattice for detecting line with slope of (¾).

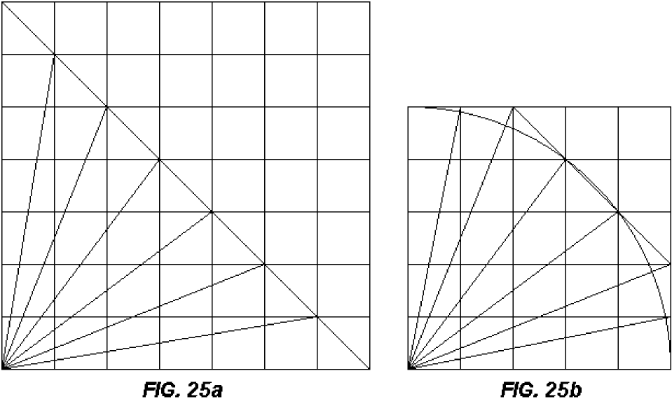

FIG. 25a: A set of lines whose pixel spans are exactly 7 in walking distance.

FIG. 25b: A set of lines whose pixel spans are about 5 in real distance.

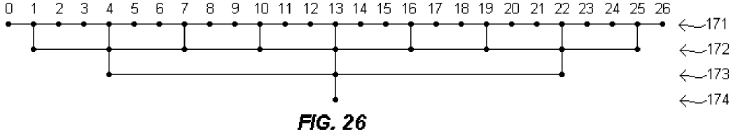

FIG. 26: Log(N) long range connectivity.

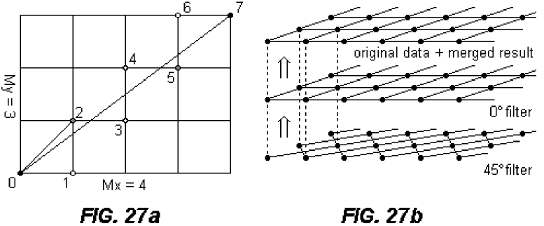

FIG. 27a: 2-D super-lattice connectivity.

FIG. 27b: 3-D super-lattice connectivity.

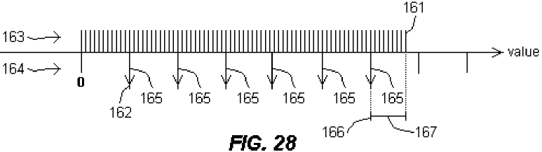

FIG. 28: Logic diagram of parallel divider.

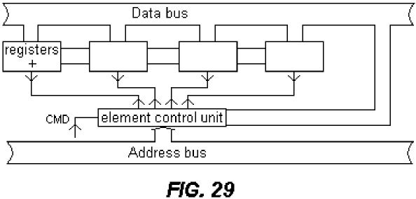

FIG. 29: Function diagram of a concurrent processing memory, which is the overview of the invention.

### DETAILED DESCRIPTION

Backward Compatibility

FIG. 1 shows a structure overview of a most complicated CP memory on the system level, which can be turned into other family members in the CP memory family by deleting components form it, as described later in this Description.

Except a command bit input 101, a CP memory has the same external bus connection 102 for an external bus as a conventional random access memory. The external bus comprises address bus, data bus, and control bus.

The address bus is usually wider than a memory's external connection to address bus. For a conventional random access memory, the address bus bits which are not connected with the memory's external bus connection to the address bus are assigned address bits. Each memory has an assigned address which is unique for the memory. When the assigned address bits equals the assigned address, an enable bit input, which is one of the memory's external bus connection to control bus, is positively asserted to activate the memory. For a CP memory, the least significant bit of the assigned address bits is connected to the command input bit of a CP memory, while the rest bits are assigned address bits. Thus, a CP memory requires twice of address space than what it contains in its addressable registers. Other assigned address bit can also be connected to the command input bit of a CP memory, with a larger address space needed.

The data bus is usually 2\hat{ }M fold byte wide, in which M is an unsigned integer, while each addressable register inside a memory is often byte wide. If a memory's external connections to data bus are byte wide, the M least significant bits of the address bus select the byte portion of the data bus to be connected to the CP memory's external connection to data bus, using a multiplexer/demultiplexer, in the same manner as a conventional random access memory.

FIG. 2 shows how a byte-wide CP memory 301 is connected with the address bus and the data bus of an external bus, whose data bus 310 is two-byte wide. The least significant portion 303 of the address bus 302 is connected to the memory's external bus connection to address bus. The next address bus bit 304 is connected with the memory's command input bit. When the rest address bits 305 contain a value that equals the assigned address 308 for the memory, the memory is activated through its enable bit input 307, which is one of the memory's external bus connections to control bus. The least significant bit 306 of the address bus 302, which is also connected to the memory's external bus connection to the address bus, selects to connect either the lower portion 311, or the higher portion 312 of the data bus 310 to the memory's external bus connection to data bus 314 through a multiplexer/demultiplexer 313.

The CP memory's external bus connections to the other bits of the control bus are the same as those of a random access memory. The control bus of an external bus provides power and ground, instructs the memory for either a storing or a retrieving operation, and provides synchronization and handshake with other devices which are also connected to the same external bus.

If the address space is not a concern, a CP memory may have more than one command bit to connect to the address bits, to increase the bandwidth of transferring instructions. Some bus standards have dedicated control and arbitration bits to control the connected devices. Accordingly, the CP memory may have additional command bits to take advantages of the situation.

Exclusive Access

In FIG. 1, when the command bit input 101 is negatively asserted, the CP memory behaves exactly like a conventional random access bus. The address bus of the external bus 102 specifies a register address for one of the addressable registers 106within the CP memory; the register address is sent to the input/output control unit 103, and then to the register control unit 104, which exclusively activates the corresponding addressable register at the register address through exclusive connections 107 to each of all the addressable registers. The control bus of the external bus 102 specifies either a storing operation or a retrieving operation to the CP memory. For a storing operation, the data is sent from the data bus of the external bus 102 to the input/output control unit 103, then to the exclusive bus 105, and then to the exclusively activated addressable register. For a retrieve operation, the data is sent from the exclusively activated addressable register, to the exclusive bus 105, then to the input/output control unit 103, and then to the data bus of the external bus 102. A CP memory may use the same logic and the same hardware for exclusive access as a random access memory.

Concurrent Instructing

The CP memory is also a SIMD machine, containing identical memory elements 108, each of which preferably comprises at least one addressable registers 106, possibly other registers, an enable bit input 111, an optional match bit output 112, and some processing power.

When the command bit input 101 is positively asserted, the CP memory treats the content of the external bus 102 as an instruction. Since the command input pin 101 is connected as an address bus bit, to a user of a CP memory, sending instruction and getting result is like storing and retrieving data with a conventional random access memory when a particular address bit is positively asserted. Within CP memory, the instruction is then translated by the input/output control unit 103, and broadcasted to all the memory elements 108 concurrently through a concurrent bus 109. In addition to instruction, the concurrent bus 109 may also broadcast data to all the memory elements 108. The concurrent bus 109 is exclusively written by the input/output control unit 103, and concurrently read by multiple memory elements 108.

Each memory element 108 has a unique element address. The input/output control unit 103 sends a start address, an end address, and a carry number to a general decoder 110, which, through enable bit inputs 111 exclusively to each of all the memory elements 108, activates all the memory elements 108 whose element addresses are: (A) no less than the start address, (B) no more than the end address, and (C) an integer increment of the carry number starting from the start address. All the enabled memory elements receive and execute a same instruction with a same data parameter from the concurrent bus 109. The start address, end address, and carry number are all parameters as part of instructions to the CP memory.

As described later, the carry number needs not to exceed the square root of the total bit output count of the general decoder. For a content movable memory or a content searchable memory, it is a constant of 1.

The data for majority parallel problems are in the format of array. Using the above activation rules, an item may be held by a same number of memory elements which have consecutive element addresses, or a memory element may hold a same number of items. For simplicity of the following discussion, each memory element may hold one item, and the other two cases can be treated similarly.

It is possible that each of all bit outputs of the general decoder is connected to a dedicated bit storage cell 115, such as a flip-flop, and the bit storage cell connects to the enable bit input of the corresponding memory element 111. One use of the bit storage cell 115 is to separate the general decoder from active duty of activating memory elements when the general decoder 110, parallel counter and priority encoder 113 are configured as a parallel divider, as described later. The other use of the bit storage cell 115 is to put additional constraint on the activation of memory elements, such as acting as a filter for a 2D image pattern which has irregular shape.

Like a conventional static random access memory, the execution of an instruction by a CP memory may take the same amount of time as storing or retrieving data with an addressable register. Like a conventional dynamic random access memory, the execution of an instruction by a CP memory may take longer time, or even variable time, and the input/output control unit 103 may use standard asynchronous means for signaling the termination of instruction execution, such as interrupt, wait states, or predefined content change of the external bus 102, or simply require a predefined wait period before receiving another instruction from the external bus 102.

Each register inside a memory element is identified by a register number, so that it can be referred in an instruction to the memory element. The assignment of register number satisfies the following conditions: (1) the set of register numbers is identical for all of the memory elements; (2) the registers which have the same register number are functionally equivalent within their memory elements respectively, and (3) the register number for an addressable register is between zero and the value of one less than the count of the addressable registers within each memory element. Thus, the register address of each addressable register 106 comprises: (1) the element address of the memory element 108 which contains the addressable register 106; and (2) the register number to identify the addressable register 106 within the memory element. If the register number is used as the lower portion for the register address, all functionally equivalent registers within all memory elements form a continuous register address range, which is convenient for task switching such as using direct memory access.

Concurrent Matching

Each activated memory element 108 of a CP memory can have internal states. If the internal state matches a requirement, which may have been sent to the memory elements by the concurrent bus 109, the memory element positively asserts its match bit output 112 exclusively to a priority encoder 113, which outputs to the input/output control unit 103 either the highest or the lowest element address of the memory element which is in the required state. The priority of the priority encoder is controlled by the input/output control unit 103. Alternatively, each match bit output 112 for the memory element may exclusively connect to a parallel counter 113, which outputs the total count of the memory element which is in the matched state to the input/output control unit 103. Both priority encoder and parallel counter may also be used.

Each memory element may have a storage bit to save the binary value of the match bit output, so that it can be used for subsequent state definition, or state definition which involves neighboring memory elements.

Local Connectivity

The physically neighboring memory elements have adjacent element addresses. In a one-dimensional CP memory, except the two boundary memory elements, each of which has either lowest or highest element address, each of all the memory elements has two neighboring memory elements whose element address is either immediately lower or immediately higher than the element address of the memory element itself. In a two-dimensional CP memory, each memory element is on the node of a square lattice; the two perpendicular lattice directions are the X and the Y directions; the element address is partitioned into X and Y addresses; and except boundary memory elements; each of all memory elements has a pair of neighboring memory elements along the X direction, and another pair of neighboring memory elements along the Y direction.

The neighboring memory elements may be connected through neighborhood connection 114 so that each memory element shows a universal content of at least one of its registers, which is called the neighboring register, to all of its neighbors.

A CP memory may contain additional external connections to the neighboring registers of the boundary memory, so that several CP memories can be connected and used as one large CP memory. FIG. 3 shows how to connect two CP memories together, each of which has been connected to an external bus as described in FIG. 2, using the additional external connections to the neighboring registers of the boundary memory elements 315

Instruction Kernel

A CP memory is controlled by the external bus, which is connected and controlled by the processing unit of a computer. An instruction kernel may interface between a CP memory and an external bus, to translate instructions for the instruction kernel into instructions for the CP memory, not unlike translating the instructions for a processor into micro-kernel instructions within the processor. The instruction kernel could be: (1) an instruction kernel inside the input/output unit of the CP memory, (2) an embedded microcontroller between the CP memory and the external bus, or (3) a software driver that manages the CP memory.

The instructions for the instruction kernel are more complex, and probably more capable than the instructions for the memory elements. For an example, in math memory, the multiplication and division instructions for the instruction kernel may be translated into a series of addition, subtraction, and shifting instructions for the memory elements. The instruction kernel may contain resources such as memory, registers, and/or accumulator to carry out the instructions. The instructions for the instruction kernel may be carried out asynchronously, and the instruction kernel may use a predefined wait time period, a wait state of the data bus, an interrupt, or other means, to signal the end of such an instruction execution.

General Decoder

As described earlier, the general decode 110 has a carry number input, a start address input, an end address input, all of which from the input/output control unit 103, and a plurality of element control bit outputs 111, each of which connecting exclusively to the enable bit input of a unique memory element 108. The element address of each memory element 108 is actually decided by the general decoder 110.

Inside the general decoder 110, the carry number input is connected to a carry pattern generator, which positively asserts all its bit outputs whose addresses are an increment of the inputted carry number while negatively asserting all the other bit outputs. All possible values of the carry number form a set C. A bit output D has an address A, whose binary expression is C(A), and whose natural number factors forming another set Q(A). K(A) is the overlap set between C and Q(A). Using K(A)[k] to denote a unique element of K(A), the logic expression of D[A] is:

D[0]=1;

IF A ε K[A]: D[A]=ΣₖD[K(A)[k]]+C(A);

ELSE: D[A]=ΣₖD[K(A)[k]];

The above expression is transformed into standard product-of-sum format using either K-map or Quine-Mc-Cluskey method, and the carry pattern generator is constructed using corresponding two-level gates. The product-of-sum construct is chosen for expansibility, so that the addition of C[M] input bit appends !C[M] product term to the existing expressions of (C[M−1] . . . C[0]). For an example, a ⅜ carry pattern generator inputs binary carry number (C[2] C[1] C[0]), and outputs bit outputs (D[7] D[6] D[5] D[4] D[3] D[2] D[1] D[0]) in the following manner:

D[0]=1;

D[1]=!C[2] !C[1] C[0];

D[2]=!C[2] C[1] !C[0]+D[1];

D[3]=!C[2] C[1] C[0]+D[1];

D[4]=C[2] !C[1] !C[0]+D[2]+D[1];

D[5]=C[2] !C[1] C[0]+D[1];

D[6]=C[2] C[1] !C[0]+D[3]+D[2]+D[1];

D[7]=C[2] C[1] C[0]+D[1];

Or:

D[0]=1;

D[1]=!C[2] !C[1] C[0];

D[2]=!C[2(C[1]+C[0])(!C[1]+!C[0]);

D[3]=!C[2] C[0];

D[4]=(C[2]+C[1]+C[0])(!C[2]+!C[1])(!C[1]+!C[0])(!C[2]+!C[0]);

D[5]=!C[1] C[0];

D[6]=(!C[2]+!C[0])(C[1]+C[0]);

D[7]=(!C[2]+C[1])(C[2]+!C[1])C[0];

The bit outputs of the carry pattern generator D=(D[N−1] . . . D[0]) are connected to the bit inputs of a parallel left shifter, whose shift amount input S=(S[M−1] . . . S[0]) is connected from the start address input to the general decoder 110. The parallel left shifter concurrently shifts all bit inputs D=(D[N−1] . . . D[0]) toward higher address by the amount of shift amount input S at its bit outputs H=(H[N−1] . . . H[0]), mathematically as:

IF A=>S: H[A]=D[A−S];

ELSE: H[A]=0;

Since shifting is accumulative, each S[j] input bit just shifts each of all the inputs by the amount of 2\hat{ }j toward higher address. For an example, the circuit diagram of a ⅜ parallel left shifter is shown in FIG. 4, in which (D[7] . . . D[1] D[0]) is the 8-bit input, (H[7] . . . H[1] H[0]) is the 8-bit output, and (S[2] S[1] S[0]) is the 3-bit shift amount input. The circuit diagram is readily to be extended when the bit count of inputs and outputs is more than 8.

Inside the general decoder 110, the end address input is connected to the address input E=(E[M−1] . . . E[0]) of an all-line decoder, which activates all its bit outputs F=(F[N−1] . . . F[0]) whose address is less than or equal to the input address. For an example, a ⅜ all-line decoder inputs 3-bit address (E[2] E[1] E[0]), and outputs 8-bit bit outputs (F[7] . . . F[1] F[0]) in the following manner:

F[7]=E[2] E[1] E[0];

F[6]=E[2] E[1] !E[0]+F[7];

F[5]=E[2] !E[1] E[0]+F[6];

F[4]=E[2] !E[1] !E[0]+F[5];

F[3]=!E[2] E[1] E[0]+F[4];

F[2]=!E[2] E[1] !E[0]+F[3];

F[1]=!E[2] !E[1] E[0]+F[2];

F[0]=!E[2] !E[1] !E[0]+F[1];

Or:

F[7]=E[2](E[1] E[0]);

F[6]=E[2](E[1]);

F[5]=E[2](E[1]+E[0]);

F[4]=E[2] 1;

F[3]=E[2]+(E[1] E[0]);

F[2]=E[2]+(E[1]);

F[1]=E[2]+(E[1+E[0]);

F[0]=E[2]+1;

The corresponding circuit diagram is displayed in FIG. 5. Assuming the bit output is F[E, N], in which N denotes the bit width of the address input and E denotes the address of the bit output, an all-line-decoder with input address bit width of (N+1) can be built from an all-line-decoder with input address bit width of N using the logic expression of F[E, N]:

F[0, 1]=1;

F[1, 1]=E[0];

F[(0 E[N−1] . . . E[0]), N+1]=F[(E[N−1] . . . E[0]), N]+E[N];

F[(1 E[N−1] . . . E[0]), N+1]=F[(E[N−1] . . . E[0]), N] E[N];

Inside the general decoder 110, the bit outputs of the parallel left shifter H=(H[N−1] . . . H[0]) are AND-combined with the corresponding bit outputs of the all-line decoder F=(F[N−1] . . . F[0]), to become the corresponding bit outputs of the general decoder 110, as illustrated in FIG. 6. All the element control bit outputs are activated 123 whose element addresses are: (A) no less than a start address 121, (B) no more than an end address 122, and (C) an integer increment of the carry number starting from the start address 120.

As described later, the value of the carry number input needs not exceed the square root of the total bit output count of the general decoder.

If the carry number is a constant of 1, the start address is input into a first all-line decoder whose outputs are negatively assertive, and the end address is input into a second all-line decoder whose outputs are positively assertive. The corresponding outputs from the two all-line decoders are AND-combined, before becoming the bit outputs of the general decoder 110. This special case of general decoder is called a range decoder.

Due to the design of the general decoder 110, changing its start address input may be less efficient than changing its end address input in terms of the number of gates that need to change their states.

It is possible to enable each memory element by the bit storage cell only (without using the general decoder), like conventional processor array. Other means then is used to setting the values of the bit storage cell serially, such as using a controlling CPU. However, this method may be slow for task switching between different array or different members of array items of a same array. Thus, general decoder or range decoder also may be very useful in controlling processor array in general.

Content Movable Memory

The simplest CP memory is a content movable memory. FIG. 7 shows its memory element 108. Each memory element 108 has only one addressable register 106, thus the element address is same as the register address of the addressable register 106. Through neighborhood connection 114, the addressable register 106 is also the neighboring register. The memory element has another register, the operation register 200, which is made of cheap dynamic memory cells that only need to keep their values for more than one clock cycles. A multiplexer 212 selects a neighborhood connection, either (A) from the memory element which has immediately lower element address 114a or (B) from the memory element which has immediately higher element address 114b, to copy to the operation register 200 when the write control bit 244 of the operation register 200 is positively asserted. The value of the operation register 200 can be copied to the addressable register 106 when the write control bit 243 of the addressable register 106 is positively asserted. The concurrent bus 109 has two bits, one 241 to select the source of the multiplexer 212 from either 114a or 114b, the other 242 to select copying to one of the two registers, 200 or 106. The enable bit input 111 is AND combined with the other bit 242 of the concurrent bus 109, to disable any copying when the enable bit input 111 is negatively asserted. Thus, the control unit of the memory element 108 comprises the connections of the multiplexer 212, the AND gate for the write control bit 243 of the addressable register 106, the AND gate for the write control bit 244 of the operation register 200, and the enable bit input 111.

The content of addressable registers 106 in the neighboring memory elements can be copied to the addressable register 106 by first being copied through the neighborhood connection 114a or 114b to the operation register 200, and then to the addressable register 106 of the memory elements.

A content movable memory needs neither priority encoder nor parallel counter 113. A range decoder is used as the general decoder 110, so that all the memory elements are activated if their element address is: (A) no less than a start address, and (B) no more than an end address. In this way, the data within a register address range can be moved within a content movable memory.

Using the contenting moving procedure, a content movable memory can add, remove, relocate, and change size of a stored data object anywhere within it while keep its content closely packed. It may contain a truly dynamic array without the need for either link list or look-ahead allocation. It may even use address independent unique ID to identify each stored data objects, and support containment relationship so that: (A) when the size of a contained data object is changed, the container data object is changed accordingly, and (B) when the container data object is removed, all the contained data objects are removed.

When using a content movable memory for a program, the space allocated for a variable can grow and shrink easily according to the need, which brings about the following advantages: (1) a numerical variable will never go out of range, (2) an array is always dynamic; (3) the distinction between stack memory and heap memory may no longer need, and (4) the most economical use of the resources can be achieved.

Since both size and precision for each numerical variable is adjustable dynamically, the conventional float fractional formats and their rules of operations can be improved so that the precision error is always limited to the LSB (least significant bit) of the mantissa. For an example, the result precision of an addition or subtraction is the lesser precision of the two operands, and in case the two operands having same precision, the result precision remains in the original LSB if the two operands are independent from each other, and the operation on the original LSBs does generate carry, or it is shifted to the bit immediately above the original LSB if otherwise. The multiplication, division, and other arithmetic operations can be based upon similar rules for addition and subtraction. In such a scheme, each numerical value is guaranteed to be precise until LSB. In worst case, instead of giving wrong answer due to precision error accumulation and propagation as in the conventional float fractional math, the new float fractional math may indicate that at a certain step of the algorithm, the initial values are no longer precise enough for the algorithm.

Content Matchable Memories

Content matchable memory is also a family name. It has three types of memory element:

(1) content searchable memory element, which can match the content of its addressable register 106 with a datum, and positively assert its match bit output 112 if (I) its enable bit input 111 is positively asserted, and (II) the comparison satisfies the match requirement, which can be any of: (A) equal, and (B) unequal. Neighborhood connection allows comparison between a datum and the collective content of any neighboring memory elements. Thus, the primary use is to find all matching strings among a text.

(2) content comparable memory element, which can compare the content of its addressable register 106 with a datum, and positively assert its match bit output 112 if (I) its enable bit input 111 is positively asserted, and (II) the comparison satisfies the match requirement, which can be any of: (A) equal, (B) unequal, (C) larger, (D) smaller, (E) larger or equal, and (F) smaller or equal. Neighborhood connection allows comparison between a datum and the collective content of neighboring memory elements which forms the items of an array. Thus, the primary use is to find all matching array items.

(3) It is also possible to combine either a content searchable memory element or a content comparable memory element with a content movable memory element.

FIG. 8a shows a content searchable memory element 108. It has only one addressable register 106, whose content is to be searched. The concurrent bus 109 sends: (A) a mask 204, which is AND combined with the addressable register 106 at a bus AND gate 261; (B) the datum to be matched 205, whose value is compared with the masked data from the output of the AND gate 261 at a comparator 211, which composed of a bus XOR gate and a OR gate; and (C) the instruction 207, which contains the requirement of matching. The mask 204 of the concurrent bus 109, and the AND gate 261 are optional, and the addressable register 106 may be compared directly with the datum to be matched 205 of the concurrent bus 109 at the comparator 211. The bit output of the comparator is positively asserted if the masked datum at the addressable register 106 differs from the datum to be matched 205 at any bit, which is the “case” of the comparison. The instruction 207 portion of the concurrent bus 109 contains a “condition” code bit 252, which is compared with the “case” of the comparison at a XOR gate 260, whose bit output is positively asserted if the “case” does not equals the “code”. The bit output from the XOR gate 260 is AND combined with the enable bit input 111 at an AND gate 262 whose output asserts the match bit output 112 of the memory element 108.

Additional logic allows the value matching across memory elements when neighboring elements to be matched together. Instead of directly connecting to the AND gate 262, the bit output from the XOR gate 260 is connected to an AND gate 263, to be saved into a one-bit neighboring register 201, whose write control bit is connected to the enable bit input 111 of the memory element 108, and whose bit output is connected to the AND gate 262 which drives the match bit output 112 of the memory element 108. The one-bit neighboring register 201 is connected to the neighboring memory elements through neighborhood connection 114. The concurrent bus 109 sends one more instruction bit “self” 253 with the instruction portion 207 of the concurrent bus 109. Through an OR gate 264, when the instruction bit “self” 253 is positively asserted, the match bit output 112 is positively asserted when a match is found by the XOR gate 260; otherwise, the neighborhood connection from the memory element whose element address is higher 114b also has to be positively asserted to positively assert the match bit output 112. Assuming the width of the addressable register 106 of each of all the memory elements is byte, an algorithm for a search of a string is the following:

(1) Match for equal the addressable register 106 with the highest byte of the value, while positively asserting the instruction bit “self” 253;

(2) In the order from high to low, match for equal the addressable register 106 with the corresponding byte of the value, while negatively asserting the instruction bit “self” 253;

(3) The memory elements whose match bit outputs are positively asserted are the memory elements which have the smallest element addresses of neighboring memory elements which hold the string to be searched.

Similar construct can be built for the algorithm to match for equal in the order from low to high, or from both directions.

FIG. 8b shows a content comparable memory element 108. It has only one addressable register 106, whose content is to be compared. The concurrent bus 109 sends: (A) a mask 204, which is AND combined with the addressable register 106 at a bus AND gate 261; (B) the datum to be compared 205, whose value is compared with the masked datum from the output of the AND gate 261 at a comparator 211; and (C) the instruction 207, which contains the requirement of comparison. The mask 204 of the concurrent bus 109, and the AND gate 261 are optional, and the addressable register 106 may be compared directly with the datum to be compared 205 of the concurrent bus 109 at the comparator 211. The “=” and “>” outputs of the comparator 211 is the “case” of comparing the masked value of the addressable register 106 and the datum to be compared 205, while the first three bits 250 to 252 of the instruction 207 portion of the concurrent bus 109 contains the “condition” code of the match requirements. A matching logic table 260 of standard two-layer logic combines the “case” and the “condition”, to positively assert its output if the “case” matches the “condition”, as demonstrated by the following function table for the match output from the matching logic table 260:

Function of Matching Logic Table

| | Cond | 000 | 001 | 01X | 11X | 100 | 101 |
|---|---|---|---|---|---|---|---|
| Case | Mean | < | > | != | == | <= | >= |
| 00 | < | 1 | 0 | 1 | 0 | 1 | 0 |
| 01 | > | 0 | 1 | 1 | 0 | 0 | 1 |
| 1X | == | 0 | 0 | 0 | 1 | 1 | 1 |

The bit output from the matching logic table 260 is AND combined with the enable bit input 111 at an AND gate 262 whose output asserts the match bit output 112 of the memory element 108

Additional logic allows the value matching across memory elements when each of the items to be matched spans several neighboring elements. Instead of directly connecting to the AND gate 262, the bit output from the matching logic table 260 is connected to an AND gate 263, to be saved into a one-bit neighboring register 201, whose write control bit is connected from the enable bit input 111 of the memory element 108, and whose bit output is connected to the AND gate 262 which drives the match bit output 112 of the memory element 108. The one-bit neighboring register 201 is connected to the neighboring memory elements through neighborhood connection 114. The concurrent bus 109 sends three more instruction bits: “self” 253, “transfer” 254, and “select” 255, with the instruction 207 portion of the concurrent bus 109. When the instruction bit “select” 255 is positively asserted, the neighborhood connection from the memory element whose element address is immediately higher 114b is selected to the output of a multiplexer 265; otherwise, the neighborhood connection from the memory element whose element address is immediately lower 114a is selected. Through an OR gate 264, when the instruction bit “self” 253 is positively asserted, the output of the AND gate 263 is positively asserted when a matched is found by the matching logic table 260; otherwise, the output of the multiplexer 265 also has to be positively asserted to positively assert the output of the AND gate 263. Through a multiplexer 266 and a AND gate 267, when the instruction bit “transfer” 254 is positively asserted, and the neighboring register 201 is also positively asserted, the output of the multiplexer 265 is saved into the neighboring register 201; otherwise, the output of the AND gate 263 is saved into the neighboring register 201.

For simplicity of discussion: (A) the bit width of the addressable register 106 in each memory element is byte; (B) each item contains M neighboring memory elements, which are denoted as (M−1)th to 0th in the order of from high to low in element address containing (M−1)th to 0th significant bytes of the value of the item; (C) the value to be matched is a M-byte unsigned value; and (D) the action of setting the general decoder 110 accordingly is omitted, which is somewhat obvious.

An algorithm for an equal matching is the following:

(1) For all the (M−1)th memory elements of all the items, match for equal the addressable register 106 with the (M−1)th significant byte of the value, while: (A) positively asserting the instruction bit “self” 253; and (B) negatively asserting the instruction bit “transfer” 254. Step (1) positively asserts the neighboring registers 201 of all the (M−1)th memory elements when each of their addressable registers 106 has value equal to the (M−1)th significant byte of the value to be matched.

(2) Letting j be (M−2), for all the jth memory elements of all the items, match for equal the addressable register 106 with the jth byte of the value, while: (A) negatively asserting the instruction bit “self” 253; (B) negatively asserting the instruction bit “transfer” 254; and (C) positively asserting the instruction bit “select” 255;. Step (2) positively asserts the neighboring registers 201 of each of all the jth memory elements when: (A) the addressable register 106 has value equal to the jth significant byte of the value to be matched, and (B) the neighboring memory element of (j+1)th significance has positively asserted neighboring register 201.

(3) Repeat step (2) with j decreased from (M−2) to 0. Step (3) positively asserts the neighboring registers 201 of the consecutive memory elements of each of all the array items whose addressable registers 106 all have values equal to the corresponding bytes of the value to be matched from highest significance.

(4) The array items which equal the value to be matched have their neighboring registers 201 of 0th memory elements positively asserted.

An algorithm to compare the value of all the array items with a value to be matched for a requirement other than (A) equal, or (B) unequal, is the following:

(1) For all the (M−1)th memory elements of all the items, match for equal the addressable register 106 with the (M−1)th significant byte of the value, while: (A) positively asserting the instruction bit “self” 253; and (B) negatively asserting the instruction bit “transfer” 254. Step (1) positively asserts the neighboring registers 201 of all the (M−1)th memory elements when each of their addressable register 106 has value equal to the (M−1)th significant byte of the value to be matched.

(2) Letting j be (M−2), for all the jth memory elements of all the items, match for equal the addressable register 106 with the jth byte of the value, while: (A) negatively asserting the instruction bit “self” 253; (B) negatively asserting the instruction bit “transfer” 254; and (C) positively asserting the instruction bit “select” 255;. Step (2) positively asserts the neighboring registers 201 of each of all the jth memory elements when: (A) the addressable register 106 has value equal to the jth significant byte of the value to be matched, and (B) the neighboring memory element of (j+1)th significance has positively asserted neighboring register 201.

(3) Repeat step (2) with j decreased from (M−2) to 1. Step (3) positively asserts the neighboring registers 201 of the consecutive memory elements of each of all the array items whose addressable registers 106 all have values equal to the corresponding bytes of the value to be matched from highest significance.

(4) For all the 0th memory elements of all the items, match for the requirement the addressable register 106 with the 0th significant byte of the value to be matched, while: (A) positively asserting the instruction bit “self” 253; and (B) negatively asserting the instruction bit “transfer” 254. Step (4) positively asserts the neighboring registers 201 of the 0th memory elements when the addressable register 106 has value satisfying the match requirement with the 0th significant byte of the value to be matched.

(5) Letting j be 1, for all the jth memory elements of all the items, match for the requirement the addressable register 106 with the jth byte of the value to be matched, while: (A) positively asserting the instruction bit “self” 253; (B) positively asserting the instruction bit “transfer” 254; and (C) negatively asserting the instruction bit “select” 255. When a neighboring register 201 is originally positively asserted, it is filled with the value of the neighboring register 201 from the neighboring memory element of (j−1)th significance; otherwise, it is positively asserted when the addressable register 106 has value satisfying the match requirement with the jth significant byte of the value to be matched.

(6) Repeat Step (5) with j increased from 1 to (M−1). At last, the match bit outputs 112 from the (M−1)th memory elements of all the items are positively asserted when the array item which is held by neighboring memory elements matches the value to be matched according to the requirement.

The above algorithm can be extended easily to array each item of which contains memory elements whose addressable registers 106 have width other than byte, or whose content significance is in reverse order with the element address, or matching signed values.

Instead of comparing the value of a register and a value to be matched on the concurrent bus 109, it is also possible the matching is between two addressable registers 106 within each memory elements.

When the content of the enabled memory elements are distinguished, content matchable memory has three ways to collect the positively asserted match bit outputs 112 using:

(1) a priority encoder 113 to find either the highest or the lowest element address of the match bit outputs 112 which have been positively asserted.

(2) a parallel counter 113 to count the match bit outputs 112which have been positively asserted.

(3) the combination of (1) and (2).

An algorithm for enumerating matched array items is:

(1) Assert positively the match bit outputs 112 of all the matched items concurrently.

(2) Set the priority of the priority encoder 113 to be from high to low.

(3) If the no-hit bit output of the priority encoder 113 is positively asserted, all the matched items have been enumerated, and the enumerating algorithm should be terminated.

(4) Read the address output of the priority encoder 113, which contains the highest element address of the matched item between the start address and the end address.

(5) Set the end address to the item whose element address is immediately lower than that of the item which has been found in step (4).

(6) Repeat step (3) to step (5).

It is easy to design an alternative algorithm similar to the above algorithm based on the low-to-high priority of the priority encoder 113. Due to the design of the general decoder 110, changing its start address input may be less efficient than changing its end address input.

An algorithm for counting matched array items is:

(1) Assert positively the match bit outputs 112 of all the matched items concurrently.

(2) Read the count output of the parallel counter 113, which contains the count of the matched memory elements.

An algorithm to construct a histogram of M sections is:

(1) Designate a variable CNT_HIGH.

(2) Designate a variable CNT_LOW.

(3) Match for smaller all the items with the upper limit of the smallest section.

(4) Read the count output of the parallel counter 113 into CNT_LOW, which contains the histogram count of the smallest section.

(5) Let j be 1, match for smaller all the items with the upper limit of the jth section.

(6) Read the count output of the parallel counter 113 into CNT_HIGH.

(7) Subtracting CNT_LOW from CNT_HIGH to obtain the histogram count of the jth section.

(8) Copy CNT_LOW from CNT_HIGH.

(9) Repeat Step (5) to (8) for j from 2 to (M−1).

(10) Subtracting CNT_HIGH from the total count of the items to obtain the histogram count of the largest section.

The histogram of the data can be used to estimate the sum and the distribution of the data.

It is possible that the concurrent bus 109 sends no instruction 207, and the matching is done in a predefined manner, such as (A) always searching for equal between the content of the addressable register 106 of each of all the enabled memory elements and the condition datum 205 of the concurrent bus 109, or (B) always searching for equal between the contents of two addressable registers 106 of each of all the enabled memory elements. The usefulness of such arrangement is limited.

Parallel Comparator

To facilitate quick value comparison, a parallel comparator may be used as the comparator 211 in the memory elements 108. An example of 4-bit parallel comparator is shown in FIG. 9. A parallel comparator inputs two numbers, X=(X[2\hat{ }N−1] . . . X[0]), and Y=(Y[2\hat{ }N−1] . . . Y[0]), in which X[j] and Y[j] denote the jth significant bit of the input numbers of bit width 2\hat{ }N. When X and Y are equal, the parallel comparator positively asserts its equal bit output “X=Y”. Otherwise, it positively asserts its larger bit output “X>Y” when X is larger than Y, or negatively asserts the larger bit output “X>Y” when X is smaller than Y, and outputs the largest bit significance of the X and Y difference at its address output A=(A[N−1] . . . A[0]), in which A[j] denotes the jth significant bit of the address A of bit width N. In the first step, each pair of X[j] and Y[j] are compared to obtain G[j] and L[j], which are positively asserted when X[j]>Y[j] and X[j]<Y[j] respectively, as:

G[j]=X[j] !Y[j];

L[j]=!X[j] Y[j];

In the second step, the corresponding bits of G and L are OR-combined to obtain the exclusive-OR combination Z[j] of X[j] and Y[j], as:

Z[j]=G[j]+L[j];

In the third step, each of all the bits of Z is connected to the input bit of an encoder 271 of high-to-low priority with the bit's significance in Z being the same as the input bit's address of the encoder 271, the address at the address output (A[N−1] . . . A[0]) of the encoder 271 thus contains the most significance of the bit at where X and Y differs, and the no-hit bit output of the encoder 271, which is the equal bit output “X=Y” of the parallel comparator, is positively asserted when X and Y are equal.

In the forth step, the address output of the encoder is connected to the address input of a multiplexer 272. Each of all the bits of G is connected to the input bit of the multiplexer with the bit's significance in G being the same as the input bit's address, so that the bit output of the multiplexer 272, which is the larger bit output “X>Y” of the parallel comparator, is positively asserted when X is larger than Y, or negatively asserted when X is smaller than Y.

Parallel Adder

A parallel adder adds two numbers X and Y into a number S in two steps:

(1) Adds all corresponding bits of X and Y simultaneously without considering carrying over from other bits. Let n denote the nth bit, Z denote the bitwise XOR combination of X and Y, and C denote the carry number:

Z[n]=X[n] XOR Y[n]=(X[n]+Y[n])!(X[n] Y[n]);

C[n]=X[n−1] Y[n−1], with C[0] as carry input;

IF Z[n−1]=1 THEN C[n]=0; IF C[n]=1 THEN Z[n−1]=0;

(2) Adds the Z and C into S. Let “1 . . . 1” denotes a continuous 1 of bits of any length, and let “?” denotes an unknown value, the general cases for adding any fragment of Z and C bits is:

Parallel Addition Cases

Case

| | I | II | III | IV |
|---|---|---|---|---|
| Z | 0 | 00...0 | 01...10 | 01...10 |
| C | 0 | 1...10 | 0...01? | 0...00? |
| S | ? | 1...1? | 10...0? | 01...1? |

Case I and II show that whenever Z[n] is 0, there is no carry over beyond this bit. Case III and IV shows how carry is generated. The general equations for the sum S are:

A[n,j]=C[n−j] Π_{k=1 to j}Z[n−k];

A[n]=Σ_{j=1 to n}A[n,j];

S[n]=!Z[n] C[n]+Z[n] !C[n] !A[n]+!Z[n] A[n];

The equation of A[n] defines the carry look-ahead logic of the parallel adder, which can be implemented by an OR gate which adds the outputs from a series AND gate, each of which implements an A[n,j] of a different j. Due to large number of inputs, simplified AND and OR gate symbols are used, which are commonly used for transmission gate logic. FIG. 10 shows the examples of the standard and simplified three-input AND gate symbol. FIG. 11 shows an example of a 4-bit parallel adder.

A by-product of the above parallel adder implementation is the outputs for the bitwise AND, OR, and XOR outputs of X and Y.

Parallel Counter

As described earlier, either a priority encoder or a parallel counter or both may be used in concurrent matching operations. A priority encoder is a standard device. A parallel counter concurrently counts the bit inputs which are positively asserted simultaneously and outputs the count at its output. An N-bit parallel counter has 2\hat{ }N bit inputs and N-bit output.

A parallel counter can be constructed using parallel adders in binary tree construct, in which each parallel adder counts two inputs to its output at each tree node. The binary tree construct is made of layers of notes of same parallel adders. The jth layer contains 2\hat{ }(N−j) j-bit parallel adders, each of which adds two j-bit inputs X=(X[j] . . . X[0]) and Y=(Y[j] . . . Y[0]) from the previous layer, and outputs (j+1)-bit output S=(S[j+1] S[j] . . . S[0]) to the next layer. FIG. 12 shows the binary tree construct of a 4-bit parallel counter comprising 16 bit inputs, a 1st layer 151 of 8 1-bit parallel adders, a 2nd layer 152 of 4 2-bit parallel adders, a 3rd layer 153 of 2 3-bit parallel adders and a 4th layer 154 of 1 4-bit parallel adders.

In the following tables, the item at the first column of the first row marks the layer number, the first row contains the values for X, the first column contains the values for Y, and the rest items contains the corresponding bit output of the parallel adder:

1st layer 1-bit adder

| (1) | 0 | 1 |
|---|---|---|
| 0 | 00 | 01 |
| 1 | 01 | 10 |

2nd layer 2-bit adder

| (2) | 00 | 01 | 10 |
|---|---|---|---|
| 00 | 000 | 001 | 010 |
| 01 | 001 | 010 | 011 |
| 10 | 010 | 011 | 100 |

3rd Layer 3-Bit Adder

| (3) | 000 | 001 | 010 | 011 | 100 |
|---|---|---|---|---|---|
| 000 | 0000 | 0001 | 0010 | 0011 | 0100 |
| 001 | 0001 | 0010 | 0011 | 0100 | 0101 |
| 010 | 0010 | 0011 | 0100 | 0101 | 0110 |
| 011 | 0011 | 0100 | 0101 | 0110 | 0111 |
| 100 | 0100 | 0101 | 0110 | 0111 | 1000 |

As a general rule, when the (j+1)th bit output is positively asserted for a j-bit parallel adder in a jth layer, its other bit outputs are negatively asserted. There is also no carry bit input. Thus, the parallel adders on each node of the binary tree of the parallel counter can be simplified accordingly by: (A) removing the carry look-ahead logic for the most significant bit; and (B) starting the carry look-ahead logic from the 1st bit. FIG. 13 shows such a 4-bit parallel counter.

An alternative way for constructing a small-scale parallel counter of high speed is to: (1) use resistors to convert logic inputs into currents, (2) use GHz op-amp to add these currents together and convert the current sum to voltage, then (3) use GHz D/A converter to convert the voltage to binary number. A 3-bit parallel counter of such construct is shown in FIG. 14. In the first stage, the currents of 7 bit inputs (D6 D5 D4 D3 D2 D1 D0) driving 7 resisters of identical resistance R are summed up by the first op-amp 131, which has a feedback resistor of ¼ R. When the count of the positively asserted bit input is equal to or larger than 4, the voltage at the output of the first op-amp 131 is equal or larger than the voltage of logic 1, thus the output C2 of the first analog comparator 132 is positively asserted, which is the most significant bit of the counter output; otherwise, C2 is negatively asserted. Through analog switches 133 and 135, when C2 is positively asserts, a voltage of logic 1 is subtracted from the output of the first op-amp 131 by a second op-amp 134; otherwise, the output of the first op-amp 131 is passed directly to the next stage. The input at the next stage is scaled up by 2-fold by the third op-amp 136, to find the bit C1 of the counter output by a second analog comparator 137. Same procedure goes on until all bits of the counter output are found. In this way, a fast parallel counter is constructed with fairly small number of opamps. Such scheme can be extended to 255-inputs and 8-bit outputs using 16 op-amps, 16 analog switches and 8 analog comparators.

A (2N)-bit parallel counter of slightly slower speed can be made of three layers of N-bit parallel counters. An example of constructing a 6-bit parallel counter using 3-bit parallel counters is shown in FIG. 15. The first layer 141 is consisted of (2\hat{ }N+1) N-bit parallel counters counting (2\hat{ }(2N)−1) bit inputs. Out of them, the corresponding digit of the counter outputs of (2\hat{ }N−1) smaller parallel counters are counted by N smaller parallel counters in the second layer 142. For an example, a second-layer N-bit counter 144 counts the 1st bit outputs of the first layer N-bit counters. Except their most significant bits, the counter outputs of the rest two smaller parallel counters in the first layer are counted by an additional N-bit parallel counter 145 in the second layer. The outputs from the 2nd layer N-bit counters 142 are added together by several smaller parallel counters connected as ripple 1-bit adders in the 3rd layer 143, each of them functions like a multiple inputs and multiple carry outputs 1-bit adder. For an example, a third-layer N-bit counter 146 is connected as a multiple carry-in and multiple carry-out 1-bit adder for the 2nd bit output of the (2N)-bit counter. A conventional 1-bit adder 147 may be used for the 0th bit output of the (2N)-bit counter. Using this technique, a 16-bit output parallel counter of 6-cycle delay can be made of two hundred and sixty-eight 8-bit output parallel counters, and one 6-bit output parallel counter.

Multi-Channel Multiplexer and Demultiplexer

A multi-channel multiplexer selects a channel width number of consecutive bit inputs starting from a bit address. When the channel width is non-zero, the bit address not only selects the corresponding bit input to the LSB output, but also the bit input which has immediately higher bit address to the next-to-LSB output, and so forth. A multichannel demultiplexer is the functionally reverse of the corresponding multi-channel multiplexer. An example of 8-input 4-channel multiplexer is shown in FIG. 16. The channel inputs are (X7 X6 X5 X4 X3 X2 X1 X0). The Channel outputs are (Z3 Z2 Z1 Z0). The channel width selections are (W1 W0). The channel address inputs are (A2 A1 A0). (A2 A1 A0) selects one of (X7 X6 X5 X4 X3 X2 X1 X0) as Z0 in the same manner as a normal multiplexer. When either W1 or W0 is positively asserted, (A2 A1 A0) selects one of (X7 X6 X5 X4 X3 X2 X1) as Z1, which has immediately higher input bit address than Z0. When W1 is positively asserted, (A2 A1 A0) selects one of (X7 X6 X5 X4 X3 X2) as Z2, which has immediately higher input bit address than Z1. When both W1 and W0 are positively asserted, (A2 A1 A0) selects one of (X7 X6 X5 X4 X3) as Z3, which has immediately higher input bit address than Z2. Thus, the number of valid bit outputs is determined by the value of the channel width selections (W1 W0). The corresponding 8-output 4-channel demultiplexer is shown in FIG. 17. The channel inputs are (X3 X2 X1 X0). The Channel outputs are (Z7 Z6 Z5 Z4 Z3 Z2 Z1 Z0). The channel width selections are (W1 W0). The channel address inputs are (A2 A1 A0). (A2 A1 A0) selects one of (Z7 Z6 Z5 Z4 Z3 Z2 Z1 Z0) from X0 in the same manner as a normal demultiplexer. When either W1 or W0 is positively asserted, (A2 A1 A0) selects one of (Z7 Z6 Z5 Z4 Z3 Z2 Z1) from X1, which has immediately higher input bit address than X0. When W1 is positively asserted, (A2 A1 A0) selects one of (Z7 Z6 Z5 Z4 Z3 Z2) from X2, which has immediately higher input bit address than X1. When both W1 and W0 are positively asserted, (A2 A1 A0) selects one of (Z7 Z6 Z5 Z4 Z3) from X3, which has immediately higher input bit address than X2. Thus, the number of valid output channels is determined by the value of the channel width selections (W1 W0).

Construct of a Database/Math Memory Element

The memory elements are the basic units within a CP memory that store and process data, each of which comprises preferably at least one addressable registers, possibly other registers, a control unit, and some processing power. FIG. 18 shows the memory element construct of a math memory, which could be either math 1D memory or math 2D memory, which only differs in number of neighborhood connections. It can be turned into the memory element of a database memory by deleting components from it, as described later in this Description.

Most conventional massive parallel architectures implore bit serial operation to save semiconductor construct on each processing element. The CP memory may use some new hardware components such as parallel comparator and multi-channel multiplexer and multi-channel demultiplexer, or improved hardware component such as paraller adder, to implore bit parallel operation to improve the performance without paying a high price in semiconductor construct for each processing element.

The registers within memory element can be categorized as either addressable register or internal register, depending on whether it is accessible by the exclusive bus 105 and thus from outside the CP memory using the register address of the register. All the registers in FIG. 18 are addressable registers. In this way, while the CP memory is concurrently processing one set of registers, the other set of registers can be prepared for another task by exclusive access means such as direct memory access, since the exclusive bus 105 and the concurrent bus 109 within a CP memory can work independently from each other.

Some registers have special functions.

(1) One register of the memory element is a neighboring register 201, which is connected concurrently to neighboring memory elements through neighborhood connections 114. Such connections from different two neighboring memory elements are 114a and 114b respectively for a math 1D memory or a database memory. A math 2D memory has four such connections from different four neighboring memory elements in each of its memory elements. Except the neighboring memory element count and the partition of element address into X address and Y address, a math 2D memory is otherwise identical to a math 1D memory.

(2) One register of the memory element is a status register 203. When being activated by the exclusive connection 111 to the enable bit input of the control unit 210, a memory element can have internal states, which is determined by inputs to the control unit 210. Some of the bits of a status register 203 are connected to the control unit 210 through connection 209, and can be set or reset by the control unit 210. The status register 203 contains a carry bit and at least one status bit.

(3) One register of the memory element is an operation register 200. A bit multiplexer/demultiplexer 213, which is a multi-channel multiplexer/demultiplexer, can either selectively read any bit section of the operation register 200 when the write control bit 226 is negatively asserted, or selectively write any bit section of the operation register 200 when the write control bit 226 is positively asserted.

(4) The rest registers 202 of the memory element are data registers. A register multiplexer/demultiplexer 212, which is also a multi-channel multiplexer/demultiplexer, can: either (A) selectively read any bit section of the data registers 202 and the neighboring register 201 of the memory element, the neighboring registers in the neighboring memory elements through the neighborhood connections 114a, 114b, etc, and the data portion 204 from the concurrent bus 109 when the write control bit 225 is negatively asserted, or (B) selectively write any bit section of the data registers 202 and the neighboring register 201 of the memory element when the write control bit 225 is positively asserted.

The concurrent bus 109 carries element instruction to the memory elements in the format of:

“condition: operation width [bit] register[bit]”

The bit width of the operant is the “width” code. The value starts from 0 for bit-serial operation, and ends at one less than the bit width of the operation register 200. It is sent to both the register multiplexer/demultiplexer 212 and the bit multiplexer/demultiplexer 213. as the channel width inputs

One operant is the first “[bit]” code, which is a portion 206 of the concurrent bus 109 that is sent to the bit multiplexer/demultiplexer 213 as the address input. When the write control bit 226 of the bit multiplexer/demultiplexer 213 is negatively asserted, a bit section of the operation register 200 of “width” width starting from bit significance “[bit]” and up is cached at the “read” output 221 of the bit multiplexer/demultiplexer 213 and is denoted as “[bit]” 221.

The other operant is the “register[bit]” code, which is another portion 205 of the concurrent bus 109 that is sent to the register multiplexer/demultiplexer 212 as the address input. The “register” could be any one of: its own neighboring register 201 and data registers 202, its neighbor's neighboring registers 114a, 114b, etc, and the data portion 204 on the concurrent bus 109. The “[bit]” specifies the lowest bit significance of the bit section of “width” width. When the write control bit 225 is negatively asserted, the bit section specified by “register[bit]” is cached at the “read” output 220 of the register multiplexer/demultiplexer 212 and is denoted as “register[bit]” 220. The data registers 202 may form a random access memory of bits so that a selection of bit section may across register boundary.

The “condition: operation” portion 207of the concurrent bus 109 is input into the control unit 210. The “condition” code is the condition for finishing executing the “operation width [bit] register[bit]” portion of the instruction. It is implemented by the inputs into the control unit 210 comprising the connection from the status register 209, the AND- or OR-logic combination 222 of all the bits of “register[bit]” 220 or “[bit]” 221, and the outputs of a comparator 211 which compares the values of the “[bit]” 221 and the “register[bit]” 220

The “condition” code of the instruction can be: (A) none, (B) any one of, (C) the AND or OR combination of any ones from any two categories of:

(1) “ANY register[bit]”, “ALL register[bit]”: If any or all the “register[bit]” 220 bits are positively asserted respectively.

(2) “ANY [bit]”, “ALL [bit]”: If any or all the “[bit]” 221 bits is positively asserted respectively.

(3) <, <=, =, !=, >=, >: If the corresponding value relation between the “register[bit]” 220 and the “[bit]” 221 is satisfied.

(4) R, S: if the status bit of the status register 203 is being negatively or positively asserted respectively.

(5) E, C: if the carry bit of the status register 203 is being negatively or positively asserted respectively. A database memory has no carry bit in the status register 203, thus no this category of “condition” code.

If the condition is not met, the instruction execution terminates before executing the “operation” code, as if the memory element is not activated.

The “operation” code is different for a database memory and a math memory.

The memory elements of a database memory have neither carry bit in its status register 203, nor adder 214, nor operation multiplexer 215, nor op-code outputs 208 of the control units 210. The “register[bit]” 220 is connected directly to the operation result 222. Thus, the set of “operation” code contains at least:

(1) WA (Write address): to positively assert the match bit output 112.

(2) WR (Write): to copy the “register[bit]” 220 to the bit section of the operation register 200 specified by “[bit]”.

(3) RD (Read): to copy the “[bit]” 221 to the bit section of any one of its data registers 202 or its own neighboring register 201 specified by “register[bit]”.

(4) CS (Clear Status): negatively assert the status bit of the status register 203.

(5) SS (Set Status): positively assert the status bit of the status register 203.

The memory element of a math memory is more complex. An adder 214 inputs the “register[bit]” 220, the “[bit]” 221, the carry bit of the status register 203, and outputs the sum to an operation multiplexer 215 while setting the carry bit of the status register 203 accordingly. As by product of adding the “register[bit]” 220 and the “[bit]” 221, the adder 214 also outputs the bitwise AND-, OR- and XOR-combination of the “[bit]” 221 and “register[bit]” 220 to the operation multiplexer 215. The operation multiplexer 215 also inputs the “register[bit]” 220, and the bit-wise complement of the “[bit]” 221. The control unit 210 may select an operation result 222 from an operation multiplexer 215 through an op-code connection 208 and save the operation result 222 to the “[bit]” bit of the operation register 200 by positively asserting the write control bit 226 of the bit multiplexer/demultiplexer 213. As a result, the set of “operation” code contains at least the addition of:

(6) NG (Negate): to select the bitwise complement of the “[bit]” 221 as the output 222 of the operation multiplexer 215, and to copy it to the bit section of the operation register 200 specified by “[bit]”. This operation logically inverts each bits of the bit section of the operation register 200 specified by “[bit]”.

(7) ND (AND): to logically AND combine the corresponding bits of the “register[bit]” 220 and the “[bit]” 221, and to copy the result to the bit section of the operation register 200 specified by “[bit]”.

(8) OR (OR): to logically OR combine the corresponding bits of the “register[bit]” 220 and the “[bit]” 221, and to copy the result to the bit section of the operation register 200 specified by “[bit]”.

(9) XR (XOR): to logically XOR combine the corresponding bits of the “register[bit]” 220 and the “[bit]” 221, and to copy the result to the bit section of the operation register 200 specified by “[bit]”.

(10) AD (Add): to add the values of the “register[bit]” 220 and the “[bit]” 221 with the carry bit of the status register 203, to set the carry bit of the status register 203 from adding, and to copy the result of adding to the bit section of the operation register 200 specified by “[bit]”.

(11) CC (Clear Carry): to negatively assert the carry bit of the status register 203.

(12) SC (Set Carry): to positively assert the carry bit of the status register 203.

The register multiplexer/demultiplexer 212 and the bit multiplexer/demultiplexer 213 enable instant bit-wise shift operations of any amount. Thus, each of all the memory elements of a math memory can carry out multiplication and division using a series of addition, subtraction and shift operations. Other math operations are also possible.

The coding of the element instruction set are designed so that multiple “operation” codes can be carried concurrently by the concurrent bus 109 in a same element instruction for the same “register[bit]” code and the “[bit]” code provided that these “operation” codes may be carried out concurrently without confliction. For an example, the concurrent positively assertion of the write control bit 225 of the register multiplexer/demultiplexer 212 and the write control bit 226 of the bit multiplexer/demultiplexer 213 in the memory elements of a database memory results in exchange the two set of bits of the two registers. Thus, the “operation” codes for “WR” and “RD” should be concurrent for each other.

All element instruction may have same length and uses one clock cycle, so that the memory element circuit can be treated as combinational logic. The control unit 210 sends pulse signal 231, 232, and 233, to other components of a database memory element, or pulse signal 231, 232, 233, 234, and 235 to other components of a math memory element. The timing logic is the following:

(1) The control unit 210 pulses the enable bit input 231 while negatively asserting the write control bit 225 of the bit & register multiplexer/demultiplexer 212, to read “register [bit]” bit section to its “read” output 220. At the same time, the control unit 210 pulses the enable bit input 232 while negatively asserting the write control bit 226 of the bit multiplexer/demultiplexer 213 to read “[bit]” bit section to its “read” output 221.

(2a) The control unit 210 pulses the enable bit input 233 of the comparator 211.

(2b) At the same time, the control unit 210 of a math memory pulses the enable bit input 234 of the adder 214.

(3) If the “condition” code of the instruction is not met, the control unit 210 sends no more timing signals for the instruction cycle, and the instruction execution terminates. Otherwise, the control unit 210 of a math memory pulses the enable bit input 235 of the operation multiplexer 215.

(4) According to the “operation” code, the control unit 210 may: (A) pulse the enable bit input 231 while positively asserting the write control bit 225 of the register multiplexer/demultiplexer 212, or (B) pulse the enable bit input 232 while positively asserting the write control bit 226 of the bit multiplexer/demultiplexer 213, or (C) positively assert the match bit output 112, or (D) combination of (A) and (B), or (E) combination of (A) and (C), or (F) combination of (B) and (C), or (G) combination of (A) and (B) and (C)

Simplification for Discussion

The neighboring registers 201 of all the enabled memory elements are collectively referred to as the neighboring layer. The operation registers 200 of all the enabled memory elements are collectively referred to as the operation layer. The data registers 202 of all the enabled memory elements are collectively referred to as the data layers 202. The status bits and the carry bits of the status registers 203 of all the enabled memory elements are collectively referred to as the status layer and the carry layer, respectively.

In a database memory or a math 1D memory, the neighboring layers of the memory element whose address is immediately lower or immediately higher than that of the memory element which is being operated on is called the left layer 114a and the right layer 114b, respectively. In a math 2D memory, the neighboring layers of the memory element whose Y address is the same as while whose X address is immediately lower or immediately higher than that of the memory element which is being operated on is called the left layer and the right layer, respectively; while the neighboring layers of the memory element whose X address is the same as while whose Y address is immediately lower or immediately higher than that of the memory element which is being operated on is called the bottom layer and the top layer, respectively.

If a database memory contains non-addressable registers, the content of its non-addressable is accessible through its operation register 200 and any one of its addressable registers 106. Thus, all registers are treated as addressable registers 106. And the operation register 200 should be addressable for optimal performance in this case.

The following simplifications are applied only for discussing the usage of the CP memory. They are by no mean the constraints on the construct or application of the CP memory.

Each memory element has only one status bit in its status register 203. Each of its other registers 200, 201, and 202 has enough bit width to hold each datum for the array.

Each memory element has only one neighboring register 201.

An array of total N items is stored in the data layer(s) 202 of a database memory or a math memory, and the status bits of all memory elements are reset initially. The start address and the end address for the general decoder 110 of the memory are defaulted to point to the first and last items of the array respectively, and the carry number for the general decoder of the memory is defaulted to 1.

Use of Database Memory

A database memory provides instant execution of almost all basic operations to manage database tables, each of which is an array of records. The following table compares the order of required instruction cycle count of all basic operations using a conventional random access memory (RAM) vs. using a database memory (DBM): Speed improvement of using database memory

| OPERATION | RAM | DBM |
|---|---|---|
| Delete any item | ˜N | ˜1 |
| Insert a new item | ˜N | ˜1 |
| Match an item | ˜N or log(N) | ˜1 |
| Count matched items | ˜N | ˜1 |
| Enumerate M matched items | ˜N | ˜M |
| Histogram of M sections | ˜N | ˜M |
| Find local max/min | ˜N | ˜1 |
| Find global max/min | ˜N | ˜log(N) |
| Order all items | ˜(N Log(N)) to ˜N\hat{ }2 | ˜sqrt(N) to ˜N |

In the above table, for match using RAM, a normal match requires ˜N instruction cycles; if a index table has been maintained for the item to be matched, the match is done using binary tree search and it requires ˜log(N) instruction cycles.

In the above table, both the average and the worse-case instruction cycles for ordering all items are given.

Use of Math Memory

A math 1D memory can be used instead of a database memory to hold arrays and database tables, providing additional benefit of: (A) counting degree of matching; (B) Find local minimum and maximum using a difference threshold; and (C) provide more efficient sorting algorithm.

The parallel problems can be solved much more efficiently using a math memory (M1M or M2M) than using a conventional random access memory (RAM). The required instruction cycle counts for most common parallel problems are shown in the following:

Speed Improvement of Using 1D Math Memory

| OPERATION | RAM | M1M |
|---|---|---|
| Filter of size M | ˜(N M) | ˜M |
| Sum | ˜N | ˜sqrt(N) |
| Match template of size M | ˜(N M) | ˜M\hat{ }2 |

Speed Improvement of Using 2D Math Memory

| OPERATION | RAM | M2M |
|---|---|---|
| Filter of size (Mx by My) | ˜(Nx Ny Mx My) | ˜(Mx My) |
| Sum | ˜(Nx Ny) | ˜cbrt(Nx Ny) |
| Match template of size (Mx by | ˜(Nx Ny Mx My) | ˜(Mx\hat{ }2 My) |
| My) | | |
| Recognize Line (to 1/D angle) | ˜(Nx Ny D\hat{ }2) | ˜D\hat{ }2 |

Content Moving

An algorithm for deleting the item at a deletion element address is:

(1) Set the start address to one above the deletion element address.

(2) Copy a data layer 202 to the operation layer 200.

(3) Copy the operation layer 200 to the neighboring layer 201.

(4) Set the start address to the deletion element address.

(5) Set the end address to one below the last used memory element 108 of all the database memory.

(6) Copy the operation layer 200 from the right layer 114b.

(7) Copy the operation layer to the same data layer 202.

(8) Repeat step (1) to (7) for all other data layers 202.

An algorithm for inserting a new item to an insertion element address is:

(1) Set the start address to the insertion element address.

(2) Copy a data layer 202 to the operation layer 200.

(3) Copy the operation layer 200 to the neighboring layer 201.

(4) Set the start address to one above the insertion element address.

(5) Set the end address to one above the last used memory element 108 of all the database memory.

(6) Copy the operation layer 200 from the left layer 114a.

(7) Copy the operation layer to the same data layer 202.

(8) Repeat step (1) to (7) for all other data layers 200, to move all the items above the insertion address up by one element.

(9) Copy a datum of the new item from the data bus of the external data bus 102 to the corresponding data register 202 of the memory element 108 at the insertion element address using the exclusive bus 105.

(10) Repeat step (9) until all the data of the new item are copied from the external data bus 102 to the corresponding data registers 202 of the memory element 108 at the insertion element address.

Because of its instant content moving ability, a database memory has all the benefit of a content movable memory. The tables stored in the database memory are truly dynamic, without needs for look-ahead allocation and link list, and at the same time the database memory is closely packed, without being fragmented after extensive insertions and deletions. Instead of the element address of the memory element that stores the record, each record can be referred by its primary key ID, and the actual storage of the data may be managed internally by the database memory.

A math memory has all the benefit of a database memory. Using similar algorithm, a 2D math memory can insert or delete its data based on columns and rows.

Content Matching

An algorithm for matching items is:

(1) Copy the data layer 202 to be matched to the operation layer 200.

(2) Assert positively the status layer.

(3) Match the operation layer 200 with the data portion 204 of the concurrent bus 109, according to the “condition” of the concurrent bus 109, which is the logical opposite of the match requirement, and negatively assert the status layer if the “condition” is met.

(4) If there are further matching conditions, repeat step (3).

(5) The matched items have positively asserted status bits, and further operation may be carried out concurrently on the matched items without knowing their actual positions.

It is easy to design an alternative algorithm similar to the above algorithm based on the match requirement rather than its logical opposite, or combination of the two.

An algorithm for counting matched items is:

(1) Assert positively the match bit outputs 112 of all the matched memory elements 108 concurrently.

(2) The count output of the parallel counter 113 contains the count of the matched memory elements.

An algorithm for enumerating matched items is:

(1) Set the priority of the priority encoder 113 to be from high to low.

(2) Assert positively the match bit outputs 112 of all the matched memory elements 108 concurrently.

(3) If the no-hit bit output of the priority encoder 113 is positively asserted, all the matched memory elements 108 have been enumerated, and the enumerating algorithm is terminated. Otherwise, the the address output of the priority encoder 113 contains the highest element address of the matched memory elements 108 between the start address and the end address.

(4) Set the end address to one less than the element address which has been found in step (3).

(5) Repeat step (3) to step (4).

It is easy to design an alternative algorithm similar to the above algorithm based on the low-to-high priority of the priority encoder 113. Due to the design of the general decoder 110, changing its start address input may be less efficient than changing its end address input.

Because any matching operation in an array of N items stored in a conventional random access memory requires ˜N instruction cycles, traditional databases relies on index tables, each of the index tables stores the sorting order of a field in the original table. During a match on the field, the index tables are matched using a binary-tree search, requiring ˜log(N) instruction cycles, instead of the ˜N instruction cycles required when the original table is matched. When a new record is added, or an existing record is modified, the index tables are modified accordingly. The extensively use of index tables requires a lot of additional memory and processing powers. Especially, all index tables have to be updated properly and promptly, otherwise if any index table contains wrong information, the search results become unreliable, and the database itself may become unstable. Managing index tables is a major tasking in any traditional databases.

When using database memories to store the array, matching items or counting matched items only takes ˜1 instruction cycles. This means not only that the required instruction cycles are greatly reduced, but also that the index tables are no longer required, so that the database can be much more efficient and stable.

The processing power of math memory adds new functionality to the database management. An algorithm for matching items and calculating degrees of matching using a math 1D memory is:

(1) Send a zero to all the memory elements using the concurrent bus 109 and copy it to the operation layer 200.

(2) Match all the memory elements 108 against one requirement.

(3) Send a weight number to all the memory elements using the concurrent bus and add it to the operation layer 200 of all the matched memory elements 108 in step (2).

(4) If there are further matching requirements, repeat step (2) to (3) for all the memory elements 108.

(5) The operation layer 200 contains the degree of matching of the requirements.

Similar algorithm can be constructed using a data base memory which can increment its operation layer 200.

The ability to calculate the degree of matching not only allows exactly match as currently provided by conventional database engine, but also allows quantified fussy match as currently provided by web search engine. The items of the array may be further handled according to their degree of matching.

Content Statistics

An algorithm to construct a histogram of M sections is:

(1) Copy the data layer 202 to be matched to the operation layer 200.

(2) Assert positively the match bit outputs 112 of all the memory elements whose status layer is negatively asserted and whose operation layer 200 is larger than the data portion 204 of the concurrent bus 109, which contains the first section limit from large to small.

(3) The count output of the parallel counter 113 contains the histogram count of the first section.

(4) Assert positively the status layer of all the memory elements whose operation layer 200 is larger than the data portion 204 of the concurrent bus 109. Step (4) masks off those memory elements 108 which have already been counted.

(5) Repeat step (2) to (4) for all the rest section limits from large to small of the M histogram sections.

The histogram of the data can be used to estimate the sum and the distribution of the data.

An algorithm to find the local maximums is:

(1) Copy the data layer 202 to be characterized to the operation layer 200.

(2) Copy the operation layer 200 to the neighboring layer 201.

(3) Assert positively the status layer of all the memory elements each of whose operation layer 200 is larger than the neighboring layer 114 of their neighboring memory elements. This procedure can be carried out in two steps: (A) positively assert the status layer if the operation layer 200 is larger than the neighboring layer 114a of one of their neighboring memory elements; and (B) negatively assert the status layer if the status layer itself is positively asserted and the operation layer 200 is smaller than the neighboring layer 114b of any other of their neighboring memory elements.

An algorithm to find the local minimums can be similarly constructed.

An algorithm to find the local maximums with a difference threshold using a math memory is:

(1) Copy the data layer 202 to be characterized to the operation layer 200.

(2) Copy the operation layer 200 to the neighboring layer 201.

(3) Send the difference threshold to all the memory elements 108 through concurrent bus 109 and add it to the operation layer 200.

(4) Assert positively the status layer of all the memory elements each of whose operation layer 200 is larger than the neighboring layer 114 of their neighboring memory elements.

The algorithm to find the local minimums using difference threshold is similar.

The use of difference threshold reduces the effect of noise presented in the original data when determining the local minimums and maximums.

An open-end binary tree algorithm to find a global upper limit to the data is:

(1) Designate a variable denoted as FOLD, and initiate it with 1.

(2) Designate a variable denoted as ADDR.

(3) Designate a variable denoted as MAX.

(4) Designate a variable denoted as VAL.

(5) Find the local maximums. As a result, the memory elements 108 which are local maximums have status layer positively asserted and operation layer 200 containing data to be characterized.

(6) Set the priority of the priority encoder 113 to be from high to low.

(7) Assert positively the match bit outputs 112 of all the memory elements 108 whose status layer has been positively asserted.

(8) Read the output address of the priority encoder 113 into ADDR.

(9) Read the operation register 200 in the memory element 108 at element address ADDR into MAX.

(10) Let VAL=MAX.

(11) Set the end address to be one less than ADDR.

(12) Assert positively the match bit outputs 112 of all the memory elements 108 whose status layer has been positively asserted and whose operation layer 200 is larger than VAL.

(13) Read the output address of the priority encoder 113. If it contains NULL, a global upper limit is in VAL while the largest known value is MAX at the element address ADDR, and the algorithm terminates. Otherwise, save it into ADDR.

(14) Read the operation register 200 in the memory element 108 at the element address ADDR into MAX.

(15) Let VAL=VAL+(MAX−VAL)*FOLD.

(16) Double the value of FOLD.

(17) Repeat step (11) to (16).

The algorithm can be continued in close-end binary tree manner to find the global maximum of the data, as the following:

(20) Let VAL=(VAL+MAX)/2.

(21) Set the end address to be one less than ADDR.

(22) Assert positively the match bit outputs 112 of all the memory elements 108 whose status layer has been positively asserted and whose operation layer 200 is larger than VAL.

(23) Read the output address of the priority encoder 113. If it contains NULL, VAL contains a better global upper limit, and step (20) to (23) is repeated. Otherwise, save it into ADDR.

(24) Read the operation register 200 in the memory element 108 at the element address ADDR into MAX.

(24) Assert positively the match bit outputs 112 of all the memory elements whose status layer has been positively asserted and whose operation layer 200 is larger than MAX.

(25) Read the output address of the priority encoder 113. If it contains NULL, the global maximum is MAX at address ADDR, and the algorithm terminates. Otherwise, save it into ADDR and repeat step (24) to (26).

To find a upper global limit and the global maximum for a randomly arranged set of {1, 2, 3, . . . N}, the above algorithms take ˜log(N) instruction cycles on average.

An algorithm to find a lower global limit and the global minimum can be similarly constructed.

The ability to quickly find and count the local extreme values, and the ability to quickly find the global limits, the global extreme values, the histogram, the estimated sum of a large set of data means that a database memory or a math memory can be used in statistical processing such as estimating its distribution.

Sorting

Because of its instant match finding ability, a database memory require no index table and much less sorting of data. Still, it is possible to sort data using a database memory with much less instruction cycles than what is required using a conventional random access memory.

An algorithm to see if the array is in order is the following:

(1) Copy the data layer 202 which contains the data to be characterized to the operation layer 200.

(2) Copy the operation layer 200 to the neighboring layer 201.

(3) Set the start address to one more than the first item.

(4) Assert positively the match bit outputs 112 of all the memory elements 108 whose operation layer 200 is smaller than left layer 114a.

(5) Read the count output of the parallel adder 113. If it equals zero or the total item count, the array is already sorted.

The above count output is the disorder count to sort the array into small-to-large order. The disorder count to sort the array into large-to-small order can be found similarly. To sort an array in either way is functionally equivalent—the other sorting order can be achieved by reading from end item to start item of one sorting order. Thus, the two disorder count is compared to select a better sorting order of the two, and the worst case for sorting—to sort an almost sorted array into another order—can be avoided.

There are two ways to disorder an already ordered array: (A) to randomly exchange the adjacent neighboring items, to create local disorder; or (B) to remove and insert an item randomly to another location, to create global disorder. These two kinds of disorders are dealt with by local exchange sorting algorithm and global moving sorting algorithm respectively.

A local exchange sorting algorithm concurrently exchanges all the adjacent two items into correct order. An algorithm to exchange once the adjacent even and odd numbered items toward small-to-large order is:

(1) Carry out the algorithm to find out the disorder count. If it is zero, the sorting algorithm terminates. As a result, both the operation layer 200 and the neighboring layer 201 contain data to be characterized.

((2) Set the carry number to 2.

(3) Set the start address to one more than the first item.

(4) Copy the operation layer 200 from the left layer 114a if the latter is larger.

(5) Exchange the operation layer 200 and the data layer 202 to be characterized if they are different.

(6) Set the start address to the first item.

(7) Set the end address to one less than the last item if the total item count is odd.

(8) Copy the operation layer 200 from the right layer 114b if the latter is smaller.

(9) Exchange the operation layer 200 and the data layer 202 to be characterized if they are different. If each item contains only one data layer 202, the algorithm terminates.

(10) Assert positively the status layer when the operation layer 200 and the data layer 202 to be characterized are different.

(11) Copy one of the other data layers 202, which is the data layer to be transferred, to the operation layer 200.

(12) Copy the operation layer 200 to the neighboring layer 201.

(13) Set the start address to one more than the first item.

(14) Set the end address to the last item if the total item count is odd.

(15) Copy the operation layer 200 from the left layer 114a if the status layer is positively asserted.

(16) Exchange the operation layer 200 and the data layer 202 to be transferred.

(17) Copy the operation layer 200 to the neighboring layer 201.

(18) Set the start address to the first item.

(19) Set the end address to one less than the last item if the total item count is odd.

(20) Copy the operation layer 200 from the right layer 114b if the status layer is positively asserted.

(21) Copy the operation layer 200 to the data layer 202 to be transferred.

(22) Step (11) to (21) exchanges the data layer 202 to be transferred of the adjacent even and odd numbered items which need to be exchanged. Repeat step (11) to (21) to transfer each of all the other data layers.

An example of such sorting of a one-layer array is the following:

(1)

| | | | | | | | | |
|---|---|---|---|---|---|---|---|---|
| Data | 5 | 4 | 3 | 2 | 2 | 2 | 6 | 1 |
| Layer | | | | | | | | |
| Operation | 5 | 4 | 3 | 2 | 2 | 2 | 6 | 1 |
| Layer | | | | | | | | |
| Neighbor | 5 | 4 | 3 | 2 | 2 | 2 | 6 | 1 |
| Layer | | | | | | | | |

(4)

| | | | | | | | | |
|---|---|---|---|---|---|---|---|---|
| Data | 5 | 4 | 3 | 2 | 2 | 2 | 6 | 1 |
| Layer | | | | | | | | |
| Operation | 5 | 5 | 3 | 3 | 2 | 2 | 6 | 6 |
| Layer | | | | | | | | |
| Neighbor | 5 | 4 | 3 | 2 | 2 | 2 | 6 | 1 |
| Layer | | | | | | | | |

(5)

| | | | | | | | | |
|---|---|---|---|---|---|---|---|---|
| Data | 5 | 5 | 3 | 3 | 2 | 2 | 6 | 6 |
| Layer | | | | | | | | |
| Operation | 5 | 4 | 3 | 2 | 2 | 2 | 6 | 1 |
| Layer | | | | | | | | |
| Neighbor | 5 | 4 | 3 | 2 | 2 | 2 | 6 | 1 |
| Layer | | | | | | | | |

(8)

| | | | | | | | | |
|---|---|---|---|---|---|---|---|---|
| Data | 5 | 5 | 3 | 3 | 2 | 2 | 6 | 6 |
| Layer | | | | | | | | |
| Operation | 4 | 4 | 2 | 2 | 2 | 2 | 1 | 1 |
| Layer | | | | | | | | |
| Neighbor | 5 | 4 | 3 | 2 | 2 | 2 | 6 | 1 |
| Layer | | | | | | | | |

(9)

| | | | | | | | | |
|---|---|---|---|---|---|---|---|---|
| Data | 4 | 5 | 2 | 3 | 2 | 2 | 1 | 6 |
| Layer | | | | | | | | |
| Operation | 5 | 4 | 3 | 2 | 2 | 2 | 6 | 1 |
| Layer | | | | | | | | |
| Neighbor | 5 | 4 | 3 | 2 | 2 | 2 | 6 | 1 |
| Layer | | | | | | | | |

An algorithm to exchange the adjacent odd and even numbered items once into small-to-large order can be similarly constructed. The local exchange sorting algorithm comprises of repeated alternative execution of algorithm to exchange once the adjacent items of (A) even and odd numbered, and (B) odd and even numbered. Using this sorting algorithm alone can sort an array in no more than ˜N instruction cycles.

The local exchange sorting algorithm may not be efficient enough because the array may be nearly sorted except a very few difficult items which still walk one element at a time toward their final destinations. Using a math 1D memory, or a database memory which can increment or decrement its operation layer, an improved algorithm awards walks in correct direction with jumps:

(1) A minimal and a maximal cap of the array are inserted as the first and last items, respectively.

(2) Each item carries a walk number, which is initiated to 0.

(3) Designate a threshold M for the walk number.

(4) Check if the array is already sorted. If yes, terminate the algorithm by removing the first and last items.

(5) Carry out one local exchange sorting toward small-to-large order. If an item walks to right, its walk number is increased by 1; otherwise, if it walks to left, its walk number is decreased by 1.

(6) By content matching means, with the priority from right to left, enumerate an item whose walk number reach +M.

(7) The value of each such item is compared with all the other items to its right using content matching means, with the priority from left to right, and the leftmost item whose value is not smaller than such item is found.

(8) If the newly found item has not a negative walking number, such item is moved to the left of the newly found item. The walk number of such item is reset to 0.

(9) By content matching means, with the priority from left to right, enumerate an item whose walk number reach −M.

(10) The value of each such item is compared with all the other items to its left using content matching means, with the priority from right to left, and the rightmost item whose value is not larger than such item is found.

(11) If the newly found item has not a positive walking number, such item is moved to the right of the newly found item. The walk number of such item is reset to 0.

(12) Repeat step (6) to (11) until there is no item whose walk number reaches either +M or −M.

(13) Repeat step (4) to (12).

To order a randomly arranged set of {1, 2, 3. . . N}, when M equals to sqrt(N), the above algorithm takes ˜sqrt(N) instruction cycles on average.

A global moving sorting algorithm removes disordered items in a nearly sorted array and inserts them to proper place. It does this by analyzing “topography” of the sorting disorders. Peak and valley are used to describe sorting disorder. A peak 331 is an item whose data layer to be characterized contains value larger than those of its both neighbors', while a valley 341 is an item whose data layer to be characterized contains value smaller than those of its both neighbors'. For the small-to-large sorting order, a true valley or a true peak has right neighbor not smaller than left neighbor. Otherwise they are false valley or false peak respectively. General cases of sorting disorder are shown in FIG. 19, which shows:

(1) Single true valley: Case 321 is identified by a true valley 342with an adjacent false peak 332 to the left. When the true valley 342 is removed, the false peak 332 disappears also.

(2) Single true peak: Case 322 is identified by a true peak 333 with an adjacent false valley 343 to the right. When the true peak 333 is removed, the false valley 343 disappears also.

(3) A section of data which is ordered in incorrect order: Case 323 is identified by a lone true peak 334 to its left, and a lone false valley 344 to its right. Case 324 is identified by a lone false peak 335 to its left, and a lone true valley 345 to its right. Case 323 and 324 can be merged together, with a lone true peak 334 to its left, and a lone true valley 345 to its right. Remove one true peak or valley from the end of any sections generates another true peak or valley, until the whole section is removed. Any of these sections may contain lone pairs of apparently false valley with an adjacent apparently true peak to the right, or lone pairs of apparently true valley with an adjacent apparently false peak to the right. Because the topography is reversed from that of single true valley or peak, the apparently false valley or peak is actually true, while the apparently true valley or peak is actually false.

(4) A section of data which is ordered in correct order but in incorrect increment: Both Case 325 and 326 are identified by an adjacent pair of false peak and false valley, as 336 and 346, and 337 and 347. Case 325 and 326 can merge together. Applying a local exchange sorting algorithm separates out either a true peak or a true valley or both, from the ends of the sections. Any of these sections may contain a single true valley or peak within the section.

The leftmost true valley item can be moved to the right of the first item to its left which is smaller than it, or to the left end of the array, in ˜1 instruction cycles. The rightmost true peak item can be moved to the left of the first item to its right which is larger than it, or to the right end of the array, in ˜1 instruction cycles. Applying these two procedures is the global moving sorting algorithm, which may also be used between the applications of local exchange sorting algorithm to accelerate the sorting.

Local Operations

The connectivity and arithmetic ability of a math memory enables local operations, such as filtering. A local operation involving M neighbors takes ˜M instruction cycles generally, independent of the total array item count N.

For simplicity of following discussion, the neighboring layer 201 contains the data to be characterized, or the content of the memory element. A special 1D vector of odd-number of items is used to describe the content composition of the operation layer 200 of all the enabled memory elements after a concurrent 1D local operation in a 1D math memory. The center item describes the content originated from the element itself and is indexed as 0. The item left to the center item describes the content originated from the left neighbor of the element and is indexed as −1. The item right to the center item describes the content originated from the left neighbor of the element and is indexed as +1. So forth. For an example, (1) denotes the content of all the enabled memory elements; (1 0 0) denotes the content of left neighbors to all the enabled memory elements; (1 1 0) denotes adding the content of left neighbors to the content of all the enabled memory elements; and (1 1 1) denotes three point average for all the enabled memory elements.

Two successive operations can be additive if both of them use the operation layer accumulatively, such as:

(1 1 0)=(1)+(1 0 0);

Mathematically, a + operation is defined as:

C=A+B: C[i]=A[i]+B[i];

The + operation satisfies:

A+B=B+A;

(A+B)+C=A+(B+C);

When the operation layer 200 is copied to or exchanged with the neighboring layer 201, the successive operations are no longer addictive. For example, a 3-point (1 2 1) Gaussian averaging algorithm is:

(1) Copy the data layer 202 to be averaged to the operation layer 200.

(2) Copy the operation layer 200 to the neighboring layer 201.

(3) Set the start address to be one more than the first item.

(4) Set the end address to be one less than the last item.

(5) Add the left layer 114a to the operation layer 200.

(6) Copy the operation layer 200 to the neighboring layer 201.

(7) Add the right layer 114b to the operation layer 200. The result is in the operation layer.

In the above algorithm, the additive result of step (2) and (5) is subjected to Step (7) due to Step (6). Without step (6), step (7) is also additive to step (2) and (5), and the algorithm result is (1 1 1). When the result of a first operation A undergoes a second operation B, the overall operation C is expressed mathematically as:

C=A # B: C[i]=Σⱼ(A[i+j] B[i−j]);

The # operation satisfies:

A # B=B # A;

(A # B)# C=A #(B # C);

The # and + operations satisfy:

(A+B)# C=(A # B)+(A # C);

The 3-point (1 2 1) Gaussian averaging algorithm is expressed as:

(1 2 1)=(1 1 0)#(0 1 1);

A 5-point Gaussian averaging is:

(1 2 4 2 1)=(1 1 1)#(1 1 1)+(1);

The corresponding algorithm can be read from the mathematical expression, as:

(1) Copy the data layer 202 to be averaged to the operation layer 200.

(2) Copy the operation layer 200 to the neighboring layer 201.

(3) Set the start address to be one more than the first item.

(4) Set the end address to be one less than the last item.

(5) Add the left layer 114a to the operation layer 200.

(6) Add the right layer 114b to the operation layer 200. Step (4) to (6) carry out the first (1 1 1) operation.

(7) Exchange the operation 200 and the neighboring layers 201. Step (7) carries out the # operation.

(8) Add the left layer 114a to the operation layer 200.

(9) Add the right layer 114b to the operation layer 200. Step (7) to (9) carry out the second (1 1 1) operation.

(9) Add the neighboring layer 201 to the operation layer 200. Step (9) carries out the “+(1)” operation.

This concept is extendable to 2D local operations, such as a 9-point Gaussian averaging:

$$( \begin{matrix}1 & 2 & 1 \\ 2 & 4 & 2 \\ 1 & 2 & 1\end{matrix} ) = \begin{matrix}( \begin{matrix}1 & 1 & 0\end{matrix} ) & \# & ( \begin{matrix}0 & 1 & 1\end{matrix} ) & \# & ( \begin{matrix}0 \\ 1 \\ 1\end{matrix} ) & \# & ( \begin{matrix}1 \\ 1 \\ 0\end{matrix} )\end{matrix} ;$$

The corresponding algorithm can be read from the mathematical expression, as:

(1) Copy the data layer 202 to be averaged to the operation layer 200.

(2) Copy the operation layer 200 to the neighboring layer 201.

(3) Set the start X address to be one more than the left boundary.

(4) Set the end X address to be one less than the right boundary.

(5) Set the start Y address to be one more than the bottom boundary.

(6) Set the end Y address to be one less than the top boundary.

(7) Add the left layer to the operation layer 200.

(8) Copy the operation layer 200 to the neighboring layer 201.

(9) Add the right layer to the operation layer 200.

(10) Copy the operation layer 200 to the neighboring layer 201.

(11) Add the bottom layer to the operation layer 200.

(12) Copy the operation layer 200 to the neighboring layer 201.

(13) Add the top layer to the operation layer 200.

Or a 9-point 0-degree Sober filtering:

$$( \begin{matrix}- 1 & 0 & 1 \\ - 2 & 0 & 2 \\ - 1 & 0 & 1\end{matrix} ) = \begin{matrix}( \begin{matrix}- 1 & 0 & 1\end{matrix} ) & \# & ( \begin{matrix}0 \\ 1 \\ 1\end{matrix} ) & \# & ( \begin{matrix}1 \\ 1 \\ 0\end{matrix} )\end{matrix} ;$$

The corresponding algorithm can be read from the mathematical expression, as:

(1) Copy the data layer 202 to be characterized to the operation layer 200.

(2) Copy the operation layer 200 to the neighboring layer 201.

(3) Set the start X address to be one more than the left boundary.

(4) Set the end X address to be one less than the right boundary.

(5) Set the start Y address to be one more than the bottom boundary.

(6) Set the end Y address to be one less than the top boundary.

(7) Copy the left layer to the operation layer 200.

(8) Negate the operation layer 200.

(9) Add the right layer to the operation layer 200.

(10) Copy the operation layer 200 to the neighboring layer 201.

(11) Add the bottom layer to the operation layer 200.

(12) Copy the operation layer 200 to the neighboring layer 201.

(13) Add the top layer to the operation layer 200.

Sum

To sum a one-dimensional array of N items, the array is divided into sections, each of which contains M consecutive items. All sections are summed concurrently from left to right, in ˜M instruction cycles. Then the section sums, which are at the right-most items of every sections, are summed together serially in ˜N/M instruction cycles. Thus, the total instruction cycle count is ˜(M+N/M). When M˜sqrt(N), the total instruction cycle count has a minimum of ˜sqrt(N). A detailed sum algorithm is:

(1) Copy the data layer 202 to be summed to the operation layer 200.

(2) Copy the operation layer 200 to the neighboring layer 201.

(3) Set the carry number to M˜sqrt(N). The M is the item count in each section, except the last section which may have items less than M.

(4) Increment the start address by one.

(5) Add the left layer 114a to the operation layer 200.

(6) Exchange the operation layer 200 and the neighboring layer 201.

(7) Repeat step (4) to (6) M times. The section sums are at the neighboring layer 201 of the last items of all sections.

(8) Read and add all the neighboring registers 201 of all last items of all sections serially, to get the sum of the array.

For an example, an array starts with (0, 1, 2, 3, 4, 5, 6, 7) is summed as:

Example of 1D Array Summing

| step | operation layer | neighboring layer |
|---|---|---|
| 2 | 0, 1, 2, 3, 4, 5, 6, 7 | 0, 1, 2, 3, 4, 5, 6, 7 |
| 3 | M = 3 | |
| 5a | 0, 1, 2, 3, 7, 5, 6, 13 | 0, 1, 2, 3, 4, 5, 6, 7 |
| 6a | 0, 1, 2, 3, 4, 5, 6, 7 | 0, 1, 2, 3, 7, 5, 6, 13 |
| 5b | 0, 1, 3, 3, 4, 12, 6, 7 | 0, 1, 2, 3, 7, 5, 6, 13 |
| 6b | 0, 1, 2, 3, 4, 5, 6, 7 | 0, 1, 3, 3, 4, 12, 6, 13 |
| | accumulator | |
| 8a | 3 | |
| 8b | +12 = 15 | |
| 8c | +13 = 28 | |

The above algorithm can be displayed by an algorithm flow diagram in FIG. 20, in which serial operations are represented by a series of simple arrows 351, and concurrent parallel operations are represented by a series of arrow with two parallel bars on each side 352. Each arrow shows the data range of the operation, such as on a section 356with M items of the whole array 357with N items. Each series of arrows is marked by a step sequence number followed by “:” 353, an instruction cycle count pre-ceded by “˜” 354, and an operation 355. The instruction cycle counts from consecutive and independent steps are additive, so the total instruction cycle count is (M+N/M)>=˜sqrt(N), which has a minimum of ˜sqrt(N) when M˜sqrt(N).

To sum a two-dimensional array of Nx by Ny items, the array is divided into sections, each of which contains Mx by My consecutive items. All rows of all sections are summed concurrently from left to right, in ˜Mx instruction cycles. Then all the right-most columns of all sections, each item of which contains a row sums for a section, are summed concurrently from bottom to top. Then the top-right-most items of all sections, each of which contains a section sum, are scanned and summed together serially, with the column and the row direction being the fast and the slow scan direction respectively. FIG. 21 is the corresponding algorithm flow diagram, in which step sequence number “4*3” 358 means a complete step 3 is carried out before each instruction cycle of step 4. Thus, the total instruction cycle count for such combination of steps is the product of the individual instruction cycle count of each step. The total instruction cycle count is (Mx+My+Nx/Mx Ny/My), which has minimum of cbrt(Nx Ny) when Mx˜My˜cbrt(Nx Ny).

Template Matching

To match a template of size M, the array is divided into N/M sections, each of which contains M consecutive items. The algorithm diagram is shown in FIG. 22. In Step 1, the template to be matched is loaded to all sections concurrently in ˜M instruction cycles. Then the point-to-point absolute difference is calculated concurrently for all points in ˜1 instruction cycles, which is omitted from the algorithm flow diagram. In Step 2, all sections are summed concurrently from right to left in ˜M instruction cycles, to obtain the difference values of the array to the pattern at the first positions to the left of all sections. In the first instruction cycle of Step 3*2, the templates in all sections are shifted right by one item, to calculate the difference at the second positions of all sections, and so forth. Thus the total instruction cycle count is (M+M M)˜M\hat{ }2. When M>sqrt(N), the summing of all sections is further divided into the concurrent summing of subsections, each of which contains L consecutive items, and the serial summing of the subsections, thus the total instruction cycle count is ˜(M+(L+N/L)M), or ˜(M sqrt(N)) when L˜sqrt(N).

Similar algorithm can be carried out in a 2-D array of size Nx by Ny stored in a math 2D memory for a 2-D template of size Mx by My. The algorithm diagram is shown in FIG. 23, which also omits the step of calculating point-to-point absolute difference. In step 2*1, the template to be matched is loaded to all sections concurrently in ˜M\hat{ }2 instruction cycles. The first application of Step 3 sums the point-to-point absolute differences of each of all section at the first column from left of the section. The first instruction cycle of Step 4 moves the template right by one column. The second application of Step 3 sums the point-to-point absolute differences of each of all sections at the second column from left of the section. The first complete application of Step 4*3 fills the sums of row difference of the corresponding section. The first application of Step 5 results in the matching of the template at the first row from bottom of each of all sections. The first instruction cycle of Step 6*(4*3+5) moves the template up by one row. The Step 4*3 is carried out again except that the Step 4 is carried out from right to left this time, since the first application of the Step 4*3 has moved the template to the right-most position of each section. Thus, the total instruction cycle count is ˜(Mx My+(Mx\hat{ }2+My) My), which is equivalent to ˜(Mx\hat{ }2 My).

Using CP memory, the instruction cycle count for 1-D template matching is reduced from ˜(N M) to ˜M\hat{ }2, and it is reduced from ˜(Nx Ny Mx My) to ˜(Mx\hat{ }2 My). It may be small enough now for the template matching algorithm to be carried out in real-time for a lot of applications, such as image database.

Thresholding

With its multiple dimensions of data, image processing and spatial modeling generally requires large amount of calculation, which is linearly proportional to the size of data in each dimension.

Using a conventional bus-sharing computer, the instruction cycle count is linearly proportional to the amount of calculation. Thus, to solve a problem in a realistic time period, thresholding is frequently used to ignore large amount data in the subsequent processing. Thresholding is a major problem, because proper thresholding is difficult to achieve, and thresholding in different stages may interact with each other.

Using a math memory, the instruction cycle count is decoupled from the amount of calculation, and is independent of the size of data in each dimension. Thus, thresholding can be used only in last stage to qualify the result. Also, thresholding itself has been reduced to ˜1 instruction cycle operation.

For an example, to recognize features of an image, one of the common conventional methods is to:

(1) Use Sobel filters to find edge intensity of the image.

(2) Use thresholding to ignore most pixels except those which have large edge intensities. In most practice the image is further reduced into a binary bitmap.

(3) Analyze the reduced data set for features, such as carry out line recognition.

In step (2), if the threshold is too high, true edge pixels may be ignored. On the other hand, if it is too low, none edge pixels may be included. Both cases add difficulty to step (3) and subsequent analysis. If the illustration of the image is not uniform, or the image contains features of different reflectivity, or the objects cast shadows, it is almost certain that there is no perfect global threshold for edge intensity, and thresholding process itself may become very complicated.

Using a math memory, step (1) and (2) can be altogether canceled, and the raw intensities of all pixels are used for subsequent processing without any increase of instruction cycles. Thresholding may be applied to visualize the processed image after a step, but it can be kept out of the image processing itself until the last step.

Line Recognition

Due to neighbor-to-neighbor connectivity, CP memory can treat line detection problem as a neighbor counting problem. A line can be made of pixels of up to a distance apart, which is called the pixel span of the line. A continuous line lying exactly along X or Y direction thus has pixel span of 1. On a real image, edge lines are of primary importance, each of which separates pixels on its two sides into two intensity groups. Thus, the following discussion is limited to detecting edge lines, although the stated algorithms can be easily adopted to detecting other lines, such as intensity lines.

To detect edges line of pixel span 1 and pixel length L lying exactly along X direction left to each pixel, the neighborhood count algorithm is direct:

(1) Each of all pixels subtracts the raw intensity of its bottom layer from that of its top layer, and stores the result in the neighboring layer.

(2) Each of all pixels sums the neighboring layers of its L left neighbors together with its own. The absolute value of the result indicates the possibility of an edge line starting from that pixel, while the sign of the result indicates whether the edge is rising or falling along the Y direction.

The algorithm to detect edge line lying exactly along X direction is similar.

To detect edge lines with a slope of (My/Mx), each pixel defines a super lattice of Mx by My pixels denoted as (Mx*My), and the line which connects the pixel and the furthest corner of the super lattice has the slope of (My/Mx). Similar to obtaining the section sums in a sum algorithm, a messenger starts from furthest corner of the super lattice, walks (Mx+My) steps along the line until it reaches the original pixel. In each of its stop, if the pixel is on the left side of the line, its intensity is added to the messenger; otherwise, if the pixel is on the right side of the line, its intensity is subtracted from the messenger. When reaching the original pixel, the value of the messenger indicates the possibility and the slope of the edge line which connects the original pixel and the furthest corner of the (Mx*My) super lattice. Similar process may carry out for the (−Mx*−My) super lattice. This accumulating process is carried out concurrently for all the pixels of the image, independent of image sizes. FIG. 24 shows the (4*3) super lattice to detection a line with a slope of (¾) passing the original pixel at 0. The accumulation processing is from pixel 7 to pixel 0 in sequence, with the intensities of pixel 1, 3, and 5 to be added, and the intensities of pixel 2, 4, and 6 to be subtracted from the messenger.

If multiplication is used, the line detection algorithm can be further improved. At each stop of the line detection algorithm, through the concurrent bus 109, a weight factor for the stop is sent concurrently to all the messengers, which multiply the weight factor with the pixel intensities of the stop and accumulate the result. The weight factor is inversely proportional to the distance between the line and the pixel at the stop. In FIG. 24, assuming the edge line half-width of 1, the corresponding weight factors could be:

An Example of Weight Factors for Line Detection

Pixel

| | 1 | 2 | 3 | 4 | 5 | 6 |
|---|---|---|---|---|---|---|
| Width | +2/5 | −4/5 | +3/5 | −3/5 | +4/5 | −2/5 |

Given an angular resolution requirement, a {(Mx, My)} set can be constructed to detect all lines on an image, each element of which can be determined by a corresponding line detection algorithm. FIG. 25a shows a set of origin-bounding lines whose pixel spans are exactly 7 in walking distance, on a square grid. It also shows the walking distance envelope of 7. For such a line set of walking distance D, the angular resolution is ˜(2/D) along the 45-degree diagonal direction, and ˜(1/D) along the X and Y directions; the total instruction cycle count is ˜D\hat{ }2, independent of the image size.

To reduce the instruction cycles for detecting the lines, starting from a {(Mx, My)} set of D in walking distance, a circuit of radius ˜(D/sqrt(2)) in real distance may be used to guide the starting walking pixels for the messengers, to also have slightly more uniform angular resolution. FIG. 25b shows such a set of origin-bounding lines whose pixel spans are ˜5 in real distance, on the same square grid. It also shows the real distance envelope of 5.

If a (Mx*My) super lattice in the set have stop(s) that passes the line exactly, lines of short pixel span in that direction also need to be added to the set. For an example, the super lattice (5*0) of the set adds super lattices (4*0), (3*0), (2*0) and (1*0) to the set. As a result of line detection, each pixel is marked by the line value of the highest normalized absolute value together with its corresponding super lattice.

Long Range Connectivity

Adding long-range connectivity generally reduces the instruction cycle count for global operations. FIG. 26 shows the log3(N) long range connectivity, in which N equals 27. In FIG. 26, all dots in each column represent a memory element, which is marked by the element address at the top, and different layer represents different range of connectivity, such as neighbor-to-neighbor or between every 3\hat{ }0 neighbors 171, between every 3\hat{ }1 neighbors 172, between every 3\hat{ }2 neighbors 173, and between every 3\hat{ }3 neighbors 174. In limit finding or sum, the results of three neighbors are sent to next layer of longer range of connectivity, so that the total instruction cycle count are log3(N) in both cases. Similar algorithm may also be applied to sorting and fast Fourier transformation.

Super-Lattice Connectivity

Long-range connectivity is a special type of super-lattice connectivity. It may be difficult to change the connectivity after a CP memory has been made, but it is quite feasible that all elements in an M-dimension lattice is a subset of a (M+1)-dimension lattice, with each M-dimension lattice connected on a different super lattice.

FIG. 27a shows an example of 2-D super-lattice connectivity. Instead of connecting all nodes along the X and Y directions, to detection a line which lies specifically along the direction from node 0 to node 7, it connects node 0 and node 7, and node 0 and node 2, so that the direct neighborhood counting algorithm can be used concurrently on all the nodes to detect the line in the specific direction. FIG. 27b shows an example of 2-D super-lattice connectivity. It composes of planes of 2-D super-lattice connectivity, each is specialized for detecting lines in one direction similar to that of FIG. 27a. All these planes have same pixel registry between the planes, to allow direct connections between registered nodes between different planes. The image data may come from a steady source, such as a video camera. The data pass all 2-D super lattices in turn, which works concurrently and continuously on the same instructions as part of a SIMD pipeline, and finally emerges with the best line value and the associated super lattice attached to each pixel.

Parallel Divider

FIG. 28 shows a circuitry algorithm for parallel divider using an all-line decoder, a carry pattern generator, a parallel counter, and a priority encoder. The dividend 161 is input into an all-line decoder, to generate continuous bit outputs up to the dividend 163. The divisor 162 is input into a carry-pattern generator, to generate the corresponding carry pattern 164. The two sets of bit outputs are AND-combined together. The combined bit outputs are counted by a parallel counter, to get the quotient of the division 165. Meanwhile, the combined bit outputs are also processed by an encoder of high-to-low priority, to get the largest bit output of the carry pattern generator which is less than or equal to the dividend 166, and thus the value of dividend minus reminder 167

Because a CP memory may already have an all-line decoder, a carry pattern generator, and a parallel counter, by caching the bit outputs of the general decoder, the CP memory may also be a parallel divider in addition, which, due to the functionality of the general decoder, provides slightly more powerful functionality of obtaining the quotient and the value of dividend minus reminder, of dividing a dividend by a divider, the dividend being the value of a subtrahend minus an offset.

Functional Overview of Concurrent Processing Memory

As illustrated by FIG. 29, in which the general decoder, the priority encoder, and the parallel counter have been packed into an element control unit, a general CP memory can be summarized by the following rules:

(1) A CP memory is made of identical elements, each of which has a unique address.

(2) Each memory is connected with a data bus.

(3) One element can read from or write to the data bus exclusively.

(4) Multiple elements can be activated by an element control unit. A memory element is activated if its element address corresponds to the increments of a carry number starting at a start address and if it is equal to or less than an end address

(5) Multiple activated elements can read from the data bus concurrently.

(6) Multiple activated elements can be required to identify themselves concurrently. Each element positively asserts a line which connects the element back to the element control unit

(7) Each element contains a fixed number of registers.

(8) The neighboring elements are connected so that an element can read at least one register of its neighbor.

(9) There is an extra external command pin to indicate the address and data bus contains whether an instruction, or address and data for the memory when it is enabled.

Rule (1), (2) and (3) specifies the functional backward compatibility with a conventional random access memory.

Rule (4), (5) and (6) defines concurrency. Rule (7) and (8) defines connectivity. Rule (9) defines processing capability.

1. An apparatus that comprises the functions of a conventional random access memory of: (A) means for storing and retrieving data using addressable registers within the apparatus, (B) a plurality of external bus connections to an external bus comprising address bus, data bus and control bus, and (C) the external bus connections facilitating the means for exclusively storing or retrieving data using the addressable registers within the apparatus; wherein the improvement comprising:
(a) a command bit input,
(b) memory means for behaving as a conventional random access memory when the command bit input is negatively asserted, and
(c) instruction means for receiving instructions to the apparatus from the external bus when the command bit input is positively asserted.

2. An apparatus of claim 1, its instruction means further comprising:
(a) characterizing means for characterizing the content of multiple internal registers using: (A) the address bus of the external bus to send the characterizing instruction to the apparatus, and (B) the data bus of the external bus to get the characterization result form the apparatus; and
(b) processing means for concurrently processing multiple internal registers within the apparatus using the address bus or the data bus or both of the external bus to send the processing instruction to the apparatus.

3. An apparatus of claim 1, further comprising termination means for signaling the termination of the instruction means by:
(a) means for changing the content of the external bus of the apparatus in a predefined way, or
(b) means for waiting a predefined time period before able to receive another input from the command bit input and the external bus connections, or
(c) the combination of (a) and (b).

4. Compliance means for making the connection to the external bus of the apparatus of claim 1 in full compliance with a bus standard, the compliance means comprising:
(a) means for making the apparatus' external bus connections to the data bus in full compliance with the data bus portion of the bus standard, and being connected thereof,
(b) means for making the apparatus' external bus connections to the address bus in full compliance with the corresponding bits of the address bus portion of the bus standard, and being connected thereof,
(c) means for making the apparatus' command bit input in full compliance with a bit of the address bus of the bus standard which is not used to connect to the apparatus' connections to the address bus, as if the address bus bit of the bus standard is being used as a address bus bit, and being connected thereof, and
(d) means for making the apparatus' external bus connections to the control bus in full compliance with the bits or bits' logic combinations of the control bus portion and the remained unconnected bits of the address bus portion of the bus standard, and being connected thereof.

5. Preferred compliance means for the apparatus' connection to the external bus in full compliance with a bus standard as claimed in claim 4, the preferred compliance means further comprising:
(a) connecting the apparatus' command bit input with the least significant address bit of the bus standard which is not connected to the apparatus' external bus connection to the address bus.

6. Possible compliance means for the apparatus' connection to the external bus in full compliance with a bus standard as claimed in claim 4, the possible compliance means further comprising:
(a) the apparatus having additional instruction bits to increase the width of instructions for the apparatus, and
(b) the instruction bits being able to be connected to the external bus.

7. Using steps for using the apparatus when it is connected with other devices using an external bus of a bus standard, as claimed in claim 4, the using steps comprising:
(a) negatively asserting the command bit input of the apparatus, to use the apparatus as a conventional random access memory,
(b) positively asserting the command bit input of the apparatus, and sending a processing instruction to the apparatus as if storing data to a fictional location inside the apparatus, and
(c) positively asserting the command bit input of the external bus, and sending a characterizing instruction to the apparatus as if retrieving data from a fictional location inside the apparatus.

8. An apparatus comprising:
(a) a plurality of memory elements, each of which comprising:
(1) at least one register;
(2) element instruction means for receiving and carrying out instructions for the memory element;
(3) an enable bit input; and
(4) disabling means for disabling the element instruction means when the enable bit input is negatively asserted;
(b) a concurrent bus, which is connected to all the memory elements, and which is concurrently read by all the enabled memory elements;
(c) an exclusive bus, which is connected to a plurality of registers, and which is exclusively read from or exclusively written to by any one of the connected registers, the connected registers being addressable registers, each having a register address;
(d) an input/output control unit, comprising:
(1) means for connecting with external bus connections of the apparatus, and means for receiving instruction from the external bus;
(2) means for connecting to the concurrent bus, and means for writing exclusively to the concurrent bus; and
(3) means for connecting to the exclusive bus, and means for either (A) exclusively writing to the exclusive bus, or (B) exclusively reading from the exclusive bus;
(e) exclusive means for exclusively copying either (A) the content of any addressable register to the exclusive bus, or (B) the content of the exclusive bus to any addressable register, or (C) the content of a source within the input/output control unit to the exclusive bus; or (D) the content of the exclusive bus to a target within the input/output control unit.
(f) concurrent means for concurrently executing a same instruction on the concurrent bus in a plurality of the enabled memory elements, the concurrent means further comprising:
(1) instructing means for sending a instruction from the input/output control unit, through the concurrent bus, to each of all the memory elements concurrently;
(2) enabling means for positively asserting the enable bit inputs of a plurality of memory elements; and
(3) executing means for concurrently executing the instruction in each of all the enabled memory elements; and
(g) instruction means for receiving and carrying out instructions at the external bus connections of the apparatus.

9. An apparatus of claim 8, its instruction means further comprising:
(a) means for signaling the values of all the outputs of the apparatus being invalid for the current input values;
(b) means for translating the content of the external bus of the apparatus into instructions for the apparatus; and
(c) means for carrying out the instruction for the apparatus in a series of steps comprising the concurrent means and the exclusive means.

10. An apparatus of claim 8 that comprises the functions of a conventional random access memory of: (A) means for storing and retrieving data using addressable registers within the apparatus, (B) a plurality of external bus connections to an external bus comprising address bus, data bus and control bus, and (C) the external bus connections facilitating the means for exclusively storing or retrieving data using the addressable registers within the apparatus; wherein the improvement comprising:
(a) a command bit input,
(b) the external bus connections of the input/output control unit further comprising address bus, data bus and control bus;
(c) memory means for behaving as a conventional random access memory containing a plurality of addressable register which is exclusively addressable and accessible through the external bus connections of the apparatus when the command bit input is negatively asserted, the memory means further comprising:
(1) storing means for copying the content of the data bus of the external bus to the addressable register whose register address is specified by the address bus of the external bus when the control bus of the external bus instructs the apparatus for a storing operation; and
(2) retrieving means for copying the content of the addressable register whose register address is specified by the address bus of the external bus to the data bus of the external bus when the control bus of the external bus instructs the apparatus for a retrieving operation;.
(d) the instruction means further comprising means for receiving and carrying out instructions for the apparatus when the command bit input is positively asserted.

11. An apparatus of claim 10, its instruction means further comprising:
(a) means for signaling the values of all the outputs of the apparatus being invalid for the current input values;
(b) means for translating the content of the external bus of the apparatus into instructions for the apparatus when the command bit input is positively asserted; and
(c) means for carrying out the instruction for the apparatus in a series of steps comprising the concurrent means and the exclusive means; and
(d) means for using an existing bus standard protocol to signal the readiness of the apparatus.

12. An apparatus of claim 8, further comprising:
(a) a plurality of bit storage elements;
(b) means for connecting:
(1) each enable bit input of all the memory elements from a unique bit storage element; and
(c) the enabling means further comprising:
(1) means for using the bit storage elements to positively assert each corresponding enable bit input of all the memory elements.

13. An apparatus of claim 12, its enabling means further comprising:
(a) means for changing the values of one set of bit storage elements while retaining the values of the other set of bit storage elements.

14. An apparatus of claim 8, further comprising:
(a) a range decoder, comprising:
(1) a start address input;
(2) an end address input;
(3) a plurality of bit outputs, each of which has a unique address; and
(4) means for concurrently positively asserting all the bit outputs whose addresses are: (A) no less than the value at the start address input, and (B) no more than the value at the end address input, while negatively asserting all the other bit outputs;
(b) means for connecting each of all the memory elements to a unique bit output of the range decoder, thus each of all the memory elements having a unique element address;
(c) the input/output control unit further comprising:
(1) controlling means for providing the start address input, and the end address input to the range decoder; and
(d) the enabling means further comprising:
(1) means for positively asserting the enable bit inputs of the memory elements whose element addresses are: (A) no less than a start address, and (B) no more than an end address.

15. An apparatus of claim 8, further comprising:
(a) a general decoder, comprising:
(1) a start address input;
(2) an end address input;
(3) a carry number input;
(4) a plurality of bit outputs, each of which has a unique address; and
(5) means for concurrently positively asserting all the bit outputs whose addresses are: (A) no less than the value at the start address input, (B) no more than the value at the end address input, and (C) an integer increment of the value at the carry number input starting from the value at the start address input, while negatively asserting all the other bit outputs;
(b) means for connecting each of all the memory elements to a unique bit output of the general decoder, thus each of all the memory elements having a unique element address;
(c) the input/output control unit further comprising:
(1) controlling means for providing the start address input, the end address input, and the carry number input to the general decoder; and
(d) the enabling means further comprising:
(1) means for positively asserting the enable bit inputs of the memory elements whose element addresses are: (A) no less than a start address, (B) no more than an end address, and (C) an integer increment of a carry number starting from the start address.

16. An apparatus of claim 15, its general decoder further comprising:
(a) the value of the carry number input being no larger than the square root of the total memory element count of the apparatus.

17. An apparatus of claim 15, further comprising:
(a) a priority encoder, comprising:
(1) a plurality of bit inputs, each of which corresponds to a unique address;
(2) a no-hit bit output, which is positively asserted when none of the bit inputs is positively asserted;
(3) a priority high bit input; and
(4) an address output, when the no-hit bit output being negatively asserted, the address output containing either (A) the highest address of the bit inputs which are positively asserted when the priority high bit input is positively asserted, or (B) the lowest address of the bit inputs which are positively asserted when the priority high bit input is negatively asserted;
(b) a parallel counter, comprising:
(1) a plurality of bit inputs;
(2) a count output;
(3) means for concurrently counting the bit inputs which are positively asserted;
(c) dividing means for obtaining: (A) the quotient, and (B) the value of dividend minus reminder, of dividing a dividend by a divider, the dividend being the value of a subtrahend minus an offset, the dividing means further comprising:
(1) means for inputting the offset into the start address input of the general decoder;
(2) means for inputting the subtrahend to the end address input of the general decoder;
(3) means for inputting the divider to the carry number input of the general decoder;
(4) means for connecting each of all bit outputs of the general decoder to a unique bit input of the parallel counter, except the bit output at address 0 of the general decoder;
(5) means for outputting the quotient from the count output of the parallel counter;
(6) means for connecting each of all bit outputs of the general decoder to the bit input which has same address of the priority encoder, except (A) the bit output at address 0 of the general decoder, and (B) negatively asserting the bit input at address 0 of the priority encoder;
(7) means for positively asserting the priority high bit input of the priority encoder;
(8) when the no-hit bit output of the priority encoder is positively asserted, means for signaling the divider being 0; and
(9) when the no-hit bit output of the priority encoder is negatively asserted, means for outputting the value of dividend minus reminder from the address output of the priority encoder; and
(d) the instruction means further comprising:
(1) means for obtaining (A) the quotient, and (B) the value of dividend minus reminder, of dividing a dividend by a divider, the dividend being the value of a subtrahend minus an offset.

18. An apparatus of claim 17, further comprising:
(a) a plurality of bit storage elements;
(b) means for connecting:
(1) each enable bit input of all the memory elements from a unique bit storage element; and
(2) each of all the bit storage element from a unique bit output of the general decoder;
(c) saving means for saving the value of the bit output of the general decoder to the bit storage element; and
(d) retaining means for retaining the value of the bit storage elements when obtaining (A) the quotient, and (B) the value of dividend minus reminder, of dividing a dividend by a divider, the dividend being the value of a subtrahend minus an offset.

19. An apparatus of claim 17, further comprising:
(a) the priority encoder is constantly of high priority.

20. An apparatus of claim 8, further comprising:
(a) each of all its memory elements further comprising:
(1) a plurality of registers; and
(b) register identifying means for identifying each register within its memory element by a unique register number, the register identifying means further comprising:
(1) the set of register numbers is identical for all of the memory elements; and
(2) the registers which have the same register number are functionally equivalent within their memory elements respectively.

21. An apparatus of claim 8, each of all its memory elements further comprising:
(a) at least one addressable register.

22. An apparatus of claim 8, further comprising:
(a) element address means for assigning a unique address to each of all the memory elements.

23. An apparatus of claim 22, further comprising:
(a) each of all its memory elements further comprising:
(1) one addressable register; and
(b) means for using the element address as the register address for each of all the addressable registers.

24. An apparatus of claim 22, further comprising:
(a) each of all its memory elements further comprising:
(1) a plurality of addressable registers;
(b) register identifying means for identifying each addressable register within each memory element by a unique register number, the register identifying means further comprising:
(1) the set of register number is identical for all of the memory elements; and
(2) the registers which have the same register number are functionally equivalent within their memory elements respectively; and
(c) register addressing means for using the combination of the element address and the register number as the register address for each of all the addressable registers.

25. An apparatus of claim 24, its register addressing means further comprising:
(a) using the register number as the higher portion of the addressable register address so that functionally equivalent registers within all memory elements form a continuous register address range.

26. An apparatus of claim 24, its register addressing means further comprising:
(a) using the register number as the lower portion of the addressable register address so that all addressable registers within each memory elements form a continuous register address range.

27. An apparatus of claim 8, each of its memory elements further comprising:
(a) an match bit output;
(b) state means for defining states for the memory element when it is enabled;
(c) matching means for positively asserting the match bit output when the memory element is in a required state; and
(d) the disabling means further comprising means for negatively asserting the match bit output when the enable bit input is negatively asserted.

28. An apparatus of claim 27, each of all the memory elements further comprising:
(a) a bit storage element; and
(b) saving means for saving the value of the match bit output in the bit storage element when the memory element is enabled.

29. An apparatus of claim 28, each of all the memory elements further comprising:
(a) neighboring means for reading the saved value of the match bit output of the memory element whose element address is either immediately lower or immediately higher than the element address of the memory element itself;
(b) combining means for using the saved value of the match bit output of the selected neighboring memory element in defining the state of the memory element itself; and
(c) transferring means for using the saved value of the match bit output of the selected neighboring memory element as the state of the memory element itself.

30. An apparatus of claim 27, further comprising:
(a) a parallel counter, comprising:
(1) a plurality of bit inputs,
(2) a count output,
(3) means for concurrently counting the bit inputs which are positively asserted;
(b) means for connecting:
(1) the match bit output of each of all the memory elements to a unique bit input of the parallel counter, and
(2) the count output of the parallel counter to the input/output control unit;
(c) the concurrent means further comprising:
(1) matching means for specifying the required state for matching concurrently to all the memory elements by the data stored in each enabled memory element and a matching requirement; and
(1) counting means for concurrently counting the enabled memory elements whose match bit outputs are positively asserted; and
(d) the instruction means further comprising:
(1) means for concurrently specifying a matching requirement to each of all the memory elements; and
(2) means for writing the count of the enabled memory elements which satisfy the matching requirement to the external connection of the apparatus.

31. Steps for using the apparatus of claim 30, further comprising:
(a) steps for concurrently defining or concurrently changing the selection of the enabled memory elements for matching; and
(b) steps for concurrently specifying a matching requirement to each of all the memory elements; and
(c) steps for concurrently counting the enabled memory elements each of which satisfies the matching requirement.

32. An apparatus of claim 27, further comprising:
(a) a priority encoder, comprising:
(1) a plurality of bit inputs, each of which corresponds to a unique address;
(2) a no-hit bit output, which is positively asserted when none of the bit inputs is positively asserted;
(3) a priority high bit input; and
(4) an address output, when the no-hit bit output being negatively asserted, the address output containing either (A) the highest address of the bit inputs which are positively asserted when the priority high bit input is positively asserted, or (B) the lowest address of the bit inputs which are positively asserted when the priority high bit input is negatively asserted;
(b) means for connecting:
(1) the match bit output of each of all the memory elements to a unique bit input of the priority encoder, thus each of all the memory elements having an address;
(2) the priority high bit input of the priority encoder from the input/output control unit; and
(3) the no-hit bit output and the address output of the priority encoder to the input/output control unit;
(c) the concurrent means further comprising:
(1) matching means for specifying the required state for matching concurrently to all the memory elements by the data stored in each enabled memory element and a matching requirement;
(2) null means for signaling none of the enabled memory elements whose match bit outputs are positively asserted; and
(3) addressing means for finding either the highest or the lowest element address of the enabled memory elements whose match bit outputs are positively asserted; and
(d) the instruction means further comprising:
(1) means for concurrently specifying a matching requirement to each of all the memory elements;
(2) means for writing a predefined value to the external connection of the apparatus if no enabled memory element satisfying the matching requirement; and
(3) means for writing to the external connection of the apparatus either (A) the highest or (B) the lowest address among those of the enabled memory elements which satisfy the matching requirement.

33. Steps for using the apparatus of claim 32, further comprising:
(a) steps for concurrently defining or concurrently changing the selection of the enabled memory elements for matching;
(b) steps for concurrently specifying a matching requirement to each of all the memory elements;
(c) steps for concurrently finding none of the enabled memory elements satisfying the matching requirement;
(d) steps for concurrently finding the highest address of the enabled memory element which satisfies the matching requirement;
(e) steps for concurrently finding the lowest address of the enabled memory element which satisfies the matching requirement; and
(f) steps for concurrently enumerating the addresses of the enabled memory elements each of which satisfies the matching requirement.

34. An apparatus of claim 32, further comprising:
(a) a parallel counter, comprising:
(1) a plurality of bit inputs,
(2) a count output,
(3) means for concurrently counting the bit inputs which are positively asserted;
(b) means for connecting:
(1) the match bit output of each of all the memory elements to a unique bit input of the parallel counter, and
(2) the count output of the parallel counter to the input/output control unit;
(c) the concurrent means further comprising:
(1) matching means for specifying the required state for matching concurrently to all the memory elements by the data stored in each enabled memory element and a matching requirement; and
(2) counting means for concurrently counting the enabled memory elements whose match bit outputs are positively asserted; and
(d) the instruction means further comprising:
(1) means for concurrently specifying a matching requirement to each of all the memory elements; and
(2) means for writing to the external connection of the apparatus the count of the enabled memory elements which satisfy the matching requirement.

35. Steps for using the apparatus of claim 34, further comprising:
(a) steps for concurrently defining or concurrently changing the selection of the enabled memory elements for matching;
(b) steps for concurrently specifying a matching requirement to each of all the memory elements;
(c) steps for concurrently finding none of the enabled memory elements satisfying the matching requirement;
(d) steps for concurrently finding the highest address of the enabled memory element which satisfies the matching requirement;
(e) steps for concurrently finding the lowest address of the enabled memory element which satisfies the matching requirement;
(f) steps for concurrently enumerating the addresses of the enabled memory elements each of which satisfies the matching requirement; and
(g) steps for concurrently counting the enabled memory elements each of which satisfies the matching requirement.

36. An apparatus of claim 34, each of all its memory elements further comprising:
(a) a general decoder, comprising:
(1) a start address input;
(2) an end address input;
(3) a carry number input;
(4) a plurality of bit outputs, each of which has a unique address; and
(5) means for concurrently positively asserting all the bit outputs whose addresses are: (A) no less than the value at the start address input, (B) no more than the value at the end address input, and (C) an integer increment of the value at the carry number input starting from the value at the start address input, while negatively asserting all the other bit outputs;
(b) means for connecting each of all the memory elements to the bit output of the general decoder which has the same address as the memory element;
(c) the input/output control unit further comprising:
(1) controlling means for providing the start address input, the end address input, and the carry number input to the general decoder; and
(d) the enabling means further comprising:
(1) means for positively asserting the enable bit inputs of the memory elements whose element addresses are: (A) no less than a start address, (B) no more than an end address, and (C) an integer increment of a carry number starting from the start address.

37. An apparatus of claim 36, further comprising:
(a) dividing means for obtaining (A) the quotient and (B) the value of dividend minus reminder, of dividing a dividend by a divider, the dividend being the value of a subtrahend minus an offset, the dividing means further comprising:
(1) means for inputting the offset into the start address input of the general decoder;
(2) means for inputting the subtrahend to the end address input of the general decoder;
(3) means for inputting the divider to the carry number input of the general decoder;
(4) means for connecting each of all bit outputs of the general decoder to a unique bit input of the parallel counter, except the bit output at address 0 of the general decoder;
(5) means for outputting the quotient from the count output of the parallel counter;
(6) means for connecting each of all bit outputs of the general decoder to the bit input which has same address of the priority encoder, except (A) the bit output at address 0 of the general decoder, and (B) negatively asserting the bit input at address 0 of the priority encoder;
(7) means for positively asserting the priority high bit input of the priority encoder;
(8) when the no-hit bit output of the priority encoder is positively asserted, means for signaling the divider being 0; and
(9) when the no-hit bit output of the priority encoder is negatively asserted, means for outputting the value of dividend minus reminder from the address output of the priority encoder; and
(b) the instruction means further comprising:
(1) means for obtaining (A) the quotient, and (B) the value of dividend minus reminder, of dividing a dividend by a divider, the dividend being the value of a subtrahend minus an offset.

38. An apparatus of claim 37, further comprising:
(a) a plurality of bit storage elements;
(b) means for connecting:
(1) each enable bit input of all the memory elements from a unique bit storage element; and
(2) each of all the bit storage element from a unique bit output of the general decoder;
(c) saving means for saving the value of each of all the bit outputs of the general decoder to the corresponding bit storage element; and
(d) retaining means for retaining the value of the bit storage elements when obtaining (A) the quotient, and (B) the value of dividend minus reminder, of dividing a dividend by a divider, the dividend being the value of a subtrahend minus an offset.

39. An apparatus of claim 27, each of its memory elements further comprising:
(a) at least one status bit;
(b) status means for either (A) positively or (B) negatively asserting any of the status bits, and
(c) the state means further comprising means for using the values of the status bit(s) to define the state of the memory element.

40. An apparatus of claim 27, each of its memory elements further comprising:
(a) the required state being a predefined state.

41. An apparatus of claim 27, further comprising:
(a) the concurrent bus further carrying a condition specification to each of all the memory elements; and
(b) the matching means further comprising:
(1) specifying means for using the condition specification of the concurrent bus to specify the required state, and
(2) determining means for determining if the state of the memory element matches the required state which has been specified by the condition specification of the concurrent bus.

42. An apparatus of claim 27, each of its memory elements further comprising:
(a) an unequal comparator, comprising:
(1) a first input;
(2) a second input; and
(3) a bit output, which is positively asserted when any bit of the first input is asserted differently from the corresponding bit of the second input;
(b) the state means further comprising means for using the bit output of the unequal comparator to define the state of the memory element.

43. An apparatus of claim 42, the unequal comparator in each of its memory elements further comprising:
(a) a bus XOR gate, comprising:
(1) a first input;
(2) a second input; and
(3) a output, each of its bit being positively asserted when the corresponding bit of the first input is asserted differently from the corresponding bit of the second input;
(b) a OR gate, comprising:
(1) a plurality of bit inputs; and
(2) a bit output, which is positively asserted when any of its bit inputs is positively asserted;
(c) means for connecting:
(1) the first input of the comparator to the first input of the bus XOR gate;
(2) the second input of the comparator to the second input of the bus XOR gate;
(3) each bit of the output of the bus XOR gate to an unique bit input of the OR gate; and
(4) the bit output of the OR gate to the bit output of the comparator.

44. An apparatus of claim 42, each of its memory elements further comprising:
(a) means for connecting one register to the first input of the unequal comparator, the register being called the comparable register of the memory element.

45. An apparatus of claim 44, each of its memory elements further comprising:
(a) the comparable register being addressable.

46. An apparatus of claim 44, each of its memory elements further comprising:
(a) means for connecting one addressable register other than the comparable register to the second input of the unequal comparator.

47. An apparatus of claim 42, further comprising:
(a) the concurrent bus further carrying a condition datum to all the memory elements; and
(b) each of all the memory elements further comprising:
(1) means for connecting the condition datum of the concurrent bus to the second input of the unequal comparator.

48. An apparatus of claim 42, further comprising:
(a) the concurrent bus further carrying a mask to each of all the memory elements;
(b) each of all the memory elements further comprising:
(1) a bus AND gate, comprising:
(A) a first input;
(B) a second input;
(C) a output, each of its bit being positively asserted when the corresponding bits of the first input and the second input are both positively asserted; and
(2) means for connecting:
(A) the mask of the concurrent bus to the second input of the bus AND gate; and
(B) the output of the bus AND gate to the first input of the unequal comparator; and
(c) the concurrent means further comprising:
(1) masking means for masking the first input of the AND gate with the mask of the concurrent bus before comparing it with the second input of the unequal comparator.

49. An apparatus of claim 42, further comprising:
(a) the concurrent bus further carrying a condition code bit to all the memory elements; and
(b) each of all the memory elements further comprising:
(1) a XOR gate, comprising:
(A) a first bit input;
(B) a second bit input; and
(C) a bit output, which is positively asserted when the first bit input is asserted differently from the second bit input;
(2) means for connecting:
(A) the bit output of the unequal comparator to the first bit input of the XOR gate; and
(B) the condition code bit of the concurrent bus to the second bit input of the XOR gate;
(c) the concurrent means further comprising:
(1) specifying means for using the condition code bit of the concurrent bus to specify the required state to be either (A) equal, or (B) unequal;
(2) determining means for determining if the state which comprises the output value of the unequal comparator of each of all the enabled memory elements matches the required state which has been specified by the condition code bit of the concurrent bus.

50. An apparatus of claim 49, each of its memory elements further comprising:
(a) an AND gate, comprising:
(1) a first bit input and a second bit input; and
(2) a bit output, which is positively asserted when both bit inputs are positively asserted;
(b) means for connecting:
(1) the enable bit input of the memory element to the first bit input of the AND gate;
(2) the bit output of the XOR gate to the second bit input of the AND gate; and
(3) the bit output of the AND gate to the match bit output of the memory element.

51. An apparatus of claim 49, further comprising:
(a) the concurrent bus further carrying a condition datum to all the memory elements;
(b) each of all the memory elements further comprising means for connecting:
(1) a register to the first input of the comparator, the register being called the comparable register of the memory element; and
(2) the condition datum to the second input of the comparator of each of all the memory elements.
(c) the concurrent means further comprising:
(1) means for positively asserting the match bit outputs of each of all the enabled memory elements whose comparable register having value satisfying the comparing requirement of either (A) equal, or (B) unequal, with the value of the condition datum of the concurrent bus.

52. An apparatus of claim 49, further comprising:
(a) the concurrent bus further carrying to all the memory elements:
(1) a condition datum;
(2) a mask;
(b) each of its memory elements further comprising:
(1) a bus AND gate, comprising:
(A) a first input;
(B) a second input; and
(C) a output, each of its bit being positively asserted when the corresponding bits of the first input and the second input are both positively asserted; and
(2) means for connecting:
(A) a register to the first input of the bus AND gate, the register being called the comparable register of the memory element; and
(A) the mask of the concurrent bus to the second input of the bus AND gate;
(C) the condition datum of the concurrent bus to the second input of the unequal comparator; and
(c) the concurrent means further comprising:
(1) means for positively asserting the match bit outputs of each of all the enabled memory elements whose comparable registers after being masked by the mask of the concurrent bus having value satisfying the comparing requirement of either (A) equal, or (B) unequal, with the value of the condition datum of the concurrent bus.

53. Searching steps for searching from data stored in the comparable registers of the memory elements in an apparatus of claim 51, for a value to be searched, according to a searching requirement, the searching steps further comprising:
(a) steps for concurrently defining or concurrently changing the selection of the memory elements for searching;
(b) steps for concurrently specifying the value to be searched by the concurrent bus; and
(c) steps for concurrently specifying by the concurrent bus the searching requirement to be either (A) equal or (B) unequal between the value to be searched and the value of the comparable register of each of all the enabled memory element.

54. An apparatus of claim 54, further comprising:
(a) a range decoder, comprising:
(1) a start address input;
(2) an end address input;
(3) a plurality of bit outputs, each of which has a unique address; and
(4) means for concurrently positively asserting all the bit outputs whose addresses are: (A) no less than the value at the start address input, and (B) no more than the value at the end address input, while negatively asserting all the other bit outputs;
(b) means for connecting each of all the memory elements to a unique bit output of the range decoder, thus each of all the memory elements having a unique address;
(c) the input/output control unit further comprising:
(1) controlling means for providing the start address input, and the end address input to the range decoder;
(d) the enabling means further comprising:
(1) means for positively asserting the enable bit inputs of the memory elements whose element addresses are: (A) no less than a start address, and (B) no more than an end address;
(e) the concurrent bus further carrying a self code bit to all the memory elements;
(f) each of all the memory elements further comprising:
(1) a neighboring bit input;
(2) an one-bit neighboring register; and
(3) saving means for saving the match state of the memory element to be either (A) match, or (B) not match, to the neighboring register when the memory element is enabled;
(g) neighboring means for connecting:
(1) the neighboring register of each of all the memory elements to the neighboring bit input of the memory element whose element address is immediately lower than the element address of the memory element itself;
(h) the concurrent means further comprising:
(1) when the self code bit of the concurrent bus is positively asserted, self means for positively asserting the match bit output of each of all the enabled memory element when the bit output of the XOR gate is positively asserted; and
(2) when the self code bit of the concurrent bus is negatively asserted, combining means for positively asserting the match bit output of each of all the enabled memory element when (A) the bit output of the the XOR gate of the memory element itself is positively asserted, and (B) the neighboring register of the memory element whose element address is immediately higher than the memory element itself is positively asserted.

55. Searching steps for searching from data stored in the comparable registers of an apparatus of claim 54, for a value to be searched which has several portions, with each portion spanning a memory element, the searching steps further comprising:
(a) steps for concurrently defining or concurrently changing the selection of the enabled memory elements for searching;
(b) steps for storing each of all array item by multiple neighboring memory elements in the same order;
(c) steps for positively asserting the neighboring register of each of all the memory elements when the comparable register equals the first portion of the value to be matched;
(d) in the order from the first portion to the last portion of the value to be searched, steps for positively asserting the neighboring register of each of all the memory elements when: (A) the comparable register equals the corresponding portion of the value to be matched; and (B) the neighboring memory element of immediately lower order has positively asserted neighboring register; and
(e) steps for using the match bit output to signal the memory element which contains the last portion of each of all the neighboring memory elements which together hold a datum that matches the value to be searched.

56. An apparatus of claim 27, each of its memory elements further comprising:
(a) a value comparator, comprising:
(1) a first input;
(2) a second input;
(3) an equal bit output, which is positively asserted when the value of the first input equals the value of the second input; and
(4) a larger bit output, which is either (A) positively asserted when the value at the first input is larger than the value at the second input, or (B) negatively asserted when the value at the first input is smaller than the value at the second input;
(b) the state means further comprising means for using (A) the equal bit output of the value comparator and (B) the larger bit output of the value comparator to define the state of the memory element.

57. An apparatus of claim 56, each of its memory elements further comprising:
(a) the value comparator being a parallel comparator, comprising:
(1) a first input;
(2) a second input;
(3) an equal bit output;
(4) a larger bit output; and
(5) means for concurrently comparing the value at the first input and the value at the second input so that: (A) the equal bit output is positively asserted when the value at the first is equal to the value at the second input; (B) the larger bit output is positively asserted when the value at the first is larger than the value at the second input; and (C) the larger bit output is negatively asserted when the value at the first is smaller than the value at the second input.

58. An apparatus of claim 56, each of its memory elements further comprising:
(a) means for connecting one register to the first input of the value comparator, the register being called the comparable register of the memory element.

59. An apparatus of claim 56, each of its memory elements further comprising:
(a) the comparable register being addressable.

60. An apparatus of claim 58, each of its memory elements further comprising:
(a) means for connecting one addressable register other than the comparable register to the second input of the value comparator.

61. An apparatus of claim 56, further comprising:
(a) the concurrent bus further carrying a condition datum to all the memory elements; and
(b) each of all the memory elements further comprising:
(1) means for connecting the condition datum of the concurrent bus to the second input of the value comparator.

62. An apparatus of claim 56, further comprising:
(a) the concurrent bus further carrying a mask to each of all the memory elements;
(b) each of all the memory elements further comprising:
(1) a bus AND gate, comprising:
(A) a first input;
(B) a second input;
(C) a output, each of its bit being positively asserted when the corresponding bits of the first input and the second input are both positively asserted; and
(2) means for connecting:
(A) the mask of the concurrent bus to the second input of the bus AND gate; and
(B) the output of the bus AND gate to the first input of the value comparator; and
(c) the concurrent means further comprising:
(1) masking means for masking the first input of the bus AND gate before comparing it with the second input of the value comparator.

63. An apparatus of claim 56, further comprising:
(a) the concurrent bus further carrying a condition code to all the memory elements, comprising:
(1) a else code bit;
(2) an equal code bit; and
(3) a larger code bit;
(b) each of all the memory elements further comprising:
(1) a matching logic table, further comprising:
(A) the condition code input, which inputs the condition code of the concurrent bus;
(B) a case input, which inputs the bit outputs of the value comparator, comprising an equal case bit input; and a larger case bit input;
(C) a match bit output; and
(D) means for asserting the match bit output according to the following function table:

| | Condition | 000 | 001 | 01X | 11X | 100 | 101 |
|---|---|---|---|---|---|---|---|
| Case | Meaning | < | > | != | == | <= | >= |
| 00 | < | 1 | 0 | 1 | 0 | 1 | 0 |
| 01 | > | 0 | 1 | 1 | 0 | 0 | 1 |
| 1X | == | 0 | 0 | 0 | 1 | 1 | 1 |

(c) the concurrent means further comprising:
(1) specifying means for using the condition code of the concurrent bus to specify the required state of the memory element as one of: (A) equal, (B) unequal, (C) larger, (D) smaller, (E) larger and equal, and (F) smaller and equal; and
(2) determining means for determining if the state which comprises the output value of the value comparator of each of all the enabled memory element matches the required state which has been specified by the condition code of the concurrent bus.

64. An apparatus of claim 63, each of its memory elements further comprising:
(a) the matching logic table comprising a standard two-layer logic.

65. An apparatus of claim 63, each of its memory elements further comprising:
(a) a AND gate, comprising:
(1) a first bit input and a second bit input; and
(2) a bit input, which is positively asserted when both bit inputs are positively asserted; and
(b) means for connecting:
(1) the matching bit output of the matching logic table to the first bit input of the AND gate;
(2) the enable bit input of the memory element to the second bit input of the AND gate; and
(3) the bit output of the AND gate to the match bit output of the memory element.

66. An apparatus of claim 63, further comprising:
(a) the concurrent bus further carrying a condition datum to all the memory elements;
(b) each of its memory elements further comprising means for connecting:
(1) a register to the first input of the value comparator, the register being called the comparable register of the memory element; and
(2) the condition datum of the concurrent bus to the second input of the value comparator; and
(c) the concurrent means further comprising:
(1) means for positively asserting the match bit outputs of each of all the enabled memory elements whose comparable registers having value satisfying the comparing requirement of either (A) equal, or (B) unequal, or (C) larger than, or (D) smaller than, or (E) equal or larger than, or (F) equal or smaller than, with the value of the condition datum of the concurrent bus.

67. An apparatus of claim63, further comprising:
(a) the concurrent bus further carrying to each of all the memory elements:
(1) a condition datum; and
(2) a mask;
(b) each of its memory elements further comprising:
(1) a bus AND gate, comprising:
(A) a first input;
(B) a second input; and
(C) a output, each of its bit being positively asserted when the corresponding bits of the first input and the second input are both positively asserted; and
(2) means for connecting:
(A) a register to the first input of the bus AND gate, the register being called the comparable register of the memory element;
(B) the mask of the concurrent bus to the second input of the bus AND gate;
(C) the output of the bus AND gate to the first input of the value comparator; and
(D) the condition datum of the concurrent bus to the second input of the value comparator; and
(c) the concurrent means further comprising:
(1) means for positively asserting the match bit outputs of each of all the enabled memory elements whose comparable registers after being masked by the mask of the concurrent bus having value satisfying the comparing requirement of either (A) equal, or (B) unequal, or (C) larger than, or (D) smaller than, or (E) equal or larger than, or (F) equal or smaller than, with the value of the condition datum of the concurrent bus.

68. Comparing steps for comparing the data stored in the comparable registers of the memory elements in an apparatus of claim 66, for a value to be searched, according to a comparison requirement, the searching steps further comprising:
(a) steps for concurrently defining or concurrently changing the selection of the memory elements for comparing;
(b) steps for concurrently specifying the value to be compared by the concurrent bus; and
(c) steps for concurrently specifying by the concurrent bus the comparison requirement to be either (A) equal, or (B) unequal, or (C) smaller, or (D) larger, or (E) equal or smaller, or (F) equal or larger, between the value to be compared and the value of the comparable register of each of all the enabled memory element.

69. An apparatus of claim 66, further comprising:
(a) a general decoder, comprising:
(1) a start address input;
(2) an end address input;
(3) a carry number input;
(4) a plurality of bit outputs, each of which has a unique address; and
(5) means for concurrently positively asserting all the bit outputs whose addresses are: (A) no less than the value at the start address input, (B) no more than the value at the end address input, and (C) an integer increment of the value at the carry number input starting from the value at the start address input, while negatively asserting all the other bit outputs;
(b) means for connecting each of all the memory elements to a unique bit output of the general decoder, thus each of all the memory elements having a unique element address;
(c) the input/output control unit further comprising:
(1) controlling means for providing the start address input, the end address input, and the carry number input to the general decoder;
(d) the enabling means further comprising:
(1) means for positively asserting the enable bit inputs of the memory elements whose element addresses are: (A) no less than the start address, (B) no more than the end address, and (C) an integer increment of the carry number starting from the start address;
(e) the concurrent bus further carrying an operation code to each of all the memory elements, the operation code comprising:
(1) a select code bit;
(2) a self code bit; and
(3) a transfer code bit;
(f) each of all the memory elements further comprising:
(1) an one-bit neighboring register;
(2) saving means for saving the match state of the memory element to be either (A) match, or (B) not match, to the neighboring register when the memory element is enabled;
(3) a register multiplexer, comprising:
(A) a first bit input;
(B) a second bit input;
(C) a bit output; and
(D) a selection bit input, which connect the first bit input to the bit output when positively asserted, or the second bit input to the bit output when negatively asserted;
(g) neighboring means for connecting:
(1) the neighboring register of each of all the memory elements to the first bit input of the register multiplexer of the memory element whose element address is immediately higher than the element address of the memory element itself; and
(2) the neighboring register of each of all the memory elements to the second bit input of the register multiplexer of the memory element whose element address is immediately lower than the element address of the memory element itself;
(h) the concurrent means further comprising:
(1) when (A) the self code bit of the concurrent bus is negatively asserted, (B) the transfer code bit of the concurrent bus is negatively asserted, and (C) the select code bit of the concurrent bus is negatively asserted, lower combining means for positively asserting the the neighboring register of the memory element itself when (A) the match bit output of the match logic table of the memory element itself is positively asserted, and (B) the neighboring register of the memory element whose element address is immediately lower is positively asserted;
(2) when (A) the self code bit of the concurrent bus is negatively asserted, (B) the transfer code bit of the concurrent bus is negatively asserted, and (C) the select code bit of the concurrent bus is positively asserted, higher combining means for positively asserting the neighboring register of the memory element itself when (A) the match bit output of the match logic table of the memory element itself is positively asserted, and (B) the neighboring register of the memory element whose element address is immediately higher is positively asserted;
(3) when (A) the self code bit of the concurrent bus is negatively asserted, (B) the transfer code bit of the concurrent bus is positively asserted, (C) the select code bit of the concurrent bus is negatively asserted, and (D) the neighboring register is positively asserted, lower transferring means for copy the neighboring register of the memory element itself from the neighboring register of the memory element whose element address is immediately lower;
(4) when (A) the self code bit of the concurrent bus is negatively asserted, (B) the transfer code bit of the concurrent bus is positively asserted, (C) the select code bit of the concurrent bus is positively asserted, and (D) the neighboring register is positively asserted, higher transferring means for copy the neighboring register of the memory element itself from the neighboring register of the memory element whose element address is immediately higher; and
(5) in any other case, self means for asserting the neighboring register of the memory element itself with the value of the match bit output of the match logic table.

70. Combined comparing steps for comparing array items stored in the comparable registers of an apparatus as claim 69 with a value to be compared which has several portions, each array item having corresponding multiple portions, with each portion spanning a memory element, the comparing steps further comprising:
(a) steps for concurrently defining or concurrently changing the selection of the enabled memory elements for searching;
(b) steps for storing each array item by multiple neighboring memory elements in the order of significance;
(c) steps for positively asserting the neighboring register of each of all the memory elements whose comparable register holds the most significant portion that equals the most significant portion of the value to be compared;
(d) in the decreased significance from the most significant memory element to the least significant memory element of each of all array items, steps for positively asserting the neighboring register of each of all the memory elements when: (A) the comparable register equals the corresponding portion of the value to be compared; and (B) the neighboring memory element of immediately higher significance has positively asserted neighboring register;
(e) in the increased significance from the least significant memory element to the most significant memory element of each of all array items:
(1) steps for positively asserting the neighboring register of each of all the memory elements when the value of the comparable register satisfies the condition code of the concurrent bus with the corresponding portion of the value to be compared when the neighboring register of the memory element itself is originally negatively asserted; and
(2) steps for transferring the neighboring register of each of all the memory elements from the neighboring register of the neighboring memory element of immediately lower significance when the neighboring register of the memory element itself is originally positively asserted; and
(f) steps for using the match bit output of the most significant memory element of each of all array items to signal the matching of the array items.

71. An apparatus of claim 56, further comprising:
(a) a parallel counter, comprising:
(1) a plurality of bit inputs,
(2) a count output,
(3) means for concurrently counting the bit inputs which are positively asserted;
(b) means for connecting:
(1) the match bit output of each of all the memory elements to a unique bit input of the parallel counter, and
(2) the count output of the parallel counter to the input/output control unit;
(c) the concurrent means further comprising:
(1) comparing means for defining the required state for matching concurrently to all the memory element by the data stored in each enabled memory element and a comparison requirement; and
(2) counting means for concurrently counting the enabled memory element whose match bit outputs are positively asserted; and
(d) the instruction means further comprising:
(1) means for concurrently specifying a comparison requirement to each of all the memory elements; and
(2) means for writing the count of the enabled memory elements each of which satisfies the comparison requirement.

72. Steps for using the apparatus of claim 70,1further comprising:
(a) steps for concurrently defining or concurrently changing the selection pattern of the enabled memory elements for matching;
(b) steps for concurrently specifying a comparison requirement to each of all the memory elements;
(c) steps for storing an array by the apparatus;
(d) steps for concurrently counting the array items each of which satisfies the comparison requirement; and
(e) steps for concurrently constructing a histogram of the array.

73. An apparatus of claim 56, further comprising:
(a) a priority encoder, comprising:
(1) a plurality of bit inputs, each of which corresponds to a unique address;
(2) a no-hit bit output, which is positively asserted when none of the bit inputs is positively asserted;
(3) a priority high bit input; and
(4) an address output, when the no-hit bit output being negatively asserted, the address output containing either (A) the highest address of the bit inputs which are positively asserted when the priority high bit input is positively asserted, or (B) the lowest address of the bit inputs which are positively asserted when the priority high bit input is negatively asserted;
(b) means for connecting:
(1) the match bit output of each of all the memory elements to a unique bit input of the priority encoder, thus each of all the memory elements having an address;
(2) the priority high bit input of the priority encoder from the input/output control unit; and
(3) the no-hit bit output and the address output of the priority encoder to the input/output control unit;
(c) the concurrent means further comprising:
(1) comparing means for specifying the required state for matching concurrently to all the memory element by the data stored in each enabled memory element and a comparison requirement;
(2) null means for signaling none of the enabled memory elements whose match bit output is positively asserted; and
(3) addressing means for finding either the highest or the lowest element address of the enabled memory element whose match bit output is positively asserted; and
(d) the instruction means further comprising:
(1) means for concurrently specifying a comparison requirement to each of all the memory elements;
(2) means for writing a predefined value to the external connections of the apparatus if no enabled memory element satisfying the comparison requirement; and
(3) means for writing to the external connections of the apparatus either (A) the highest or (B) the lowest address of the enabled memory element which satisfies the comparison requirement.

74. Steps for using the apparatus of claim 73, further comprising:
(a) steps for concurrently defining or concurrently changing the selection of the enabled memory elements for comparing;
(b) steps for concurrently specifying a comparison requirement to each of all the memory elements;
(c) steps for storing an array by the apparatus;
(d) steps for concurrently finding none of the array item which satisfies the comparison requirement;
(e) steps for concurrently finding the highest address of the array item which satisfies the comparison requirement;
(f) steps for concurrently finding the lowest address of the array item which satisfies the comparison requirement;
(g) steps for concurrently enumerating addresses of the array items each of which satisfies the comparison requirement;
(h) steps for concurrently finding a global boundary of the array; and
(i) steps for concurrently finding a global limit of the array.

75. An apparatus of claim 73, further comprising:
(a) a parallel counter, comprising:
(1) a plurality of bit inputs,
(2) a count output,
(3) means for concurrently counting the bit inputs which are positively asserted;
(b) means for connecting:
(1) the match bit output of each of all the memory elements to a unique bit input of the parallel counter, and
(2) the count output of the parallel counter to the input/output control unit;
(c) the concurrent means further comprising:
(1) comparing means for specifying the required state for matching concurrently to all the memory element by the data stored in each enabled memory element and a comparison requirement; and
(2) counting means for concurrently counting the enabled memory element whose match bit outputs are positively asserted; and
(d) the instruction means further comprising:
(1) means for concurrently specifying a comparison requirement to each of all the memory elements; and
(2) means for writing the count of the enabled memory elements each of which satisfies the comparison requirement.

76. Steps for using the apparatus of claim 75, further comprising:
(a) steps for concurrently defining or concurrently changing the selection of the enabled memory elements for matching;
(b) steps for concurrently specifying a comparison requirement to each of all the memory elements;
(c) steps for storing an array by the apparatus;
(d) steps for concurrently finding none of the array item which satisfies the comparison requirement;
(e) steps for concurrently finding the highest address of the array item which satisfies the comparison requirement;
(f) steps for concurrently finding the lowest address of the array item which satisfies the comparison requirement;
(g) steps for concurrently enumerating addresses of the array items each of which satisfies the comparison requirement;
(h) steps for concurrently finding a global boundaries of the array;
(i) steps for concurrently finding a global limit of the array;
(j) steps for concurrently counting the array items each of which satisfies the comparison requirement; and
(k) steps for concurrently constructing a histogram of the array.

77. An apparatus of claim 76, each of all its memory elements further comprising:
(a) a general decoder, comprising:
(1) a start address input;
(2) an end address input;
(3) a carry number input;
(4) a plurality of bit outputs, each of which has a unique address; and
(5) means for concurrently positively asserting all the bit outputs whose addresses are: (A) no less than the value at the start address input, (B) no more than the value at the end address input, and (C) an integer increment of the value at the carry number input starting from the value at the start address input, while negatively asserting all the other bit outputs;
(b) means for connecting each of all the memory elements to the bit output of the general decoder which has the same address as the memory element;
(c) the input/output control unit further comprising:
(1) controlling means for providing the start address input, the end address input, and the carry number input to the general decoder; and
(d) the enabling means further comprising:
(1) means for positively asserting the enable bit inputs of the memory elements whose element addresses are: (A) no less than a start address, (B) no more than an end address, and (C) an integer increment of a carry number starting from the start address.

78. An apparatus of claim 77, further comprising:
(a) dividing means for obtaining (A) the quotient, and (B) the value of dividend minus reminder, of dividing a dividend by a divider, the dividend being the value of a subtrahend minus an offset, the dividing means further comprising:
(1) means for inputting the offset into the start address input of the general decoder;
(2) means for inputting the subtrahend to the end address input of the general decoder;
(3) means for inputting the divider to the carry number input of the general decoder;
(4) means for connecting each of all bit outputs of the general decoder to a unique bit input of the parallel counter, except the bit output at address 0 of the general decoder;
(5) means for outputting the quotient from the count output of the parallel counter;
(6) means for connecting each of all bit outputs of the general decoder to the bit input which has same address of the priority encoder, except (A) the bit output at address 0 of the general decoder, and (B) negatively asserting the bit input at address 0 of the priority encoder;
(7) means for positively asserting the priority high bit input of the priority encoder;
(8) when the no-hit bit output of the priority encoder is positively asserted, means for signaling the divider being 0; and
(9) when the no-hit bit output of the priority encoder is negatively asserted, means for outputting the value of dividend minus reminder from the address output of the priority encoder; and
(b) the instruction means further comprising:
(1) means for obtaining (A) the quotient, and (B) the value of dividend minus reminder, of dividing a dividend by a divider, the dividend being the value of a subtrahend minus an offset.

79. An apparatus of claim 78, further comprising:
(a) a plurality of bit storage elements;
(b) means for connecting:
(1) each enable bit input of all the memory elements from a unique bit storage element; and
(2) each of all the bit storage element from a unique bit output of the general decoder;
(c) saving means for saving the value of each of all the bit outputs of the general decoder to the corresponding bit storage element; and
(d) retaining means for retaining the value of the bit storage elements when obtaining (A) the quotient, and (B) the value of dividend minus reminder, of dividing a dividend by a divider, the dividend being the value of a subtrahend minus an offset.

80. An apparatus of claim 8, further comprising:
(a) the concurrent bus carrying concurrently to each of all the memory elements:
(1) a read selection code; and
(2) an operation code;
(b) each of all the memory elements further comprising:
(1) a neighboring register, being a register;
(2) a operation register, being a register; and
(3) a register multiplexer, being a bus multiplexer, comprising:
(A) a plurality of inputs;
(B) an output; and
(C) a selection input, which selects one of the inputs to be connected to the output; and
(4) means for connecting:
(A) the neighboring register to a unique input of the register multiplexer;
(B) the operation register to the output of the register multiplexer; and
(C) the read selection code of the concurrent bus to the selection input of the register multiplexer;
(c) neighboring means for connecting each of all the memory elements to other memory elements, the neighboring means further comprising:
(1) up connecting means for connecting from the neighboring register of each of all the memory elements to a unique input of the register multiplexer of the memory element which has immediately higher element address; and
(2) down connecting means for connecting from the neighboring register of each of all the memory elements to a unique input of the register multiplexer of the memory element which has immediately lower element address;
(d) the concurrent means further comprising:
(1) instructing means for sending an instruction to each of all the memory elements using the concurrent bus;
(2) read selecting means for selecting the same one of the inputs to the output of the register multiplexer of each of all the enabled memory elements;
(3) read means for copying the content of the output of the register multiplexer to the operation register of each of all the enabled memory elements; and
(4) write means for copying the content of the operation register to the neighboring register of each of all the enabled memory elements.

81. An apparatus of claim 80, further comprising:
(a) a range decoder, comprising:
(1) a start address input;
(2) an end address input;
(3) a plurality of bit outputs, each of which has a unique address; and
(4) means for concurrently positively asserting all the bit outputs whose addresses are: (A) no less than the value at the start address input, and (B) no more than the value at the end address input, while negatively asserting all the other bit outputs;
(b) means for connecting each of all the memory elements to a unique bit output of the range decoder, thus each of all the memory elements having a unique address;
(c) the input/output control unit further comprising:
(1) controlling means for providing the start address input, and the end address input to the range decoder;
(d) the enabling means further comprising:
(1) means for positively asserting the enable bit inputs of the memory elements whose element addresses are: (A) no less than a start address, and (B) no more than an end address;
(e) each of all the memory elements further comprising:
(1) the neighboring register being addressable;
(2) the register multiplexer having two inputs; and
(3) only two registers within each memory element;
(f) the concurrent means further comprising:
(1) moving means for concurrently moving the content of all the addressable registers within a register address range either up or down by one addressable register.

82. An apparatus of claim 81, each of its memory elements further comprising:
(a) the operation register being made of dynamic memory cells whose storage duration is long enough for carrying out the moving means.

83. An apparatus of claim 81, its moving means further comprising:
(a) means for concurrently moving the content of all the addressable registers within a register address range to another register address range of the same size.

84. Content moving means for moving within the apparatus of claim 81, a data object which occupies a continuous register address range, the content moving means comprising:
(a) moving means for moving a data object within the apparatus to another register address range without overwriting any other useful stored data;
(b) inserting means for inserting a data object into the apparatus without overwriting any other useful stored data;
(c) enlarging means for enlarging a data object within the apparatus without overwriting any other useful stored data;
(d) shrinking means for shrinking a data object within the apparatus without leaving unused addressable registers at where the data object originally resides;
(e) removing means for removing a data object from the apparatus without leaving unused addressable registers at where the data object originally resides; and
(f) packing means for keeping the used portion of the addressable registers adjacent to each other so that the data within the apparatus are closely packed during inserting, enlarging, shrinking, removing, and moving data object within the apparatus.

85. Address independent means for identifying the stored data objects within an apparatus which has content moving means as claimed in claim 84, each by a unique number independent of the addresses which are associated with the storing of the data object in the apparatus, the address independent means comprising:
(a) means for identifying each data objects in the apparatus by an object ID which is a unique number, independent of the addresses which are associated with the storing of the data object in the apparatus;
(b) means for adding a new data object of a specified size and obtaining the corresponding new object ID;
(c) means for removing a such identified data object;
(d) means for changing the size of a such identified object by specifying a new size of the data object;
(e) means for exclusively accessing any part of a such identified data object by an offset into the data object;
(f) means for refusing access when a such access is beyond the storage range of the such identified data object; and
(g) means for containing a child data object within a parent data object, and (A) adjusting the size of the parent data object accordingly when operating any of its child data objects; and (B) adjusting the size and location of the child data object when operating any of its parent object.

86. Program using steps for using an apparatus which has content moving means as claimed in claim 84 to hold the data objects of a program, the program using steps comprising:
(a) steps for using a unified data memory instead of a stack memory and a heap memory; and
(b) steps for changing the range and precision of a numerical data object dynamically.

87. An apparatus of claim 80, it connecting means further comprising:
(a) means for connecting from the neighboring register of each of all the memory elements whose element address is (M\hat{ }j k+Σ_{l=0 . . . (j-1)}(M\hat{ }l)) to a unique input of the register multiplexer of the memory element whose element address (M\hat{ }j (k+1)+Σ_{l=0 . . . (j-1)}(M\hat{ }l)), in which M, j, k, and l are all unsigned integers; and
(b) means for connecting from the neighboring register of each of all the memory elements whose element address is (M\hat{ }j (k+1)+Σ_{l=0 . . . (j-1)}(M\hat{ }l)) to a unique input of the register multiplexer of the memory element whose element address (M\hat{ }j k+Σ_{l=0 . . . (j-1)}(M\hat{ }l)), in which M, j, k, and l are all unsigned integers.

88. An apparatus of claim 80, further comprising:
(a) the concurrent bus further carrying a datum to each of all the memory elements; and
(b) means for connecting the datum of the concurrent bus to a unique input of the register multiplexer of each of all the memory elements.

89. An apparatus of claim 80, further comprising:
(a) the concurrent bus further carrying a write selection code to each of all the memory elements;
(b) each of all the memory elements further comprising:
(1) a plurality of data registers, each being a register;
(2) a register demultiplexer, being a bus demultiplexer, comprising:
(A) an input;
(B) a plurality of outputs; and
(C) a selection input, which selects one of the outputs to be connected from the input;
(3) means for connecting:
(A) each of all the data registers to a unique input of the register multiplexer;
(B) each of all the data registers from a unique output of the register demultiplexer;
(C) the neighboring register from a unique output of the register demultiplexer;
(D) the operation register to the input of the register demultiplexer; and
(E) the write selection code of the concurrent bus to the selection input of the register demultiplexer; and
(4) means for exclusively activating either (A) the register multiplexer, or (B) the register demultiplexer; and
(c) the concurrent means further comprising:
(1) write selecting means for selecting the same one of the outputs of the register demultiplexer of each of all the enabled memory elements; and
(2) the write means further comprising means for copying the content of the operation register to the register which has been selected by the write means.

90. An apparatus of claim 89, each of all its memory elements further comprising:
(a) All the registers are addressable.

91. Task switching steps for alternatively operating on a plurality of arrays stored in the apparatus of claim 90, the task switching steps further comprising:
(a) steps for using one set of data registers to store data for a task in each memory element which are used by the task; and
(b) while operating on the set of data registers in each memory element which are used by the task, steps for updating all other data registers in each memory element which are used by the task and all registers of the memory elements which are not used by the task.

92. An apparatus of claim 80, each of its memory elements further comprising:
(a) state means for defining states for the memory element when it is enabled; and
(b) conditional means for carrying out operation code on the concurrent bus when the memory element is in a required state.

93. An apparatus of claim 92, further comprising:
(a) each of all the memory elements further comprising:
(1) at least one status bit;
(2) means for either (A) positively or (B) negatively asserting any of the status bits; and
(3) the state means further comprising means for using the values of the status bit(s) to define the state of the memory element; and
(b) the concurrent means further comprising:
(1) status means for either (A) positively or (B) negatively asserting any of the status bits of each of all the enabled memory elements.

94. An apparatus of claim 92, each of its memory elements further comprising:
(a) the required state being a predefined state.

95. An apparatus of claim 92, further comprising:
(a) the concurrent bus further carrying a condition specification to each of all the memory elements; and
(b) the conditional means further comprising:
(1) specifying means for using the condition specification of the concurrent bus to specify the required state, and
(2) determining means for determining if the state of the memory element matches the required state which has been specified by the condition specification of the concurrent bus.

96. An apparatus of claim 92, further comprising:
(a) each of its memory elements further comprising:
(1) an match bit output; and
(b) the concurrent means further comprising:
(1) match means for positively asserting the match bit output of each of all the enabled memory element.

97. An apparatus of claim 96, further comprising:
(a) a parallel counter, comprising:
(1) a plurality of bit inputs,
(2) a count output,
(3) means for concurrently counting the bit inputs which are positively asserted;
(b) means for connecting:
(1) the match bit output of each of all the memory elements to a unique bit input of the parallel counter, and
(2) the count output of the parallel counter to the input/output control unit;
(c) the concurrent means further comprising:
(1) matching means for specifying the required state for the conditional means concurrently to all the memory element by the data stored in each enabled memory element and a matching requirement; and
(2) counting means for concurrently counting the enabled memory element whose match bit outputs are positively asserted; and
(d) the instruction means further comprising:
(1) means for concurrently specifying a matching requirement to all the memory elements; and
(2) means for writing the count of the enabled memory elements each of which satisfies the matching requirement.

98. Steps for using the apparatus of claim 97, further comprising:
(a) steps for concurrently defining or concurrently changing the selection of the enabled memory elements for matching;
(b) steps for concurrently specifying a matching requirement to all the memory elements; and
(c) steps for concurrently counting the enabled memory elements each of which satisfies the matching requirement.

99. An apparatus of claim 96, further comprising:
(a) a priority encoder, comprising:
(1) a plurality of bit inputs, each of which corresponds to a unique address;
(2) a no-hit bit output, which is positively asserted when none of the bit inputs is positively asserted;
(3) a priority high bit input; and
(4) an address output, when the no-hit bit output being negatively asserted, the address output containing either (A) the highest address of the bit inputs which are positively asserted when the priority high bit input is positively asserted, or (B) the lowest address of the bit inputs which are positively asserted when the priority high bit input is negatively asserted;
(b) means for connecting:
(1) the match bit output of each of all the memory elements to a unique bit input of the priority encoder, thus each of all the memory elements having a unique address;
(2) the priority high bit input of the priority encoder from the input/output control unit; and
(3) the no-hit bit output and the address output of the priority encoder to the input/output control unit;
(c) the concurrent means further comprising:
(1) matching means for defining the required state for the conditional means concurrently to all the memory element by the data stored in each enabled memory element and a matching requirement;
(2) null means for signaling none of the enabled memory elements whose match bit output is positively asserted; and
(3) addressing means for finding either (A) the highest or (B) the lowest address of the enabled memory element whose match bit output is positively asserted; and
(d) the instruction means further comprising:
(1) means for concurrently specifying a matching requirement to all the memory elements;
(2) means for writing a predefined value to the external connection of the apparatus if no enabled memory element satisfying the matching requirement; and
(3) means for writing to the external connection of the apparatus either (A) the highest or (B) the lowest address of the enabled memory element which satisfies the matching requirement.

100. Steps for using the apparatus of claim 99, further comprising:
(a) steps for concurrently defining or concurrently changing the selection of the enabled memory elements for matching;
(b) steps for concurrently specifying a matching requirement to each of all the memory elements;
(c) steps for concurrently finding none of the enabled memory elements satisfying the matching requirement;
(d) steps for concurrently finding the highest address of the enabled memory elements which satisfies the matching requirement;
(e) steps for concurrently finding the lowest address of the enabled memory elements which satisfies the matching requirement; and
(f) steps for concurrently enumerating the addresses of the enabled memory elements each of which satisfies the matching requirement.

101. An apparatus of claim 99, further comprising:
(a) a parallel counter, comprising:
(1) a plurality of bit inputs,
(2) a count output,
(3) means for concurrently counting the bit inputs which are positively asserted;
(b) means for connecting:
(1) the match bit output of each of all the memory elements to a unique bit input of the parallel counter, and
(2) the count output of the parallel counter to the input/output control unit;
(c) the concurrent means further comprising:
(1) matching means for specifying the required state for the conditional means concurrently to all the memory element by the data stored in each enabled memory element and a matching requirement; and
(2) counting means for concurrently counting the enabled memory element whose match bit outputs are positively asserted; and
(d) the instruction means further comprising:
(1) means for concurrently specifying a matching requirement to all the memory elements; and
(2) means for writing the count of the enabled memory elements each of which satisfies the matching requirement to the external connection of the apparatus.

102. Steps for using the apparatus of claim 101, further comprising:
(a) steps for concurrently defining or concurrently changing the selection of the enabled memory elements for matching;
(b) steps for concurrently specifying a matching requirement to each of all the memory elements;
(c) steps for concurrently finding none of the enabled memory elements satisfying the matching requirement;
(d) steps for concurrently finding the highest address of the enabled memory elements which satisfies the matching requirement;
(e) steps for concurrently finding the lowest address of the enabled memory elements which satisfies the matching requirement;
(f) steps for concurrently enumerating the addresses of the enabled memory elements each of which satisfies the matching requirement; and
(g) steps for concurrently counting the enabled memory elements each of which satisfies the matching requirement.

103. An apparatus of claim 101, further comprising:
(a) a general decoder, comprising:
(1) a start address input;
(2) an end address input;
(3) a carry number input;
(4) a plurality of bit outputs, each of which has a unique address; and
(5) means for concurrently positively asserting all the bit outputs whose addresses are: (A) no less than the value at the start address input, (B) no more than the value at the end address input, and (C) an integer increment of the value at the carry number input starting from the value at the start address input, while negatively asserting all the other bit outputs;
(b) means for connecting each of all the memory elements to the bit output of the general decoder which has the same address as the memory element;
(c) the input/output control unit further comprising:
(1) controlling means for providing the start address input, the end address input, and the carry number input to the general decoder; and
(d) the enabling means further comprising:
(1) means for positively asserting the enable bit inputs of the memory elements whose element addresses are: (A) no less than a start address, (B) no more than an end address, and (C) an integer increment of a carry number starting from the start address.

104. An apparatus of claim 103, further comprising:
(a) dividing means for obtaining (A) the quotient, and (B) the value of dividend minus reminder, of dividing a dividend by a divider, the dividend being the value of a subtrahend minus an offset, the dividing means further comprising:
(1) means for inputting the offset into the start address input of the general decoder;
(2) means for inputting the subtrahend to the end address input of the general decoder;
(3) means for inputting the divider to the carry number input of the general decoder;
(4) means for connecting each of all bit outputs of the general decoder to a unique bit input of the parallel counter, except the bit output at address 0 of the general decoder;
(5) means for outputting the quotient from the count output of the parallel counter;
(6) means for connecting each of all bit outputs of the general decoder to the bit input which has same address of the priority encoder, except (A) the bit output at address 0 of the general decoder, and (B) negatively asserting the bit input at address 0 of the priority encoder;
(7) means for positively asserting the priority high bit input of the priority encoder;
(8) when the no-hit bit output of the priority encoder is positively asserted, means for signaling the divider being 0; and
(9) when the no-hit bit output of the priority encoder is negatively asserted, means for outputting the value of dividend minus reminder from the address output of the priority encoder; and
(b) the instruction means further comprising:
(1) means for obtaining (A) the quotient, and (B) the value of dividend minus reminder, of dividing a dividend by a divider, the dividend being the value of a subtrahend minus an offset.

105. An apparatus of claim 104, further comprising:
(a) a plurality of bit storage elements;
(b) means for connecting:
(1) each enable bit input of all the memory elements from a unique bit storage element; and
(2) each of all the bit storage element from a unique bit output of the general decoder;
(c) saving means for saving the value of each of all the bit outputs of the general decoder to the corresponding bit storage element; and
(d) retaining means for retaining the value of the bit storage elements when obtaining (A) the quotient, and (B) the value of dividend minus reminder, of dividing a dividend by a divider, the dividend being the value of a subtrahend minus an offset.

106. An apparatus of claim 92, each of all the memory elements further comprising:
(a) a value comparator, comprising:
(1) a first input;
(2) a second input;
(3) an equal bit output, which is positively asserted when the value of the first input equals the value of the second input; and
(4) a larger bit output, which is either (A) positively asserted when the value at the first input is larger than the value at the second input, or (B) negatively asserted when the value at the first input is smaller than the value at the second input;
(b) means for connecting:
(1) the output of the register multiplexer to the first input of the value comparator; and
(2) the operation register to the second input of the value comparator; and
(c) the state means further comprising means for using (A) the equal bit output of the value comparator and (B) the larger bit output of the value comparator to define the state of the memory element.

107. An apparatus of claim 106, each of its memory elements further comprising:
(a) the value comparator being a parallel comparator, comprising:
(1) a first input;
(2) a second input;
(3) an equal bit output;
(4) a larger bit output; and
(5) means for concurrently comparing the value at the first input and the value at the second input so that: (A) the equal bit output is positively asserted when the value at the first input is equal to the value at the second input; (B) the larger bit output is positively asserted when the value at the first input is larger than the value at the second input; and (C) the larger bit output is negatively asserted when the value at the first input is smaller than the value at the second input.

108. An apparatus of claim 106, further comprising:
(a) each of all the memory elements further comprising:
(1) at least one status bit;
(2) means for either (A) positively or (B) negatively asserting any of the status bits; and
(3) the state means further comprising means for using the values of the status bit(s) to define the state of the memory element; and
(b) the concurrent means further comprising:
(1) status means for either (A) positively or (B) negatively asserting any of the status bits of each of all the enabled memory elements.

109. An apparatus of claim 106, further comprising:
(a) each of its memory elements further comprising:
(1) an match bit output; and
(b) the concurrent means further comprising:
(1) match means for positively asserting the match bit output of each of all the enabled memory element.

110. An apparatus of claim 106, further comprising:
(a) the concurrent bus further carrying a datum to each of all the memory elements; and
(b) means for connecting the datum of the concurrent bus to a unique input of the register multiplexer of each of all the memory elements.

111. An apparatus of claim 106, further comprising:
(a) the concurrent bus further carrying a write selection code to each of all the memory elements;
(b) each of all the memory elements further comprising:
(1) a plurality of data registers, each being a register;
(2) a register demultiplexer, being a bus demultiplexer, comprising:
(A) an input;
(B) a plurality of outputs; and
(C) a selection input, which selects one of the outputs to be connected from the input;
(3) means for connecting:
(A) each of all the data registers to a unique input of the register multiplexer;
(B) each of all the data registers from a unique output of the register demultiplexer;
(C) the neighboring register from a unique output of the register demultiplexer;
(D) the operation register to the input of the register demultiplexer; and
(E) the write selection code of the concurrent bus to the selection input of the register demultiplexer;
(4) means for exclusively activating either (A) the register multiplexer, or (B) the register demultiplexer; and
(c) the concurrent means further comprising:
(1) write selecting means for selecting the same output of the register demultiplexer of each of all the enabled memory elements; and
(2) the write means further comprising means for copying the content of the operation register to the register which has been selected by the write selection means.

112. An apparatus of claim 106, further comprising:
(a) the concurrent bus further carrying a condition code to each of all the memory elements;
(b) each of all the memory elements further comprising:
(1) a control unit, comprising:
(A) an operation code input;
(B) executing means for executing an operation code at the operation code input;
(C) an condition code input;
(D) determining means for determining if the state of the memory element matches the required state which has been specified by an condition code at the condition code input; and
(E) conditional means for carrying out the executing means when the memory element is in the required state; and
(2) means for connecting:
(A) the operation code of the concurrent bus to the control unit;
(B) the condition code of the concurrent bus to the control unit; and
(C) the larger bit output and the equal bit output of the value comparator to the control unit; and
(c) the concurrent means further comprising:
(1) specifying means for using the condition code of the concurrent bus to specify the required state for the conditional means, and
(2) determining means for determining if the state of each of all the enabled memory elements matches the required state which has been specified by the condition code of the concurrent bus.

113. An apparatus of claim 112, further comprising:
(a) the concurrent bus further carrying to each of all the memory elements:
(1) a datum; and
(2) a write selection code;
(b) each of all the memory elements further comprising:
(1) at least one status bit;
(2) status means for either (A) positively or (B) negatively asserting any of the status bits;
(3) means for connecting the status bit with the control unit;
(4) the state means further comprising means for using the values of the status bits to define the state of the memory element;
(5) a match bit output;
(6) a plurality of data registers, each being a register;
(7) a register demultiplexer, being a bus demultiplexer, comprising:
(A) an input;
(B) a plurality of outputs; and
(C) a selection input, which selects one of the outputs to be connected from the input;
(8) means for connecting:
(A) the datum of the concurrent bus to a unique input of the register multiplexer;
(B) each of all the data registers to a unique input of the register multiplexer;
(C) each of all the data registers from a unique output of the register demultiplexer;
(D) the neighboring register from a unique output of the register demultiplexer;
(E) the operation register to the input of the register demultiplexer; and
(F) the write selection code of the concurrent bus to the selection input of the register demultiplexer; and
(9) means for exclusively activating either (A) the register multiplexer, or (B) the register demultiplexer; and
(c) the concurrent means father comprising:
(1) status means for either (A) positively or (B) negatively asserting any of the status bits of each of all the enabled memory elements; and
(2) match means for positively asserting the match bit output of each of all the enabled memory element;
(3) write selecting means for selecting the same output of the register demultiplexer of each of all the enabled memory elements; and
(4) the write means further comprising means for copying the content of the operation register to the register which has been selected by the write selection means.

114. An apparatus of claim 113, its instructing means further comprising means for instructing each of its memory elements in the general format of “condition: operation register”, in which:
(a) the “register” specifies (A) the read selection code, and (B) the write selection code, which can be any one of:
(1) the datum of the concurrent bus;
(2) the neighboring register of the memory element itself;
(3) the neighboring register of the memory element whose element address is immediately lower than the element address of the memory element itself;
(4) the neighboring register of the memory element whose element address is immediately higher than the element address of the memory element itself; and
(5) any one of the data registers;
(b) the “condition” specifies the condition code for the conditional means, which can be any one from the following set:
(1) the value relation between the operation register and the output of the register multiplexer, comprising any one of: (A) smaller, (B) smaller or equal, (C) equal, (D) not equal, (E) larger or equal, and (F) larger;
(2) the value of any of the status bits, comprising either (A) positively asserted, or (B) negatively asserted;
(3) the AND combination of (1) and (2); and
(4) the OR combination of (1) and (2);
(c) the “operation” specifies the operation code, comprising:
(1) read means for copying the content of the register specified by “register” to the operation register;
(2) write means for copying the content of the operation register to the register specified by “register” other than the neighboring registers of the neighboring memory elements;
(3) status means for asserting any of the status bits; and
(4) match means for asserting the match bit output of the element.

115. An apparatus of claim 114, each of all its memory elements further comprising:
(a) a first and a second OR gates, each comprising:
(1) a plurality of bit inputs; and
(2) a bit output, which is positively asserted when any of the bit inputs is positively asserted;
(b) a first and a second AND gates, each comprising:
(1) a plurality of bit inputs; and
(2) a bit output, which is positively asserted when all of the bit inputs are positively asserted;
(c) means for connecting:
(1) each bit of the output of the register multiplexer to a unique bit input of the first OR gate;
(2) the bit output of the first OR gate to the control unit;
(3) each bit of the output of the register multiplexer to a unique bit input of the first AND gate;
(4) the bit output of the first AND gate to the control unit;
(5) each bit of the output of the operation register to a unique bit input of the second OR gate;
(6) the bit output of the second OR gate to the control unit;
(7) each bit of the output of the operation register to a unique bit input of the second AND gate; and
(8) the bit output of the second AND gate to the control unit;
(d) the “condition” code for the instruction means comprising any one of the following set:
(1) the value relation between the operation register and the output of the register multiplexer, comprising any one of: (A) smaller, (B) smaller or equal, (C) equal, (D) not equal, (E) larger or equal, and (F) larger;
(2) the value of any of the status bits, comprising any one of: (A) positively asserted, and (B) negatively asserted;
(3) either (A) the AND or (B) the OR combination of all the bit of the output from the register multiplexer;
(4) either (A) the AND or (B) the OR combination of all the bit of the output from the operation register;
(5) the AND combination of (1) and (2);
(6) the OR combination of (1) and (2);
(7) the AND combination of (1) and (3);
(8) the OR combination of (1) and (3);
(9) the AND combination of (1) and (4);
(10) the OR combination of (1) and (4);
(11) the AND combination of (2) and (3);
(12) the OR combination of (2) and (3);
(13) the AND combination of (2) and (4);
(14) the OR combination of (2) and (4);
(15) the AND combination of (3) and (4); and
(16) the OR combination of (3) and (4);

116. An apparatus of claim 113, further comprising:
(a) a parallel counter, comprising:
(1) a plurality of bit inputs,
(2) a count output,
(3) means for concurrently counting the bit inputs which are positively asserted;
(b) a priority encoder, comprising:
(1) a plurality of bit inputs, each of which corresponds to a unique address;
(2) a no-hit bit output, which is positively asserted when none of the bit inputs is positively asserted;
(3) a priority high bit input; and
(4) an address output, when the no-hit bit output being negatively asserted, the address output containing either (A) the highest address of the bit inputs which are positively asserted when the priority high bit input is positively asserted, or (B) the lowest address of the bit inputs which are positively asserted when the priority high bit input is negatively asserted;
(c) means for connecting:
(1) the match bit output of each of all the memory elements to a unique bit input of the parallel counter;
(2) the count output of the parallel counter to the input/output control unit;
(3) the match bit output of each of all the memory elements to a unique bit input of the priority encoder, thus each of all the memory elements having a unique address;
(4) the priority high bit input of the priority encoder from the input/output control unit; and
(5) the no-hit bit output and the address output of the priority encoder to the input/output control unit;
(d) the concurrent means further comprising:
(1) matching means for defining the required state for the conditional means concurrently to all the memory element by the data stored in each enabled memory element and a matching requirement;
(2) counting means for concurrently counting the enabled memory elements whose match bit outputs are positively asserted;
(3) null means for signaling none of the enabled memory elements whose match bit output is positively asserted; and
(4) addressing means for finding either (A) the highest or (B) the lowest element address among the enabled memory elements whose match bit outputs are positively asserted; and
(e) the instruction means further comprising:
(1) means for concurrently specifying a matching requirement to each of all the memory elements;
(2) means for writing to the external connection of the apparatus the count of the enabled memory elements each of which satisfies the matching requirement;
(3) means for writing a predefined value to the external connection of the apparatus if no enabled memory element satisfying the matching requirement; and
(4) means for writing to the external connection of the apparatus either (A) the highest or (B) the lowest address among those of the enabled memory elements each of which satisfies the matching requirement.

117. Steps for using the apparatus of claim 116, further comprising:
(a) steps for concurrently defining or concurrently changing the selection of the enabled memory elements for matching;
(b) steps for concurrently specifying specifying a requirement for the conditional means to each of all the memory elements;
(c) steps for storing an array by the apparatus;
(d) steps for concurrently finding none of the array item satisfying the matching requirement;
(e) steps for concurrently finding the highest address of the array item which satisfies the matching requirement;
(f) steps for concurrently finding the lowest address of the array item which satisfies the matching requirement;
(g) steps for concurrently enumerating addresses of the array items each of which satisfies the matching requirement;
(h) steps for concurrently counting the array items each of which satisfies the matching requirement;
(i) steps for concurrently constructing a histogram of the array;
(j) steps for concurrently finding the local extreme values of the array;
(k) steps for concurrently finding a global limit of the array;
(l) steps for concurrently finding a global extreme value of the array;
(m) steps for concurrently sorting the array;
(n) steps for concurrently inserting a new array item anywhere in the array;
(o) steps for concurrently deleting a existing array item anywhere in the array; and
(p) steps for concurrently exchanging two existing array items anywhere in the array.

118. An apparatus of claim 116, it connecting means further comprising:
(a) means for connecting from the neighboring register of each of all the memory elements whose element address is (M\hat{ }j k+Σ_{l=0 . . . (j-1)}(M\hat{ }l)) to a unique input of the register multiplexer of the memory element whose element address is (M\hat{ }j (k+1)+Σ_{l=0 . . . (j-1)}(M\hat{ }l)), in which M, j, k and l are all unsigned integers; and
(b) means for connecting from the neighboring register of each of all the memory elements whose element address is (M\hat{ }j (k+1)+Σ_{l=0 . . . (j-1)}(M\hat{ }l)) to a unique input of the register multiplexer of the memory element whose element address is (M\hat{ }j k+Σ_{l=0 . . . (j-1)}(M\hat{ }l)), in which M, j, k and l are all unsigned integers.

119. An apparatus of claim 118, in which M equals to 3.

120. Steps for using the apparatus of claim 119, further comprising:
(a) steps for concurrently defining or concurrently changing the selection of the enabled memory elements for matching;
(b) steps for concurrently specifying a requirement for the conditional means to each of all the memory elements;
(c) steps for storing an array by the apparatus;
(d) steps for concurrently sampling the array items;
(e) steps for concurrently finding the global limit of the array; and
(f) steps for concurrently sorting the array.

121. An apparatus of claim 116, further comprising:
(a) each of all its memory elements further comprising:
(1) means for incrementing the operation register;
(b) the concurrent means father comprising:
(1) incrementing means for incrementing the operation register of each of all the enabled memory elements.

122. Steps for using the apparatus of claim 121, further comprising:
(a) steps for concurrently defining or concurrently changing the selection of the enabled memory elements for matching;
(b) steps for concurrently specifying a requirement for the conditional means to each of all the memory elements;
(c) steps for storing an array by the apparatus;
(d) steps for concurrently finding none of the array item satisfying the requirement;
(e) steps for concurrently finding the highest address among the array item each of which satisfies the requirement;
(f) steps for concurrently finding the lowest address of the array item which satisfies the requirement;
(g) steps for concurrently enumerating addresses of the array items each of which satisfies the requirement;
(h) steps for concurrently counting the array items each of which satisfies the requirement;
(i) steps for concurrently constructing a histogram of the array;
(j) steps for concurrently finding the degree of matching each of all the array item against the requirement;
(k) steps for concurrently finding the local extreme values of the array;
(l) steps for concurrently finding the local extreme values of the array with a difference threshold;
(m) steps for concurrently finding a global limit of the array;
(n) steps for concurrently finding a global extreme value of the array;
(o) steps for concurrently sorting the array;
(p) steps for concurrently inserting a new array item anywhere in the array;
(q) steps for concurrently deleting a existing array item anywhere in the array; and
(r) steps for concurrently exchanging two existing array items anywhere in the array.

123. An apparatus of claim 113, each of all its memory elements further comprising:
(a) a carry bit, being a status bit;
(b) an adder, comprising:
(1) a first input;
(2) a second input;
(3) a carry bit input;
(4) a sum output, which holds the sum value of adding the values of the carry bit input, the first input, and the second input; and
(5) a carry bit output, which holds the carry bit value of adding the values of the carry bit input, the first input, and the second input;
(c) a operation multiplexer, being a bus multiplexer, comprising:
(1) a plurality of inputs;
(2) an output; and
(3) a selection input, which selects one of the inputs to the output;
(d) means for connecting:
(1) the carry bit to the carry bit input of the adder;
(2) the carry bit from the carry bit output of the adder;
(3) the output of the register multiplexer to the first input of the adder;
(4) the operation register to the second input of the adder;
(5) the sum output of the adder to a unique input of the operation multiplexer;
(6) the output of the register multiplexer to a unique input of the operation multiplexer;
(7) the output of the operation multiplexer to the operation register; and
(8) the selection input of the operation multiplexer from the operation code of the concurrent bus; and
(e) the concurrent means means further comprising:
(1) carry means for setting a value of either (A) 0 or (B) 1 to the carry bit; and
(2) adding means for adding the values of (A) the carry bit, (B) the output of the register multiplexer, and (C) the operation register, and means for saving the result at (A) the carry bit, and (B) the operation register.

124. An apparatus of claim 123, the adder in each of all its memory elements being a parallel adder, further comprising:
(a) adding means for concurrently adding the values of (A) the carry bit, (B) the output of the register multiplexer, and (C) the operation register, and means for saving the result at (A) the carry bit, and (B) the operation register.

125. An apparatus of claim 124, further comprising:
(a) the adder parallel in each of all its memory elements further comprising:
(1) an AND output;
(2) means for outputting to the AND output, the result of bitwise AND combining the values of the first input and the second input;
(3) an OR output;
(4) means for outputting to the OR output, the result of bitwise OR combining the values of the first input and the second input;
(5) a XOR output; and
(6) means for outputting to the XOR output, the result of bitwise XOR combining the values of the first input and the second input;
(b) means for connecting:
(1) the AND output of the parallel adder to a unique input of the operation multiplexer;
(2) the OR output of the parallel adder to a unique input of the operation multiplexer; and
(3) the XOR output of the parallel adder to a unique input of the operation multiplexer;
(c) the concurrent means further comprising:
(1) AND means for bitwise logically AND combining the values of (A) the operation register, and (B) the register specified by the read selection code, and means for copying the result to the operation register;
(2) OR means for bitwise logically OR combining the values of (A) the operation register, and (B) the register specified by the read selection code, and means for copying the result to the operation register; and
(3) XOR means for bitwise logically XOR combining the values of (A) the operation register, and (B) the register specified by the read selection code, and means for copying the result to the operation register.

126. An apparatus of claim 123, further comprising:
(a) each of all its memory elements further comprising:
(1) means for logically bitwise inverting the output from the register multiplexer;
(2) means for connecting the logically bitwise inversion of the output from the register multiplexer into a unique input of the operation multiplexer; and
(b) the instructing means further comprising:
(1) inverting means for bitwise logically inverting the value of the register specified by the read selection code, and means for copying the result to the operation register.

127. An apparatus of claim 126, further comprising:
(a) each of all its memory elements further comprising:
(1) an adder multiplexer, being a bus multiplexer, comprising:
(A) a first input and a second input;
(B) an output; and
(C) a selection bit input, which selects either the first input or the second input to the output;
(2) means for connecting:
(A) the output from the register multiplexer to the first input of the adder multiplexer;
(B) the logically bitwise inversion of the output from the register multiplexer to the second input of the adder multiplexer;
(C) the output from the adder multiplexer into the first input of the adder; and
(D) the selection bit input of the adder multiplexer from the operation code of the concurrent bus;
(b) the instructing means further comprising:
(1) subtracting means for subtracting (A) the value of the register specified by the read selection code, from (B) the value of the operation register, and mans for copying the result to the operation register.

128. An apparatus of claim 123, further comprising:
(a) each of all its memory elements further comprising:
(1) means for logically bitwise inverting the operation register; and
(2) means for connecting the logically bitwise inversion of the operation register into a unique input of the operation multiplexer;
(b) the instructing means further comprising:
(1) inverting means for bitwise logically inverting the value of the operation register, and means for copying the result to the operation register; and
(2) subtracting means for subtracting (A) the value of the operation register, from (B) the value of the register specified by the read selection code, and means for copying the result to the operation register.

129. Steps for using the apparatus of claim 123, further comprising:
(a) steps for concurrently defining or concurrently changing the selection of the enabled memory elements for operating upon;
(b) steps for concurrently specifying a requirement for the conditional means to each of all the memory elements;
(c) steps for storing an array by the apparatus;
(d) steps for concurrently finding none of the array item satisfying the requirement;
(e) steps for concurrently finding the highest address among the array item each of which satisfies the requirement;
(f) steps for concurrently finding the lowest address of the array item which satisfies the requirement;
(g) steps for concurrently enumerating addresses of the array items each of which satisfies the requirement;
(h) steps for concurrently counting the array items each of which satisfies the requirement;
(i) steps for concurrently constructing a histogram of the array;
(j) steps for concurrently finding the degree of matching each of all the array item against the requirement;
(k) steps for concurrently finding the local extreme values of the array;
(l) steps for concurrently finding the local extreme values of the array with a difference threshold;
(m) steps for concurrently finding a global limit of the array;
(n) steps for concurrently finding a global extreme value of the array;
(o) steps for concurrently sorting the array;
(p) steps for concurrently inserting a new array item anywhere in the array;
(q) steps for concurrently deleting a existing array item anywhere in the array; and
(r) steps for concurrently exchanging two existing array items anywhere in the array.
(s) steps for concurrently carrying out a local operation involve neighboring array items;
(t) steps for concurrently finding the sum of neighboring array items; and
(u) steps for concurrently matching a template against neighboring array items of the array.

130. An apparatus of claim 123, further comprising:
(a) a X general decoder and a Y general decoder, each comprising:
(1) a start address input;
(2) an end address input;
(3) a carry number input;
(4) a plurality of bit outputs, each of which has a unique address; and
(5) means for concurrently positively asserting all the bit outputs whose addresses are: (A) no less than the value at the start address input, (B) no more than the value at the end address input, and (C) an integer increment of the value at the carry number input starting from the value at the start address input, while negatively asserting all the other bit outputs;
(b) means for connecting:
(1) each of all the memory elements to a unique bit output of the X general decoder, thus each of all the memory elements having a unique X address; and
(2) each of all the memory elements to a unique bit output of the Y general decoder, thus each of all the memory elements having a unique Y address;
(c) the input/output control unit further comprising:
(1) controlling means for providing (A) the X start address input, (B) the X end address input, and (C) the X carry number input to the X general decoder; and
(2) controlling means for providing (A) the Y start address input, (B) the Y end address input, and (C) the Y carry number input to the Y general decoder;
(d) the enabling means further comprising means for positively asserting the enable bit inputs of the memory elements:
(1) whose X addresses are: (A) no less than the X start address, (B) no more than the X end address, and (C) an integer increment of the X carry number starting from the X start address; and
(2) whose Y addresses are: (A) no less than the Y start address, (B) no more than the Y end address, and (C) an integer increment of the Y carry number starting from the X start address;
(e) the neighboring means further comprising:
(1) left connecting means for connecting from the neighboring register of each of all the memory elements to a unique inputs of the register multiplexer of the memory element which has immediately lower X address but same Y address;
(2) right connecting means for connecting from the neighboring register of each of all the memory elements to a unique input of the register multiplexer of the memory element which has immediately higher X address but same Y address;
(3) bottom connecting means for connecting from the neighboring register of each of all the memory elements to a unique inputs of the register multiplexer of the memory element which has immediately lower Y address but same X address; and
(4) top connecting means for connecting from the neighboring register of each of all the memory elements to a unique input of the register multiplexer of the memory element which has immediately higher Y address but same X address.

131. Steps for using the apparatus of claim 130, further comprising:
(a) steps for concurrently defining or concurrently changing the selection of the enabled memory elements for operating upon;
(b) steps for concurrently specifying a requirement for the conditional means to each of all the memory elements;
(c) steps for storing an array by the apparatus;
(d) steps for concurrently finding none of the array item satisfying the requirement;
(e) steps for concurrently finding the highest address among the array item each of which satisfies the requirement;
(f) steps for concurrently finding the lowest address of the array item which satisfies the requirement;
(g) steps for concurrently enumerating addresses of the array items each of which satisfies the requirement;
(h) steps for concurrently counting the array items each of which satisfies the requirement;
(i) steps for concurrently constructing a histogram of the array;
(j) steps for concurrently finding the degree of matching each of all the array item against the requirement;
(k) steps for concurrently finding the local extreme values of the array;
(l) steps for concurrently finding the local extreme values of the array with a difference threshold;
(m) steps for concurrently finding a global limit of the array;
(n) steps for concurrently finding a global extreme value of the array;
(o) steps for concurrently sorting the array;
(p) steps for concurrently inserting a new array item anywhere in the array;
(q) steps for concurrently deleting a existing array item anywhere in the array; and
(r) steps for concurrently exchanging two existing array items anywhere in the array.
(s) steps for concurrently carrying out a local operation involve neighboring array items;
(t) steps for concurrently finding the sum of neighboring array items;
(u) steps for concurrently matching a template against neighboring array items of the array;
(v) steps for concurrently detecting all lines at the a tan(Mx/My) direction on an image, in which Mx and My are both integer; and
(w) steps for concurrently detecting all lines at all directions on an image.

132. An apparatus of claim 113, further comprising:
(a) the concurrent bus further carrying to each of all the memory elements:
(1) a bit read selection code; and
(2) a bit write selection code;
(b) each of all its memory elements further comprising:
(1) the register multiplexer and a bit multiplexer, each being a multi-channel multiplexer further comprising:
(A) an address input;
(B) a plurality of bit inputs, each of which corresponds to a unique input address at the address input;
(C) a width input;
(D) a plurality of bit outputs, each of which corresponds to a unique output address at the width input; and
(E) connecting means for connecting each bit input of input address (A+j) to the bit output of output address j, in which A is the value at the address input and j is between 0 and (W−1), in which W is the value at the width input, while negatively asserting all the other bit outputs;
(2) a register demultiplexer and a bit demultiplexer, each being a multi-channel demultiplexer further comprising:
(A) an address input;
(B) a plurality of bit outputs, each of which corresponds to an output address at the address input;
(C) a width input;
(D) a plurality of bit inputs, each of which corresponds to an input address at the width input; and
(E) connecting means for connecting each bit input of input address j to the bit output of output address (A+j), in which A is the value at the address input and j is between 0 and (W−1), in which W is the value at the width input, while negatively asserting all the other bit outputs;
(3) means for connecting:
(A) the read selection code of the concurrent bus to the address input of the register multiplexer;
(B) the write selection code of the concurrent bus to the address input of the register demultiplexer;
(C) the bit read selection code of the concurrent bus to the address input of the bit multiplexer;
(D) the bit write selection code of the concurrent bus to the address input of the bit demultiplexer;
(E) each bit of the datum of the concurrent bus to a unique bit input of the register multiplexer;
(F) each bit of each of all the data registers to a unique bit input of the register multiplexer;
(G) each bit of each of all the data registers from a unique bit output of the register demultiplexer;
(H) each bit of the neighboring register to a unique bit input of the register multiplexer;
(I) each bit of the neighboring register from a unique bit output of the register demultiplexer;
(J) each bit of the operation register to a unique bit input of the bit multiplexer;
(K) each bit of the operation register from a unique bit output of the bit demultiplexer;
(L) the output of the register multiplexer to the input of the bit demultiplexer;
(M) the output of the bit multiplexer to the input of the register demultiplexer;
(N) the output of the register multiplexer to the first input of the value comparator;
(O) the output of the bit multiplexer to the second input of the value comparator; and
(4) means for exclusively activating either (A) the register multiplexer and the bit multiplexer, or (B) the register demultiplexer and the bit demultiplexer; and
(c) the neighboring means further comprising:
(1) means for connecting from each bit of the neighboring register of each of all the memory elements to a unique bit input of the register multiplexer of each of the memory elements which have immediately adjacent addresses.

133. An apparatus of claim 132, each of all its memory elements further comprising:
(a) a carry bit, being a status bit;
(b) an adder, comprising:
(1) a first input;
(2) a second input;
(3) a carry bit input;
(4) a sum output, which holds the sum value of adding the values of the carry bit input, the first input, and the second input; and
(5) a carry bit output, which holds the carry bit value of adding the values of the carry bit input, the first input, and the second input;
(c) a operation multiplexer, being a bus multiplexer, comprising:
(1) a plurality of inputs;
(2) an output; and
(3) a selection input, which selects one of the inputs to the output;
(d) means for connecting:
(1) the carry bit to the carry bit input of the adder;
(2) the carry bit from the carry bit output of the adder;
(3) the output of the register multiplexer to the first input of the adder;
(4) the output of the bit multiplexer to the second input of the adder;
(5) the sum output of the adder to a unique input of the operation multiplexer;
(6) the output of the register multiplexer to a unique input of the operation multiplexer;
(7) the output of the operation multiplexer to the input of the bit demultiplexer; and
(8) the selection input of the operation multiplexer from the operation code of the concurrent bus; and
(e) the concurrent means means further comprising:
(1) carry means for setting a value of either (A) 0 or (B) 1 to the carry bit; and
(2) adding means for adding the values of (A) the carry bit, (B) the bit section of the register specified by the read selection code, and (C) the bit section of the operation register specified by the bit read selection code, and means for saving the result at (A) the carry bit, and (B) the bit section of the operation register specified by the bit write selection code.

134. An apparatus of claim 132, its instructing means further comprising means for instructing each of its memory elements in the general format of “condition: operation wide [bit] register[bit]”, in which:
(a) the “width” specifies the value at (A) the width input of the bit multiplexer, (B) the width input of the bit demultiplexer, (C) the width input of the register multiplexer, and (D) the width input of the register demultiplexer;
(b) the “register[bit]” specifies (A) the read selection code, and (B) the write selection code, in which “register” can be any one of:
(1) the datum on the concurrent bus;
(2) the neighboring register of the memory element itself;
(3) the neighboring register of any of the memory elements which have immediately adjacent addresses than the address of the memory element itself; and
(4) any one of the data registers;
(c) the “[bit]” specifies (A) the bit read selection code, and (B) the bit write selection code;
(d) the “condition” specifies the condition code for the conditional means; and
(e) the “operation” specifies the operation code.

135. Steps for using the apparatus of claim 133, further comprising:
(a) steps for concurrently defining or concurrently changing the selection of the enabled memory elements for operating upon;
(b) steps for concurrently specifying a requirement for the concurrent means to each of all the memory elements;
(c) steps for concurrently shifting the bit section specified by the read selection code by a value in each of all the enabled memory elements;
(d) steps for concurrently shifting the bit section specified by the bit read selection code by a value in each of all the enabled memory elements;
(e) steps for concurrently obtaining the sum of the register specified by the read selection code and the operation register in each of all the enabled memory elements;
(f) steps for concurrently obtaining the difference of the register specified by the read selection code and the operation register in each of all the enabled memory elements;
(g) steps for concurrently obtaining the production of the register specified by the read selection code and the operation register in each of all the enabled memory elements;
(h) steps for concurrently obtaining the division of the register specified by the read selection code and the operation register in each of all the enabled memory elements; and
(i) steps for concurrently carrying out generic mathematical operations.

136. An all-line decoder, which is an apparatus, comprising:
(a) an address input;
(b) a plurality of bit outputs, each of which corresponds to a unique address at the address input; and
(c) activating means for concurrently positively asserting all the bit outputs whose address are equal to or less than the address input while negatively asserting all the other bit outputs, the activating means further comprising:
(1) the address input being A=(A[N−1] . . . A[0]), in which A[j] denotes the jth significant bit of the address input A of bit width N,
(2) the bit output being F[A, N], in which A denotes the corresponding address A of the bit output and N denotes the bit width of the address input A, and
(3) means for building an all-line-decoder with address bit input width of (N+1) from an all-line-decoder with address bit input width of N using the logic expression of F[A, N]:
F[0, 1]=1;
F[1, 1]=A[0];
F[(0 A[N−1] . . . A[0]), N+1 =F[(A[N−1] . . . A[0]), N]+A[N];
F[(1A[N−1] . . . A[0]), N+1]=F[(A[N−1] . . . A[0]), N] A[N].

137. An apparatus of claim 136, further comprising:
(a) an enable bit input; and
(b) disabling means for signaling the values of all the outputs of the apparatus being invalid for the current input values when the enable bit input is negatively asserted.

138. A carry patent generator, which is an apparatus, comprising:
(a) a carry number input, inputting a carry number being an unsigned integer;
(b) a plurality of bit outputs, each of which having a unique address; and
(c) activating means for positively asserting all the bit outputs whose addresses are an integer-fold of the carry number while negatively asserting all the other bit outputs, the activating means further comprising:
(1) the address for each of all the bit outputs being A=(A[N−1] . . . A[0]), in which A[j] denotes the jth significant bit of the address A of bit width N;
(2) C(A) being the binary expression of the value of the address A;
(3) all possible values of the carry number forming a set C;
(4) the natural number factors of the value of the address A forming a set Q(A);
(5) the set K(A) being the overlap set between set C and set Q(A), with a unique element of the set K(A) denoted as K(A)[k]; and
(6) means for generating the bit output F[A] as:
F[0]=1;
IF A ε K(A): F[A]=ΣₖD[K(A)[k]]+C[A];
ELSE: F[A]=Σₖ D[K(A)[k]]

139. An apparatus of claim 138, further comprising:
(a) an enable bit input; and
(b) disabling means for signaling the values of all the outputs of the apparatus being invalid for the current input values when the enable bit input is negatively asserted.

140. An apparatus of claim 138, further comprising:
(a) means for implementing the carry pattern generator using a standard two-layer OR-AND logic, so that the implementation of the carry pattern generator can be extended easily to accommodate additional bits of the carry number input.

141. A parallel left shifter, which is an apparatus, comprising:
(a) a plurality of bit inputs, each of which having a unique address;
(b) a plurality of bit outputs, each of which corresponding to a unique bit input, thus to the corresponding address as well;
(c) a shift amount input, inputting a shift amount being a unsigned integer; and
(d) connecting means for concurrently connecting each of all the bit inputs to the bit output whose address equals the sum of the address of the bit input and the value of the shift amount input while negatively asserting all the other bit outputs, the connecting means further comprising:
(1) the shift amount input being S=(S[N−1] . . . S[0]), in which S[j] denotes the jth significant bit of the shift amount input S of bit width N;
(2) N count of switching layers, with the bit output from each switching layer being F[A, j+1], in which A is the address of the bit output, and j denote any one of the switch layers, and
(3) switching means for concurrently switching F[A, j+1] by any one of the switching layers according to the logic expression:
S[j]==0: F[A, j+1]=F[A, j];
S[j]==1 AND A>2\hat{ }j: F[A, j+1]=F[A−2\hat{ }j, j];
S[j]==1 AND A<=2\hat{ }j: F[A, j+1]=0.

142. An apparatus of claim 141, further comprising:
(a) an enable bit input; and
(b) disabling means for signaling the values of all the outputs of the apparatus being invalid for the current input values when the enable bit input is negatively asserted.

143. A parallel right shifter, which is an apparatus, comprising:
(a) a plurality of bit inputs, each of which having a unique address;
(b) a plurality of bit outputs, each of which corresponding to a unique bit input, thus to the corresponding address as well;
(c) a shift amount input, inputting a shift amount being a unsigned integer; and
(d) connecting means for concurrently connecting each of all the bit outputs to the bit input whose address equals the sum of the address of the bit output and the value of the shift amount input while negatively asserting all the other bit outputs, the connecting means further comprising:
(1) the shift amount input being S=(S[N−1] . . . S[0]), in which S[j] denotes the jth significant bit of the shift amount input S of bit width N;
(2) N count of switching layers, with the bit output from each switching layer being F[A, j+1], in which A is the address of the bit output, and j denote any one of the switch layers, and
(3) switching means for concurrently switching F[A, j+1] by any one of the switching layers according to the logic expression:
S[j]==0: F[A, j+1]=F[A, j];
S[j]==1 AND A>2\hat{ }j: F[A−2\hat{ }j, j+1]=F[A, j];
S[j]==1 AND A<=2\hat{ }j: F[A, j+1]=0.

144. An apparatus of claim 143, further comprising:
(a) an enable bit input; and
(b) disabling means for signaling the values of all the outputs of the apparatus being invalid for the current input values when the enable bit input is negatively asserted.

145. A range decoder, which is an apparatus, comprising:
(a) a start address input;
(b) an end address input;
(c) a plurality of bit outputs, each of which has a unique address; and
(e) decoding means for concurrently positively asserting all the bit outputs whose addresses are: (A) no less than the value at the start address input, and (B) no more than the value at the end address input, while negatively asserting all the other bit outputs; the decoding means further comprising:
(1) a first and a second all-line decoder, each of which comprises:
(A) an address input,
(B) a plurality of bit outputs, each of which corresponds to a unique address at the address input, and
(C) means for concurrently positively asserting all the bit outputs whose address are equal to or less than the address input while negatively asserting all the other bit outputs;
(2) means for connecting:
(A) the start address input of the range decoder to the address input of the first all-line decoder,
(B) the end address input of the range decoder to the address input of the second all-line decoder,
(C) each of all the bit outputs of the range decoder from the logic-AND combination of: (A) the logical inversion of the bit output of the first all-line decoder which has the same address, and (B) the bit output of the second all-line decoder which has the same address.

146. An apparatus of claim 145, further comprising:
(a) an enable bit input; and
(b) disabling means for signaling the values of all the outputs of the apparatus being invalid for the current input values when the enable bit input is negatively asserted.

147. A general decoder, which is an apparatus, comprising:
(a) a start address input;
(b) an end address input;
(c) a carry number input;
(d) a plurality of bit outputs, each of which has a unique address; and
(e) decoding means for concurrently positively asserting all the bit outputs whose addresses are: (A) no less than the value at the start address input, (B) no more than the value at the end address input, and (C) an integer increment of the value at the carry number input starting from the value at the start address input, while negatively asserting all the other bit outputs, the decoding means further comprising:
(1) a carry patent generator, comprising:
(A) a carry number input, the carry number being an unsigned integer;
(B) a plurality of bit outputs, each of which corresponds to a unique bit output address which is one of the zero-based one-incremental consecutive values; and
(C) means for positively asserting all the bit outputs each of whose addresses is an integer-fold of the carry number while negatively asserting all the other bit outputs;
(2) a parallel left shifter, comprising:
(A) a plurality of bit inputs, each having a unique address,
(B) a plurality of bit outputs, each of which corresponds to a unique bit input, thus to the corresponding unique address as well,
(C) a shift amount input, inputting an unsigned integer, and
(D) means for connecting each of all the bit inputs to the bit output whose address equals the sum of the address of the bit input and the value of the shift amount input while negatively asserting all the other bit outputs;
(3) an all-line decoder, comprising:
(A) an address input,
(B) a plurality of bit outputs, each of which corresponds to a unique address at the address input, and
(C) means for concurrently positively asserting all the bit outputs whose address are equal to or less than the address input while negatively asserting all the other bit outputs;
(4) means for connecting:
(A) the carry number input of the general decoder to the carry number input of the carry pattern generator,
(B) the start address input of the general decoder to the shift amount input of the parallel left shifter,
(C) the end address input of the general decoder to the address input of the all-line decoder,
(D) each of all the bit outputs of the carry pattern generator to the bit input of the parallel left shifter which has the same address,
(E) each of all the element control bit outputs of the general decoder from the logic-AND combination of: (A) the bit output of the parallel left shifter which has the same address, and (B) the bit output of the all-line decoder which has the same address.

148. An apparatus of claim 147, further comprising:
(a) an enable bit input; and
(b) disabling means for signaling the values of all the outputs of the apparatus being invalid for the current input values when the enable bit input is negatively asserted.

149. A parallel divider, which is an apparatus, comprising:
(a) a dividend input;
(b) a divider input;
(c) a quotient output;
(d) a largest output;
(e) an exception bit output, which signaling the value of the divider input being 0; and
(f) dividing means for obtaining (A) the quotient at the quotient output, and (B) the value of dividend minus reminder at the largest output, of dividing the dividend at the dividend input by the divider at the divider input, the dividing means further comprising:
(1) an all-line decoder, comprising:
(A) an address input,
(B) a plurality of bit outputs, each of which corresponds to a unique address at the address input, and
(C) means for concurrently positively asserting all the bit outputs whose address are equal to or less than the address input while negatively asserting all the other bit outputs;
(2) a carry patent generator, comprising:
(A) a carry number input, the carry number being an unsigned integer;
(B) a plurality of bit outputs, each of which corresponds to a unique address; and
(C) means for positively asserting all the bit outputs whose addresses are an integer-fold of the carry number while negatively asserting all the other bit outputs;
(3) a high-priority encoder, comprising:
(A) a plurality of bit inputs, each of which corresponds to a unique address;
(B) a no-hit bit output, which is positively asserted when none of the bit inputs is positively asserted; and
(C) an address output, which contains the highest address of the bit inputs which are positively asserted when the no-hit bit output is negatively asserted;
(4) a parallel counter, comprising:
(A) a plurality of bit inputs,
(B) a count output,
(C) means for concurrently counting the bit inputs which are positively asserted;
(5) means for connecting:
(A) the dividend input to the address input of the all-line decoder;
(B) the divider input to the carry number input of the carry pattern generator;
(C) except the bit input at address 0, each of all the bit inputs of the high-priority encoder from the logic-AND combination of: (A) the bit output of the carry pattern generator which has the same address, and (B) the bit output of the all-line decoder which has the same address, while negatively asserting the bit input at address 0 of the high-priority encoder;
(D) each of all the bit inputs of the high-priority encoder to an unique bit input of the parallel counter, except the bit input at address 0 of the high-priority encoder;
(E) the quotient output from the count output of the parallel counter;
(F) the largest output from the address output of the high-priority encoder; and
(G) the exception bit output from the no-hit bit output of the high-priority encoder.

150. An apparatus of claim 149, further comprising:
(a) an enable bit input;
(b) disabling means for signaling the values of all the outputs of the apparatus being invalid for the current input values when the enable bit input is negatively asserted.

151. A parallel comparator, which is an apparatus, comprising:
(a) a first input;
(b) a second input;
(c) an equal bit output;
(d) a larger bit output; and
(e) comparing means for concurrently comparing the value at the first input and the value at the second input so that: (A) the equal bit output is positively asserted when the value at the first input is equal to the value at the second input; (B) the larger bit output is positively asserted when the value at the first input is larger than the value at the second input; and (C) the larger bit output is negatively asserted when the value at the first input is smaller than the value at the second input; the comparing means further comprising:
(1) the first input being X=(X[N−1] . . . X[0]), in which X[j] denotes the jth significant bit of the first input X of bit width N,
(2) the second input being Y=(Y[N−1] . . . Y[0]), in which Y[j] denotes the jth significant bit of the second input Y of bit width N,
(3) the corresponding bits of X and Y being concurrently and independently compared to obtain G and L, as:
G[j]=X[j] !Y[j];
L[j]=!X[j] Y[j];
(4) the corresponding bits of G and L being concurrently and independently OR combined to Z, as:
Z[j]=G[j]+L[j];
(5) each of all the bits of Z being connected to the input bit of a high-priority encoder with the bit's significance in Z being the same as the input bit's address of the encoder, the address at the address output of the encoder thus containing the most significance of the bit at where X and Y differs, and the no-hit bit output of the high-priority encoder, which is the equal bit output of the parallel comparator, being positively asserted when X and Y are equal, and
(6) the address output of the high-priority encoder being connected to the address input of a multiplexer, which each of all the bits of G being connected to the input bit of the multiplexer with the bit's significance in G being the same as the input bit's address, so that the bit output of the multiplexer, which is the larger bit output of the parallel comparator, is positively asserted when X is larger than Y, and negatively asserted when X is smaller than Y.

152. An apparatus of claim 151, further comprising:
(a) an enable bit input;
(b) disabling means for signaling the values of all the outputs of the apparatus being invalid for the current input values when the enable bit input is negatively asserted.

153. A parallel adder, which is an apparatus, comprising:
(a) a carry bit input;
(b) a first input;
(c) a second input;
(d) a sum output; and
(e) adding means for outputting to the sum output, the sum of the values of the carry bit input, the first input and the second input, the adding means further comprising:
(1) the carry bit input being C[0];
(2) the first input being X=(X[N−1] . . . X[0]), in which X[j] denotes the jth significant bit of the first input X of bit width N;
(3) the second input being Y=(Y[N−1] . . . Y[0]), in which Y[j] denotes the jth significant bit of the second input Y of bit width N;
(4) the sum output being S=(S[N] S[N−1] . . . S[0]), in which S[j] denotes the jth significant bit of the output S of bit width (N+1);
(5) means for concurrently generating bitwise carry C for X and Y:
C[j+1]=X[j] Y[j];
(6) means for concurrently generating bitwise sum Z for X and Y:
Z[j]=(X[j]+Y[j]) !(X[j] Y[j]);
(7) means for concurrently generating carry lookahead at jth bit:
A[j], n]=C[j−n] Π_{k=1 to n}(Z[j−k]);
A[j]=Σ_{n=1 to j}A[j, n];
(8) means for concurrently adding the bitwise sum Z, the bitwise carry C, and the look-ahead carry A into S:
S[0]=!Z[0] C[0]+Z[0] !C[0];
S[N]=C[N]+A[N];
S[j]=!Z[j] C[j]+Z[j] !C[j] !A[j]+!Z[j] A[j].

154. An apparatus of claim 153, further comprising:
(a) an AND output;
(b) means for concurrently outputting to the AND output, the result of bitwise AND combining the values of the first input and the second input;
(c) an OR output;
(d) means for concurrently outputting to the OR output, the result of bitwise OR combining the values of the first input and the second input;
(e) a XOR output; and
(f) means for concurrently outputting to the XOR output, the result of bitwise XOR combining the values of the first input and the second input.

155. An apparatus of claim 153, further comprising:
(a) the lock ahead logic being implemented by transmission gate logic.

156. An apparatus of claim 153, further comprising:
(a) an enable bit input;
(b) disabling means for signaling the values of all the outputs of the apparatus being invalid for the current input values when the enable bit input is negatively asserted.

157. A parallel counter, which is an apparatus, comprising:
(a) a plurality of bit inputs,
(b) a count output,
(c) counting means for concurrently counting the bit inputs which are positively asserted at the count output.

158. An apparatus of claim 157, further comprising:
(a) an enable bit input;
(b) disabling means for signaling the values of all the outputs of the apparatus being invalid for the current input values when the enable bit input is negatively asserted.

159. An apparatus of claim 157, its counting means further comprising:
(a) means for dividing the 2\hat{ }N bit inputs into bit input pairs;
(b) means for adding the two bit inputs in each of all the bit input pairs by a 1-bit adder which outputs two count bits;
(c) means for building a binary tree of parallel adders of N layers, with each jth layer of all the layers comprising 2\hat{ }(N−j) number of j-bit parallel adders, each of which inputs two unique j-bit outputs from the (j−1)th layer, and generate the sum at it (j+1)-bit output; and
(d) means for connecting the output from the sole N-bit parallel adder to the counter output.

160. The apparatus of claim 157, the parallel adder of each M-bit of all further comprising:
(a) a first input of M-bit;
(b) a second input of M-bit;
(c) an output of (M+1)-bit;
(d) adding means for outputting to the sum output, the sum of the values of the first input and the second input, the adding means further comprising:
(1) the first input being X=(X[M−1] . . . X[0]), in which X[j] denotes the jth significant bit of the first input X of bit width M;
(2) the second input being Y=(Y[M−1] . . . Y[0]), in which Y[j] denotes the jth significant bit of the second input Y of bit width M;
(3) the sum output being S=(S[M] S[M−1] . . . S[0]), in which S[j] denotes the jth significant bit of the output S of bit width (M+1);
(4) means for concurrently generating bitwise carry C for X and Y:
C[j+1]=X[j] Y[j];
(5) means for concurrently generating bitwise sum Z for X and Y:
Z[j]=(X[j]+Y[j]) !(X[j] Y[j]);
(6) means for concurrently generating carry lookahead at jth bit when M>j>0:
A[j, n]=C[j−n]Π_{k=1 to n}(Z[j−k]);
A[j]=Σ_{n=1 to j}A[j, n];
(7) means for concurrently adding the bitwise sum Z, the bitwise carry C, and the look-ahead carry A into S:
S[0]=[0]
S[1]=!Z[1] C[1]+Z[1] !C[1];
S[M]=X[M−1] Y[M−1];
S[j]=!Z[j] C[j]+Z[j] !C[j] !A[j]+!Z[j] A[j].

161. An apparatus of claim 160, further comprising:
(a) the look-ahead logic being implemented by transmission gate logic.

162. An apparatus of claim 157, its counting means further comprising:
(a) means for connecting each bit input to a resistor of a constant value, to product current of one constant magnitude if the bit is positively asserted, or no current if the bit is negatively asserted;
(b) means for concurrently summing the produced currents of all the bits and converting the current sum into a voltage signal by an analog op-amp, and
(c) means for using a fast analog-to-digital converter to convert the voltage signal to the count output, with a conversion scale such that each positively asserted bit input results in a cumulative one at the count output.

163. An apparatus of claim 157, its counting means further comprising:
(a) the bit inputs comprising (2\hat{ }(2N)−1) bit inputs, in which N is a positive integer;
(b) the count output comprising (2N) bit;
(c) a plurality of smaller parallel counters, each comprising:
(1) the bit inputs comprising (2\hat{ }(N)−1) bit inputs;
(2) the count output comprising N bit;
(d) a 1-bit adder, comprising:
(1) a first bit input;
(2) a second bit input;
(3) a carry bit output, which is positively asserted when both the first input and the second input are positively asserted; and
(4) a sum bit output, which is positively asserted when the first input and the second input contain different values;
(e) means for connecting the bit inputs of (2\hat{ }N+1) smaller parallel counters to the (2\hat{ }(2N)−1) bit inputs of the apparatus, which are called the 1st layer smaller parallel counters;
(f) means for connecting the jth significant digit of all the count outputs of (2\hat{ }N−1) 1st layer smaller parallel counters to a smaller parallel counter, which is called the jth 2nd layer smaller parallel counter, in which j runs from 0 to N;
(g) means for connecting all the digits except the Nth significant digits of all the count outputs of the remaining two 1st layer smaller parallel counters to a smaller parallel counter called the lone 2nd layer smaller parallel counter, with each jth significant bit at the count outputs of the 1st layer smaller parallel counter connecting to 2\hat{ }j unique bit inputs of the lone 2nd layer smaller parallel counter;
(h) means for connecting the 0th significant bit of the 0th 2nd layer smaller parallel counter to the first bit input of the 1-bit adder, the 0th significant bit of the lone 2nd layer smaller parallel counter to the second bit input of the 1-bit adder, and the sum bit output of the 1-bit adder to the 0th significant bit of the count output of the apparatus; and
(i) means for connecting each of the remaining smaller parallel counters as a 1-bit adder of multiple carry bit inputs and multiple carry bit outputs.

164. A multi-channel multiplexer, being an apparatus, comprising:
(a) an address input;
(b) a plurality of bit inputs, each of which corresponds to a unique input address at the address input;
(c) a width input;
(d) a plurality of bit outputs, each of which corresponds to a unique output address at the width input; and
(e) connecting means for connecting each bit input of input address (A+j) to the bit output of output address j, in which A is the value at the address input and j is between 0 and (W−1), in which W is the value at the width input, while negatively asserting all the other bit outputs.

165. An apparatus of claim 164, further comprising:
(a) an enable bit input; and
(b) disabling means for signaling the values of all the outputs of the apparatus being invalid for the current input values when the enable bit input is negatively asserted.

166. The apparatus of claim 164 being implemented by transmission gate logic.

167. A multi-channel demultiplexer being an apparatus comprising:
(a) an address input;
(b) a plurality of bit outputs, each of which corresponds to an output address at the address input;
(c) a width input;
(d) a plurality of bit inputs, each of which corresponds to an input address at the width input; and
(e) connecting means for connecting each bit input of input address j to the bit output of output address (A+j), in which A is the value at the address input and j is between 0 and (W−1), in which W is the value at the width input, while negatively asserting all the other bit outputs.

168. An apparatus of claim 167, further comprising:
(a) an enable bit input; and
(b) disabling means for signaling the values of all the outputs of the apparatus being invalid for the current input values when the enable bit input is negatively asserted.

169. The apparatus of claim 167 being implemented by transmission gate logic.
